(19) United States
(12) Patent Application Publication
(10) Pub. No.: US 2015/0118621 A1
(43) Pub. Date: Apr. 30, 2015

(54) METHOD OF FORMING PATTERN AND ACTINIC-RAY- OR RADIATION-SENSITIVE RESIN COMPOSITION FOR USE IN THE METHOD

(71) Applicant: FUJIFILM Corporation, Tokyo (JP)

(72) Inventors: Toshiaki FUKUHARA, Haibara-gun (JP); Kaoru IWATO, Haibara-gun (JP)

(73) Assignee: FUJIFILM Corporation, Tokyo (JP)

(21) Appl. No.: 14/588,579

(22) Filed: Jan. 2, 2015

Related U.S. Application Data
(63) Continuation of application No. PCT/JP2013/068458, filed on Jun. 28, 2013.

(30) Foreign Application Priority Data
Jul. 3, 2012 (JP) 2012-149543

(51) Int. Cl. G03F 7/20; G03F 7/004

(52) U.S. Cl. CPC G03F 7/20; G03F 7/004
USPC 430/285.1; 430/326

(57) ABSTRACT

Provided is a method of forming a pattern, including (a) forming a film comprising an actinic-ray- or radiation-sensitive resin composition comprising a resin (P) containing a repeating unit (P1) with a cyclic carbonic acid ester structure and any of repeating units (P2) of general formula (P2-1) below, and a compound (B) that when exposed to actinic rays or radiation, generates an acid, (b) exposing the film to actinic rays or radiation, and (c) developing the exposed film with a developer comprising an organic solvent to thereby obtain a negative pattern.

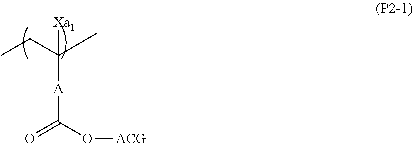

### CROSS-REFERENCE TO RELATED APPLICATIONS

This application is Continuation Application of PCT Application No. PCT/JP2013/068458, filed Jun. 28, 2013 and based upon and claims the benefit of priority from prior Japanese Patent Application No. 2012-149543, filed Jul. 3, 2012, the entire contents of which are incorporated herein by reference.

### FIELD

The present invention relates to a method of forming a pattern and an actinic-ray- or radiation-sensitive resin composition for use in the method.

More particularly, the present invention relates to a method of forming a negative pattern that is suitable for use in, for example, a semiconductor production process for an IC or the like, a circuit board production process for a liquid crystal, a thermal head or the like and other photofabrication lithography processes, and relates to an actinic-ray- or radiation-sensitive resin composition for use in the method. Further, the present invention relates to a process for manufacturing an electronic device, in which the above pattern forming method is included, and relates to an electronic device manufactured by the process. Still further, the present invention relates to an actinic-ray- or radiation-sensitive film comprising the above actinic-ray- or radiation-sensitive resin composition.

### BACKGROUND

Since the development of the resist for a KrF excimer laser (248 nm), an image forming method based on chemical amplification has been employed as a resist image forming method in order to compensate for any sensitivity decrease caused by light absorption. A positive image forming method based on chemical amplification will be described by way of example. In this image forming method, the acid generator contained in exposed areas is decomposed upon exposure to light, such as an excimer laser, electron beams or an extreme ultraviolet light, to thereby generate an acid. In the stage of the bake after the exposure (Post-Exposure Bake: PEB), the generated acid is utilized as a reaction catalyst so that alkali-insoluble groups are converted to alkali-soluble groups. Thereafter, the exposed areas are removed by an alkali developer.

For use in the above method, various alkali developers have been proposed. In particular, an aqueous alkali developer containing 2.38 mass % TMAH (aqueous solution of tetramethylammonium hydroxide) is universally used.

In another aspect, not only the currently mainstream positive type but also pattern forming methods in which use is made of a negative developer, namely, a developer comprising an organic solvent are being developed (see, for example, patent reference 1). This reflects the situation in which in the production of semiconductor elements and the like, while there is a demand for the formation of patterns with various shapes, such as a line, a trench and a hole, there exist patterns whose formation is difficult with the use of current positive resists.

Patent reference 1 describes using, in the negative pattern forming method, a resist composition containing a repeating unit in which a carbonate group is introduced. However, it is presumed that the carbonate group exhibits high hydrophilicity, this high hydrophilicity influencing the resist performances (in particular, local pattern dimension uniformity (hereinafter also referred to as CDU (critical dimension uniformity)) and line width roughness (hereinafter also referred to as LWR)). Therefore, in this resist composition, it is required to regulate the hydrophilicity-hydrophobicity of the resist composition to thereby improve CDU and LWR.

### CITATION LIST

### Patent Literature

Patent reference 1: International Publication No. 2011/122336 (pamphlet).

### DETAILED DESCRIPTION

It is an object of the present invention to provide a pattern forming method capable of forming a pattern excelling in local pattern dimension uniformity and line width roughness. It is another object of the present invention to provide an actinic-ray- or radiation-sensitive resin composition for use in the method.

The present invention is, for example, as recited below.

[1] A method of forming a pattern, comprising:

(a) forming a film comprising an actinic-ray- or radiation-sensitive resin composition comprising: a resin (P) containing a repeating unit (P1) with a cyclic carbonic acid ester structure and any of repeating units (P2) of general formula (P2-1) below, and

a compound (B) that when exposed to actinic rays or radiation, generates an acid;

(b) exposing the film to actinic rays or radiation; and

(c) developing the exposed film with a developer comprising an organic solvent to thereby obtain a negative pattern,

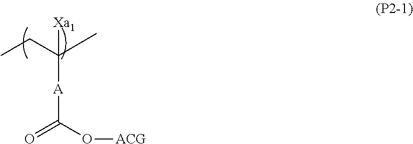

in which

Xa₁ represents a hydrogen atom, an alkyl group, a cyano group or a halogen atom;

A represents a single bond or a bivalent connecting group; and

ACG represents a non-acid-leaving hydrocarbon group consisting only of a carbon atom and a hydrogen atom.

[2] The method according to item [1], wherein the resin (P) contains any of repeating units of general formula (A-1) below as the repeating unit (P1) with a cyclic carbonic acid ester structure,

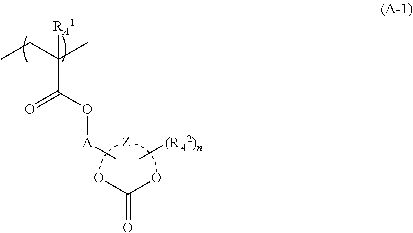

in which

R_{A}¹ represents a hydrogen atom or an alkyl group;

R_{A}², each independently when n is 2 or greater, represents a substituent;

A represents a single bond or a bivalent connecting group;

Z represents an atomic group forming a mono- or polycyclic structure with a group expressed by —O—C(═O)—O— in the formula; and

n is an integer of 0 or greater.

[3] The method according to item [1] or [2], wherein the resin (P) contains the repeating unit (P1) with a cyclic carbonic acid ester structure in an amount of 5 to 50 mol % based on all the repeating units of the resin (P).

[4] The method according to any of items [1] to [3], wherein the non-acid-leaving hydrocarbon group represented by ACG contains a mono- or polyalicyclic hydrocarbon structure.

[5] The method according to any of items [1] to [4], wherein the resin (P) contains the any of repeating units (P2) of general formula (P2-1) in an amount of 5 to 50 mol % based on all the repeating units of the resin (P).

[6] The method according to any of items [1] to [5], wherein the actinic-ray- or radiation-sensitive resin composition further comprises a hydrophobic resin containing at least either a fluorine atom or a silicon atom.

[7] The method according to any of items [1] to [6], wherein the developer comprises at least one organic solvent selected from the group consisting of a ketone solvent, an ester solvent, an alcohol solvent, an amide solvent and an ether solvent.

[8] The method according to any of items [1] to [7], further comprising (d) rinsing with a rinse liquid comprising an organic solvent.

[9] A process for manufacturing an electronic device, comprising the pattern forming method according to any of items [1] to [8].

[10] An electronic device manufactured by the process of item [9].

[11] An actinic-ray- or radiation-sensitive resin composition comprising:

a resin (P) containing a repeating unit (P1) with a cyclic carbonic acid ester structure and any of repeating units (P2) of general formula (P2-1) below, and

a compound (B) that when exposed to actinic rays or radiation, generates an acid,

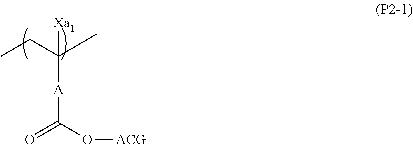

in which

Xa₁ represents a hydrogen atom, an alkyl group, a cyano group or a halogen atom;

A represents a single bond or a bivalent connecting group; and

ACG represents a non-acid-leaving hydrocarbon group consisting only of a carbon atom and a hydrogen atom.

[12] An actinic-ray- or radiation-sensitive film comprising the actinic-ray- or radiation-sensitive resin composition of item [11].

The present invention makes it feasible to provide a pattern forming method capable of forming a pattern excelling in local pattern dimension uniformity and line width roughness and to provide an actinic-ray- or radiation-sensitive resin composition for use in the method.

### DESCRIPTION OF EMBODIMENTS

Embodiments of the present invention will be described in detail below.

Herein, the groups and atomic groups for which no statement is made as to substitution or nonsubstitution are to be interpreted as including those containing no substituents and also those containing substituents. For example, the “alkyl groups” for which no statement is made as to substitution or nonsubstitution are to be interpreted as including not only the alkyl groups containing no substituents (unsubstituted alkyl groups) but also the alkyl groups containing substituents (substituted alkyl groups).

Further, herein, the term “actinic rays” or “radiation” means, for example, brightline spectra from a mercury lamp, far ultraviolet represented by an excimer laser, X-rays, soft X-rays such as extreme ultraviolet (EUV) light, or electron beams (EB). The term “light” means actinic rays or radiation.

The term “exposure to light” unless otherwise specified means not only irradiation with light, such as light from a mercury lamp, far ultraviolet, X-rays or EUV light, but also lithography using particle beams, such as electron beams and ion beams.

<Actinic-Ray- or Radiation-Sensitive Resin Composition>

First, the actinic-ray- or radiation-sensitive resin composition according to the present invention (hereinafter also referred to as the “composition of the present invention” or “resist composition of the present invention”) will be described. This resist composition is typically used in the negative development, namely, development with a developer comprising an organic solvent. That is, the composition of the present invention is typically a negative resist composition.

The actinic-ray- or radiation-sensitive resin composition of the present invention comprises [1] a resin (P) containing a repeating unit (P1) with a cyclic carbonic acid ester structure and any of repeating units (P2) of general formula (P2-1) to be described below, and [2] a compound (B) that when exposed to actinic rays or radiation, generates an acid.

Each of the repeating units (P2) of general formula (P2-1) to be described below contains a non-acid-decomposable hydrophobic group. This non-acid-decomposable hydrophobic group negates the hydrophilicity of the carbonate group contained in the repeating unit (P1) with a cyclic carbonic acid ester structure, so that an actinic-ray- or radiation-sensitive resin composition exhibiting an appropriate hydrophilicity-hydrophobicity balance can be obtained. A pattern excelling in local pattern dimension uniformity and line width roughness can be obtained by carrying out pattern formation with the use of the actinic-ray- or radiation-sensitive resin composition whose hydrophilicity-hydrophobicity has been regulated. The enhancement of line width roughness leads to an enhancement of pattern collapse performance.

Further components that can be incorporated in the composition of the present invention are a solvent [3], a hydrophobic resin [4], a basic compound [5], a surfactant [6] and other additives [7]. The composition of the present invention can be used in the pattern formation in accordance with, for example, the method to be described hereinafter as “method of forming a pattern.”

These individual components will be described in sequence below.

[1] Resin (P)

The resin (P) contains a repeating unit (P1) with a cyclic carbonic acid ester structure and any of repeating units (P2) of general formula (P2-1) to be described below. The resin (P) is a resin that is decomposed under the action of an acid to thereby exhibit an increased polarity (hereinafter also referred to as an acid-decomposable resin (P)). The repeating units that can be incorporated in the resin (P) will be described in sequence below.

[Repeating Unit (P1) with Cyclic Carbonic Acid Ester Structure]

It is preferred for the resin (P) according to the present invention to contain any of repeating units of general formula (A-1) below as the repeating unit (P1) with a cyclic carbonic acid ester structure.

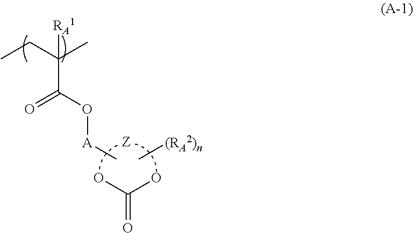

In general formula (A-1), R_{A}¹ represents a hydrogen atom or an alkyl group.

R_{A}², each independently when n is 2 or greater, represents a substituent.

A represents a single bond or a bivalent connecting group.

Z represents an atomic group forming a mono- or polycyclic structure with a group expressed by —O—C(═O)—O— in the formula; and n is an integer of 0 or greater.

General formula (A-1) will be described in detail below.

A substituent, such as a fluorine atom, may be introduced in the alkyl group represented by R_{A}¹. R_{A}¹ is preferably a hydrogen atom, a methyl group or a trifluoromethyl group, more preferably a methyl group.

Examples of the substituents represented by R_{A}² include an alkyl group, a cycloalkyl group, a hydroxyl group, an alkoxy group, an amino group and an alkoxycarbonylamino group. The substituent represented by R_{A}² is preferably an alkyl group having 1 to 5 carbon atoms. As such, there can be mentioned, for example, a linear alkyl group having 1 to 5 carbon atoms, such as a methyl group, an ethyl group, a propyl group or a butyl group, or a branched alkyl group having 3 to 5 carbon atoms, such as an isopropyl group, an isobutyl group or a t-butyl group. A substituent, such as a hydroxyl group, may be introduced in the alkyl group.

In the formula, n is an integer of 0 or greater, representing the number of substituents. For example, n is preferably 0 to 4, more preferably 0.

As the bivalent connecting group represented by A, there can be mentioned, for example, an alkylene group, a cycloalkylene group, an ester bond, an amide bond, an ether bond, a urethane bond, a urea bond, a combination of these or the like. The alkylene group is preferably an alkylene group having 1 to 10 carbon atoms, more preferably an alkylene group having 1 to 5 carbon atoms. As such, there can be mentioned, for example, a methylene group, an ethylene group, a propylene group or the like.

In an aspect of the present invention, A is preferably a single bond or an alkylene group.

As the monocycle containing —O—C(═O)—O—, involving Z, there can be mentioned, for example, any of 5- to 7-membered rings of cyclic carbonic acid esters of general formula (a) below in which n_{A} is 2 to 4. The monocycle is preferably a 5- or 6-membered ring (n_{A} is 2 or 3), more preferably a 5-membered ring (n_{A} is 2).

As the polycycle containing —O—C(═O)—O—, involving Z, there can be mentioned, for example, a structure in which a condensed ring, or a spiro ring, is formed by any of cyclic carbonic acid esters of general formula (a) below in cooperation with one, or two, or more other ring structures. The “other ring structure” capable of forming a condensed ring or a spiro ring may be an alicyclic hydrocarbon group, or an aromatic hydrocarbon group, or a heterocycle.

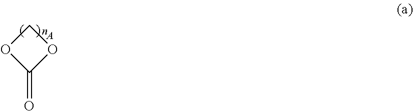

Monomers corresponding to the repeating units of general formula (A-1) above can be synthesized by heretofore known methods described in, for example, Tetrahedron Letters, Vol. 27, No. 32, p. 3741 (1986), Organic Letters, Vol. 4, No. 15, p. 2561 (2002), etc.

In the resin (P), one of the repeating units (P1) with a cyclic carbonic acid ester structure may be contained alone, or two or more thereof may be contained. The content of repeating unit with a cyclic carbonic acid ester structure (preferably any of repeating units of general formula (A-1)) in the resin (P), based on all the repeating units of the resin (P), is preferably in the range of 3 to 80 mol %, more preferably 3 to 60 mol %, further more preferably 3 to 30 mol % and most preferably 5 to 15 mol %. The resist satisfying this content can realize enhanced developability, low defect occurrence, low LWR, low PEB temperature dependence, profile, etc.

Particular examples of the repeating units of general formula (A-1) (repeating units (A-1a) to (A-1w)) are shown below, which in no way limit the scope of the present invention.

In the following particular examples, R_{A}¹ is as defined above in connection with general formula (A-1).

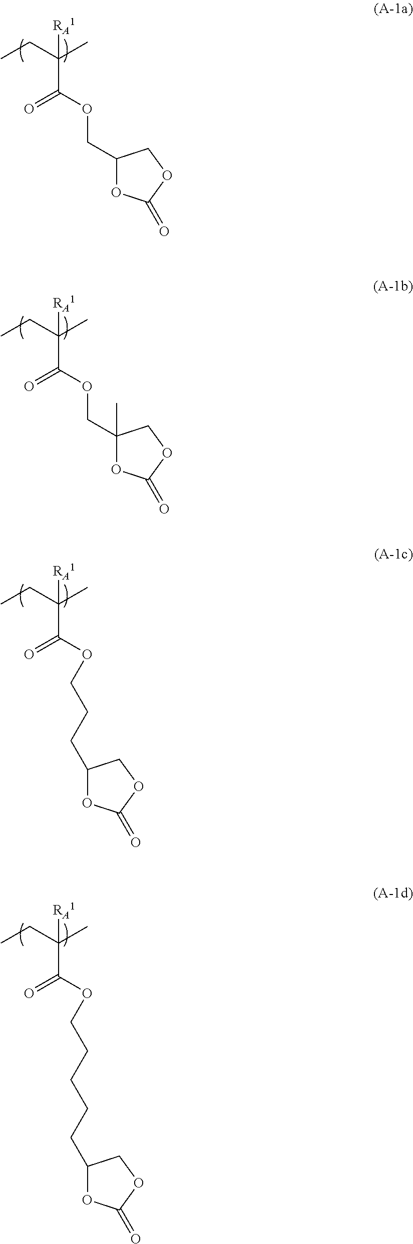

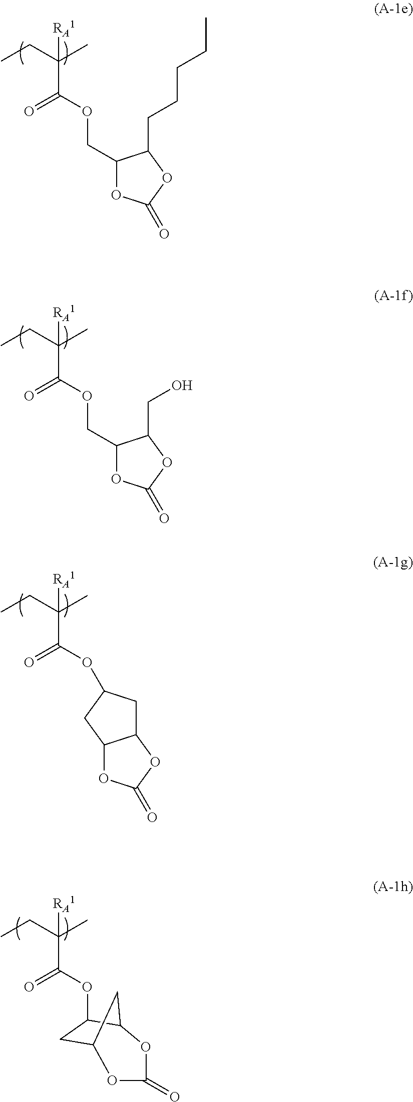

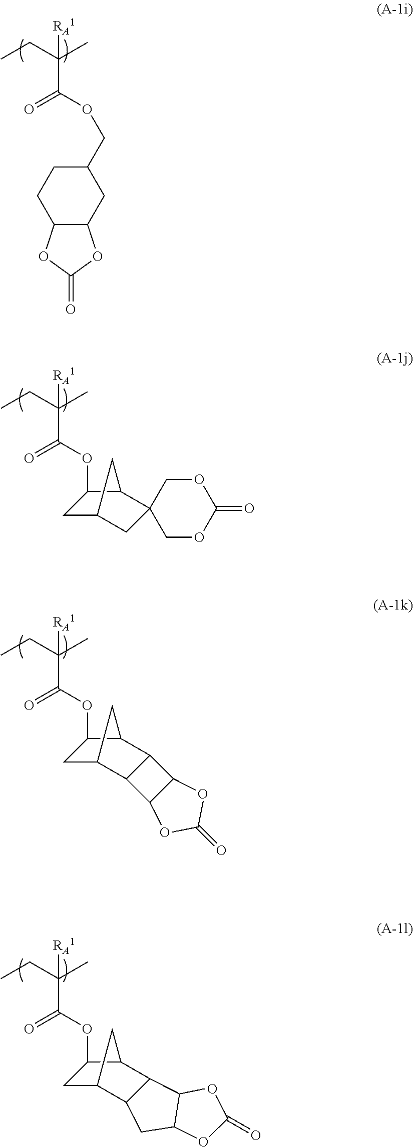

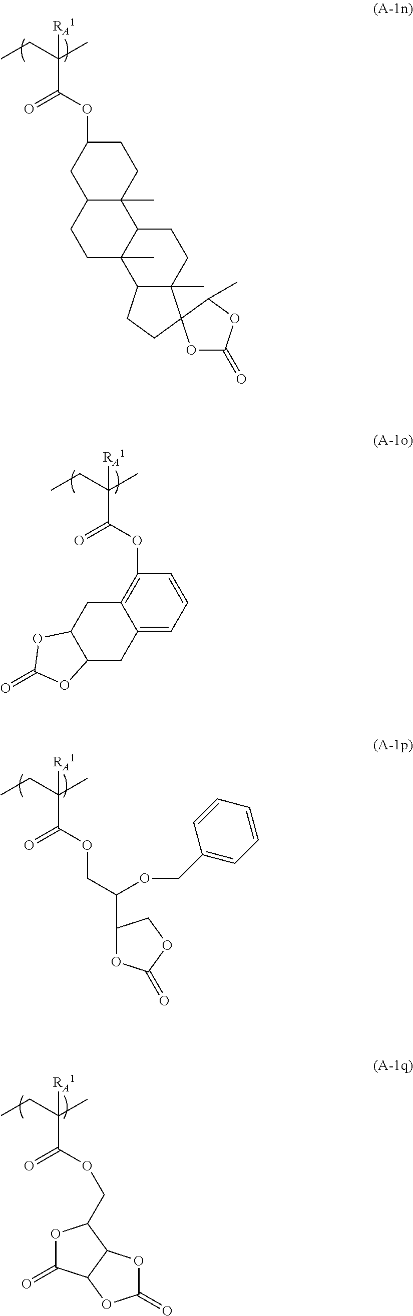

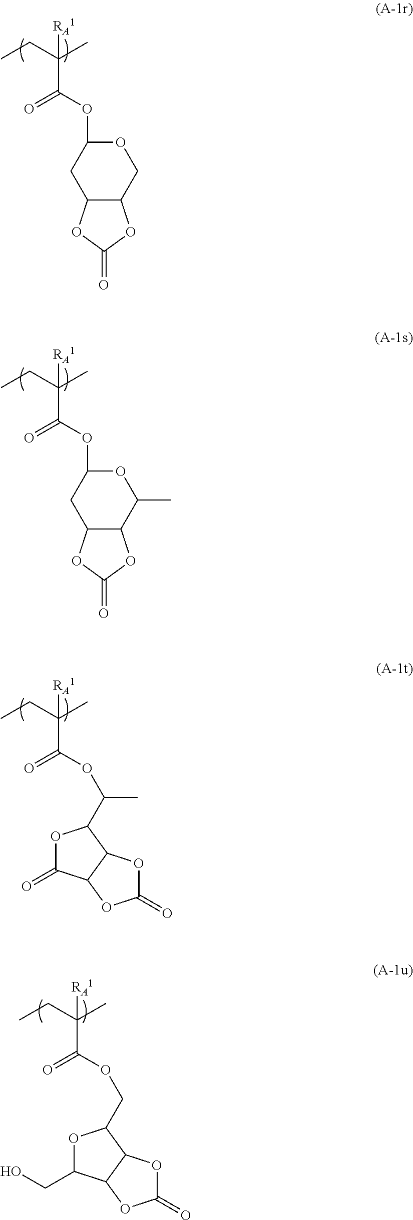

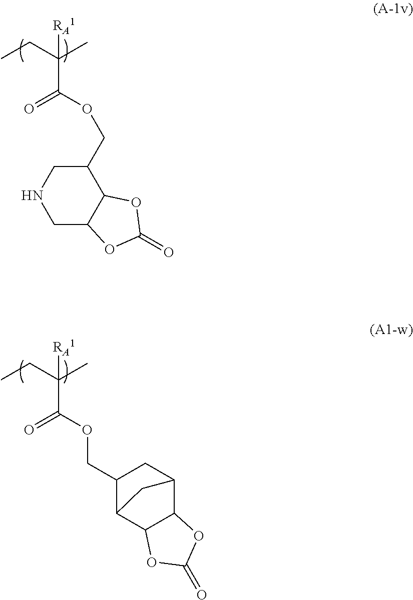

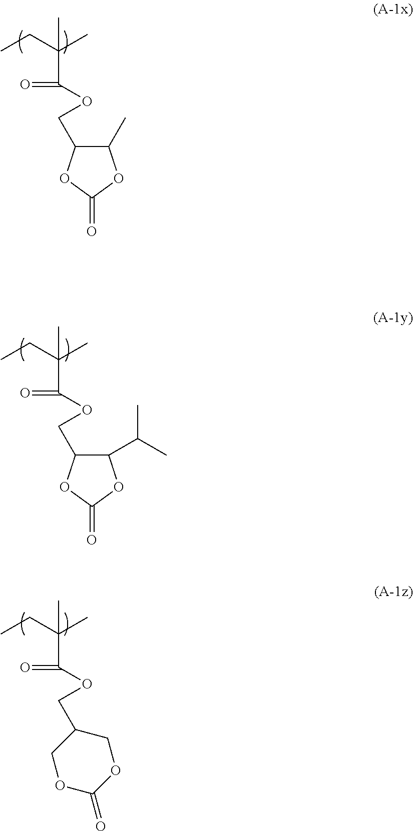

[Repeating Unit (P2) of General Formula (P2-1)]

The resin (P) according to the present invention contains any of repeating units (P2) of general formula (P2-1) below.

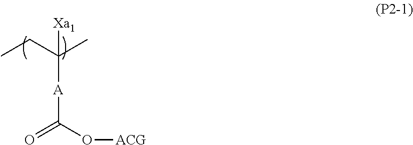

In general formula (P2-1),

Xa₁ represents a hydrogen atom, an alkyl group, a cyano group or a halogen atom.

A represents a single bond or a bivalent connecting group.

ACG represents a non-acid-leaving hydrocarbon group consisting only of a carbon atom and a hydrogen atom.

Xa₁ in general formula (P2-1) above represents a hydrogen atom, an alkyl group, a cyano group or a halogen atom. The alkyl group represented by Xa₁ may be substituted with a hydroxyl group or a halogen atom. Xa₁ is preferably a hydrogen atom or a methyl group.

A represents a single bond or a bivalent connecting group. A preferred bivalent connecting group is a —CO₂-alkylene- comprised of —CO₂— linked to an alkylene group. As the alkylene group in the —CO₂-alkylene-, there can be mentioned methylene, a bivalent connecting group resulting from the removal of two hydrogen atoms from norbornane, or a bivalent connecting group resulting from the removal of two hydrogen atoms from adamantane.

The non-acid-leaving hydrocarbon group represented by ACG is not limited as long as it is a hydrocarbon group that does not depart from the oxygen atom in the formula under the action of an acid. The non-acid-leaving hydrocarbon group is preferably a hydrocarbon group comprised only of a carbon atom and a hydrogen atom, more preferably one containing no polar substituent. It is preferred for the non-acid-leaving hydrocarbon group represented by ACG to contain a mono- or polyalicyclic hydrocarbon structure. The reason therefor is that the polarity of the resin extensively changes upon the exposure to actinic rays or radiation, thereby enhancing the dissolution contrast in development. Moreover, the resin with a mono- or polyalicyclic hydrocarbon structure generally exhibits high hydrophobicity, so that the developing speed at the development of areas of low light exposure intensity of the resist film with a negative developer (preferably, an organic solvent) is high, thereby enhancing the developability in the use of a negative developer.

As the non-acid-leaving hydrocarbon groups represented by ACG, there can be mentioned a linear or branched alkyl group and mono- or polycycloalkyl group that do not depart from the oxygen atom in the formula under the action of an acid. Preferred examples thereof include a linear or branched alkyl group having 1 to 10 carbon atoms, such as a methyl group, an ethyl group, an n-propyl group, an isopropyl group, an isobutyl group or a neopentyl group; a monocycloalkyl group having 3 to 10 carbon atoms, such as a cyclopentyl group, a cyclohexyl group or a cycloheptyl group; and a polycycloalkyl group having 7 to 15 carbon atoms, such as a norbornyl group, a tetracyclodecanyl group, a tetracyclododecanyl group, an adamantyl group, a diamantyl group or a tetrahydrodecalin group. A mono- or polycycloalkyl group may further be introduced as a substituent in the linear or branched alkyl group. A linear or branched alkyl group or a mono- or polycycloalkyl group may further be introduced as a substituent in the mono- or polycycloalkyl group.

It is preferred for the non-acid-decomposable repeating units of general formula (P2-1) to be non-acid-decomposable repeating units of general formula (I-1) below.

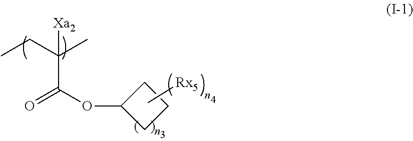

In general formula (I-1),

Xa₂ represents a hydrogen atom, an alkyl group, a cyano group or a halogen atom.

R_{X5} represents a linear or branched alkyl group or a cycloalkyl group. When there are a plurality of R_{X5}s, they may be linked to each other to thereby form a further ring in cooperation with the carbon atom to which R_{X5} is bonded.

In the formula, n₃ is an integer of 2 to 5, and

n₄ is an integer of 0 to 3.

Xa₂ in general formula (I-1) has the same meaning as that of Xa₁ in general formula (P2-1).

The linear or branched alkyl group represented by R_{X5} is preferably one having 1 to 4 carbon atoms, such as a methyl group, an ethyl group, an n-propyl group, an isopropyl group, an n-butyl group, an isobutyl group or a t-butyl group.

The cycloalkyl group represented by R_{X5} is mono- or polycyclic. The cycloalkyl group is preferably a monocycloalkyl group having 3 to 10 carbon atoms, such as a cyclopentyl group or a cyclohexyl group; or a polycycloalkyl group having 7 to 15 carbon atoms, such as a norbornyl group, a tetracyclodecanyl group, a tetracyclododecanyl group or an adamantyl group.

The mono- or polycycloalkyl group formed by at least two of R_{X5}s linked to each other in cooperation with the carbon atom to which R_{X5} is bonded is preferably a monocycloalkyl group having 3 to 10 carbon atoms, such as a cyclopentyl group or a cyclohexyl group, or a polycycloalkyl group having 7 to 15 carbon atoms, such as a norbornyl group, a tetracyclodecanyl group, a tetracyclododecanyl group or an adamantyl group.

As monomers corresponding to the non-acid-decomposable repeating units of general formula (P2-1) and general formula (I-1), there can be mentioned, for example, compounds each having one unsaturated bond capable of addition polymerization, selected from among acrylic esters, methacrylic esters, allyl compounds, vinyl ethers, vinyl esters and the like.

Particular examples of the non-acid-decomposable repeating units of general formula (P2-1) and general formula (I-1) are shown below, which in no way limit the scope of the present invention.

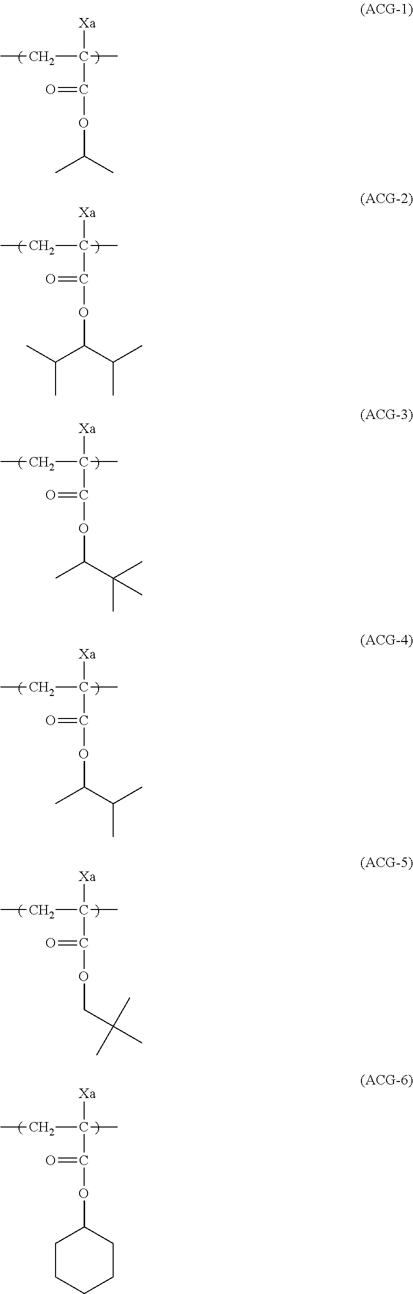

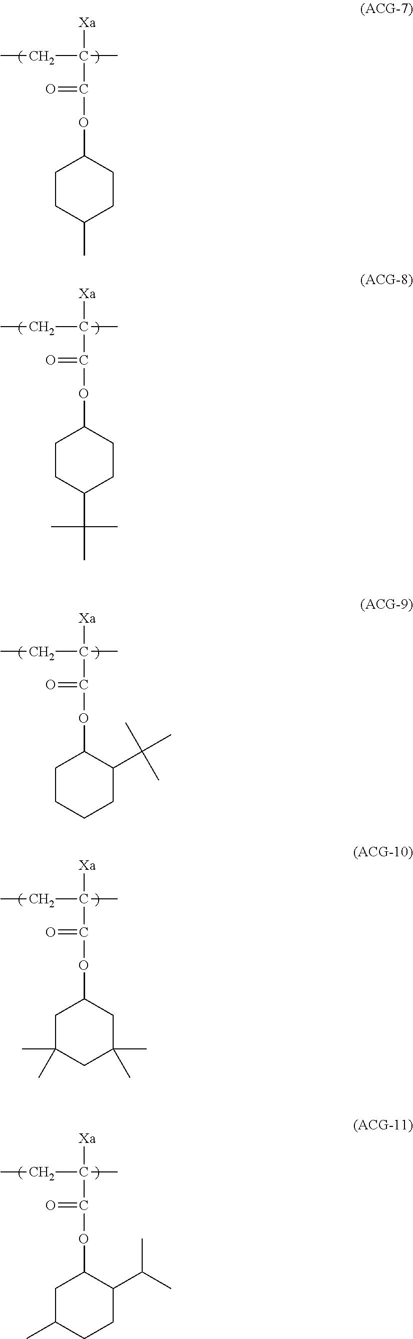

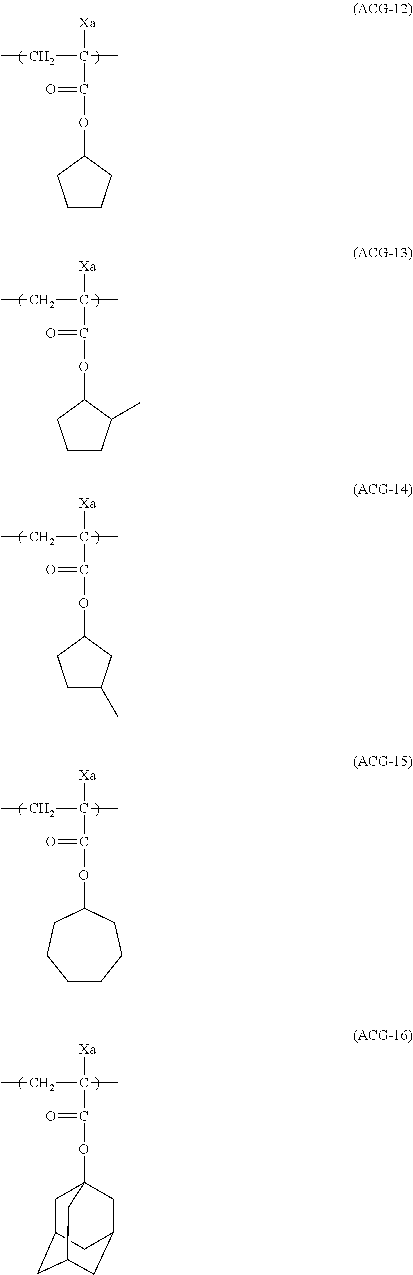

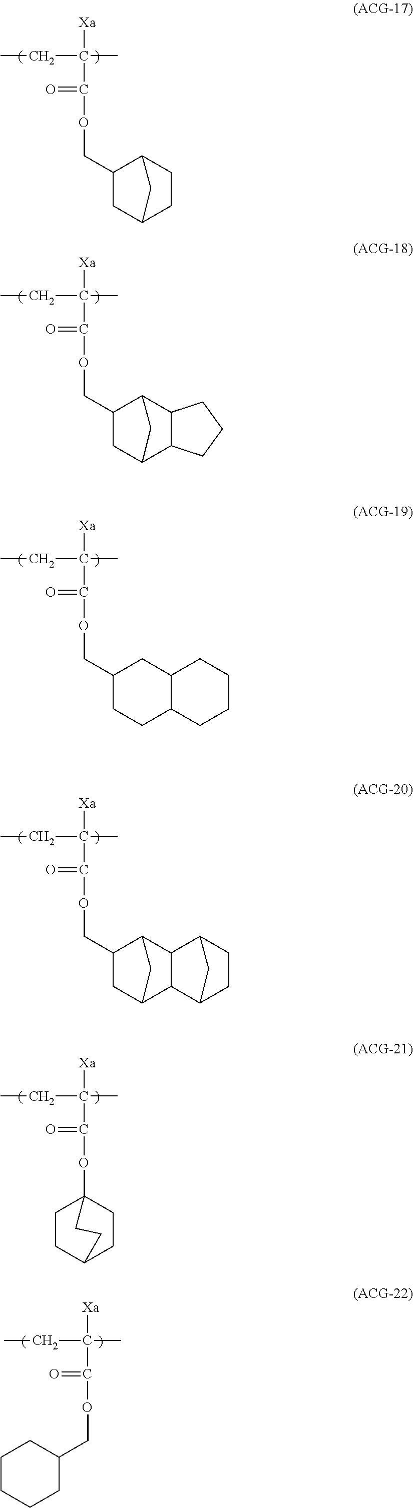

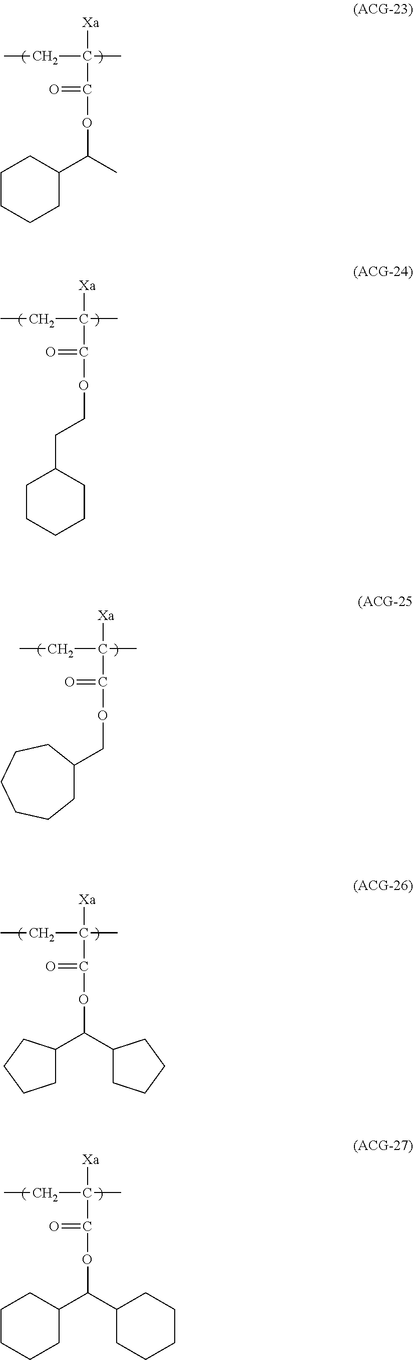

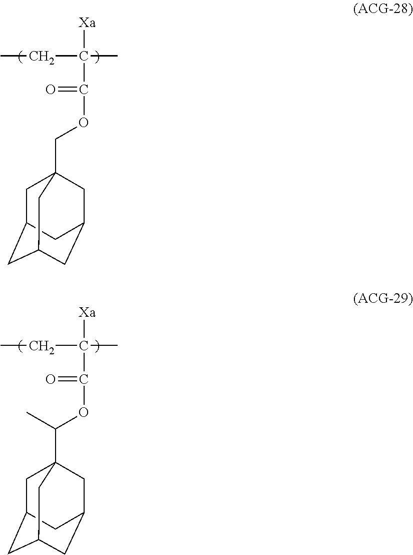

In the above particular examples, Xa represents H, CH₃, CF₃ or CH₂OH.

In the above particular examples, the repeating units (ACG-2), (ACG-6), (ACG-7), (ACG-8), (ACG-9), (ACG-12), (ACG-16), (ACG-17), (ACG-18), (ACG-19), (ACG-20), (ACG-22), (ACG-23), (ACG-24), (ACG-26), (ACG-27), (ACG-28) and (ACG-29) are especially preferred.

The content of repeating unit expressed by general formula (P2-1) or (1-1) above, based on all the repeating units of the resin (P), is preferably in the range of 3 to 80 mol %, more preferably 3 to 60 mol %, further more preferably 3 to 30 mol % and most preferably 5 to 15 mol %.

In the resin (P), the ratio between repeating unit (P1) with a cyclic carbonic acid ester structure and repeating unit expressed by general formula (P2-1) in terms of molar ratio is preferably in the range of 1:5 to 5:1, more preferably 1:3 to 3:1 and most preferably 1:2 to 2:1.

The introduction of repeating units of general formula (P2-1) or (1-1) above in the resin (P) enhances the required properties of the acid-decomposable resin, especially:

(1) solubility in applied solvents,

(2) film forming easiness (glass transition temperature),

(3) solubilities in a positive developer and a negative developer,

(4) film thinning (selections of hydrophilicity-hydrophobicity and alkali-soluble group),

(5) adhesion of unexposed area to substrate,

(6) dry etching resistance, etc.

[Other Repeating Unit]

(a) Repeating Unit Containing an Acid-Decomposable Group

The resin (P) may contain a repeating unit that when acted on by an acid, is decomposed to thereby increase its polarity and hence exhibit a decreased solubility in a developer comprising an organic solvent. As such a repeating unit, there can be mentioned, for example, a repeating unit (hereinafter also referred to as an “acid-decomposable repeating unit”) in which a group (hereinafter also referred to as an “acid-decomposable group”) that when acted on by an acid, is decomposed to thereby produce a polar group is introduced in the principal chain or a side chain or in both the principal chain and a side chain of the repeating unit.

It is preferred for the acid-decomposable group to have a structure in which a polar group is protected by a group that when acted on by an acid, is decomposed and leaves.

The polar group is not particularly limited as long as it is rendered poorly soluble or insoluble in a developer comprising an organic solvent. As polar groups, there can be mentioned an acid group (group dissociated in a 2.38 mass % aqueous tetramethylammonium hydroxide solution conventionally used as a resist developer), such as a phenolic hydroxyl group, a carboxyl group, a fluoroalcohol group (preferably a hexafluoroisopropanol group), a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group or a tris(alkylsulfonyl)methylene group; an alcoholic hydroxyl group; and the like.

The alcoholic hydroxyl group refers to a hydroxyl group bonded to a hydrocarbon group, which is one other than the hydroxyl group (phenolic hydroxyl group) directly bonded onto an aromatic ring. Any aliphatic alcohol substituted at its α-position with an electron withdrawing group, such as a fluorine atom, (for example, a fluorinated alcohol group (a hexafluoroisopropanol group, etc.)) is not included in the category of the alcoholic hydroxyl group. It is preferred for the alcoholic hydroxyl group to be a hydroxyl whose pKa value is in the range of 12 to 20.

Preferred polar groups include a carboxyl group, a fluoroalcohol group (preferably a hexafluoroisopropanol group) and a sulfonic acid group.

It is preferred for the acid-decomposable group to be a group whose hydrogen atom is replaced by a group leaving under the action of an acid.

As the group leaving under the action of an acid, there can be mentioned, for example, —C(R₃₆)(R₃₇)(R₃₈), —C(R₃₆)(R₃₇)(OR₃₉), —C(R₀₁)(R₀₂)(OR₃₉) or the like.

In the formulae, each of R₃₆ to R₃₉ independently represents an alkyl group, a cycloalkyl group, an aryl group, an aralkyl group or an alkenyl group. R₃₆ and

R₃₇ may be bonded to each other to thereby form a ring. Each of R₀₁ and R₀₂ independently represents a hydrogen atom, an alkyl group, a cycloalkyl group, an aryl group, an aralkyl group or an alkenyl group.

Each of the alkyl groups represented by R₃₆ to R₃₉, R₀₁ and R₀₂ preferably has 1 to 8 carbon atoms. For example, there can be mentioned a methyl group, an ethyl group, a propyl group, an n-butyl group, a sec-butyl group, a hexyl group, an octyl group or the like.

The cycloalkyl groups represented by R₃₆ to R₃₉, R₀₁ and R₀₂ may be monocyclic or polycyclic. When the cycloalkyl group is monocyclic, it is preferably a cycloalkyl group having 3 to 8 carbon atoms. As such, there can be mentioned, for example, a cyclopropyl group, a cyclobutyl group, a cyclopentyl group, a cyclohexyl group, a cyclooctyl group or the like. When the cycloalkyl group is polycyclic, it is preferably a cycloalkyl group having 6 to 20 carbon atoms. As such, there can be mentioned, for example, an adamantyl group, a norbornyl group, an isobornyl group, a camphonyl group, a dicyclopentyl group, an α-pinanyl group, a tricyclodecanyl group, a tetracyclododecyl group, an androstanyl group or the like. With respect to these, at least one carbon atom of each of the cycloalkyl groups may be replaced by a heteroatom, such as an oxygen atom.

Each of the aryl groups represented by R₃₆ to R₃₉, R₀₁ and R₀₂ is preferably one having 6 to 10 carbon atoms. For example, there can be mentioned a phenyl group, a naphthyl group, an anthryl group or the like.

Each of the aralkyl groups represented by R₃₆ to R₃₉, R₀₁ and R₀₂ is preferably one having 7 to 12 carbon atoms. For example, there can be mentioned a benzyl group, a phenethyl group, a naphthylmethyl group or the like.

Each of the alkenyl groups represented by R₃₆ to R₃₉, R₀₁ and R₀₂ preferably has 2 to 8 carbon atoms. For example, there can be mentioned a vinyl group, an allyl group, a butenyl group, a cyclohexenyl group or the like.

The ring formed by the mutual bonding of R₃₆ and R₃₇ is preferably a cycloalkyl group (monocyclic or polycyclic). The cycloalkyl group is preferably a monocycloalkyl group, such as a cyclopentyl group or a cyclohexyl group, or a polycycloalkyl group, such as a norbornyl group, a tetracyclodecanyl group, a tetracyclododecanyl group or an adamantyl group. A monocycloalkyl group having 5 or 6 carbon atoms is more preferred. A monocycloalkyl group having 5 carbon atoms is most preferred.

It is preferred for the acid-decomposable group to be a cumyl ester group, an enol ester group, an acetal ester group, a tertiary alkyl ester group or the like. A tertiary alkyl ester group is more preferred.

The repeating unit containing an acid-decomposable group introduced in the resin (P) is preferably any of repeating units of general formula (I) below.

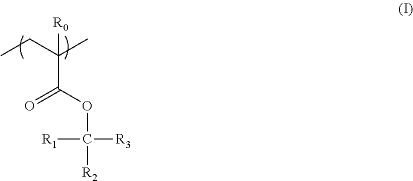

In general formula (I),

R₀ represents a hydrogen atom, or a linear or branched alkyl group.

Each of R₁ to R₃ independently represents a linear or branched alkyl group, or a mono- or polycycloalkyl group.

Any two of R₁ to R₃ may be bonded to each other to thereby form a mono- or polycycloalkyl group.

A substituent may be introduced in the linear or branched alkyl group represented by R₀. The linear or branched alkyl group is preferably one having 1 to 4 carbon atoms. As such, there can be mentioned a methyl group, an ethyl group, an n-propyl group, an isopropyl group, an n-butyl group, an isobutyl group, a t-butyl group or the like. As the substituent, there can be mentioned a hydroxyl group, a halogen atom (e.g., a fluorine atom) or the like.

It is preferred for R₀ to be a hydrogen atom, a methyl group, a trifluoromethyl group or a hydroxymethyl group.

Each of the alkyl groups represented by R₁ to R₃ is preferably one having 1 to 4 carbon atoms, such as a methyl group, an ethyl group, an n-propyl group, an isopropyl group, an n-butyl group, an isobutyl group or a t-butyl group.

Each of the cycloalkyl groups represented by R₁ to R₃ is preferably a monocycloalkyl group, such as a cyclopentyl group or a cyclohexyl group, or a polycycloalkyl group, such as a norbornyl group, a tetracyclodecanyl group, a tetracyclododecanyl group or an adamantyl group.

The cycloalkyl group formed by the mutual bonding of any two of R₁ to R₃ is preferably a monocycloalkyl group, such as a cyclopentyl group or a cyclohexyl group, or a polycycloalkyl group, such as a norbornyl group, a tetracyclodecanyl group, a tetracyclododecanyl group or an adamantyl group. A monocycloalkyl group having 5 or 6 carbon atoms is most preferred.

As a preferred form, there can be mentioned a form in which R₁ is a methyl group or an ethyl group and in which R₂ and R₃ are bonded to each other to thereby form the above-mentioned cycloalkyl group.

Substituents may be introduced in these groups. As the substituents, there can be mentioned, for example, a hydroxyl group, a halogen atom (e.g., a fluorine atom), an alkyl group (having 1 to 4 carbon atoms), a cycloalkyl group (having 3 to 8 carbon atoms), an alkoxy group (having 1 to 4 carbon atoms), a carboxyl group, an alkoxycarbonyl group (having 2 to 6 carbon atoms) and the like. The number of carbon atoms of each thereof is preferably 8 or less.

In an especially preferred form among the repeating units of general formula (I) above, each of R₁, R₂ and R₃ independently represents a linear or branched alkyl group.

In this form, each of the linear or branched alkyl groups represented by R₁, R₂ and R₃ is preferably one having 1 to 4 carbon atoms. As such, there can be mentioned a methyl group, an ethyl group, an n-propyl group, an isopropyl group, an n-butyl group, an isobutyl group or a tert-butyl group.

R₁ is preferably a methyl group, an ethyl group, an n-propyl group or an n-butyl group; more preferably a methyl group or an ethyl group; and most preferably a methyl group.

R₂ is preferably a methyl group, an ethyl group, an n-propyl group, an isopropyl group or an n-butyl group; more preferably a methyl group or an ethyl group; and most preferably a methyl group.

R₃ is preferably a methyl group, an ethyl group, an n-propyl group, an isopropyl group, an n-butyl group, an isobutyl group or a tert-butyl group; more preferably a methyl group, an ethyl group, an isopropyl group or an isobutyl group; and most preferably a methyl group, an ethyl group or an isopropyl group.

Preferred particular examples of the repeating units containing acid-decomposable groups are shown below, which in no way limit the scope of the present invention.

In the particular examples, Rx represents a hydrogen atom, CH₃, CF₃ or CH₂OH. Each of Rxa and Rxb represents an alkyl group having 1 to 4 carbon atoms. Z represents a substituent. When there are a plurality of Z's, they may be identical to or different from each other. In the formulae, p is 0 or a positive integer. Particular examples and preferred examples of Z's are the same as those of the substituents introducible in the groups represented by R₁ to R₃, etc.

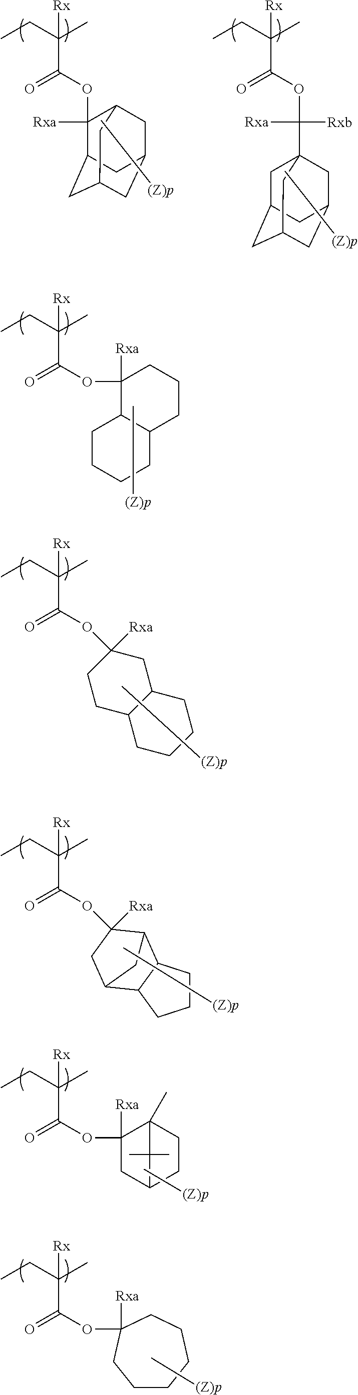

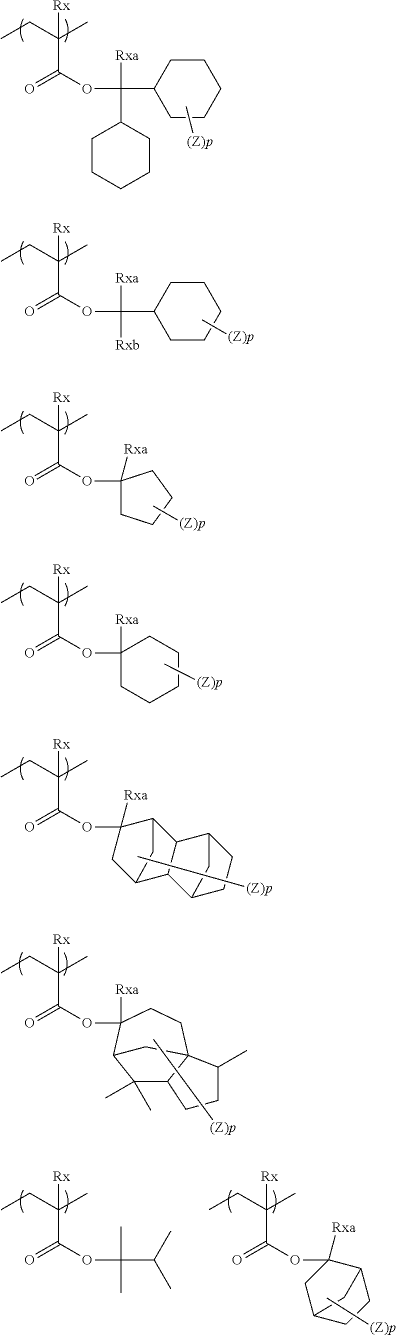

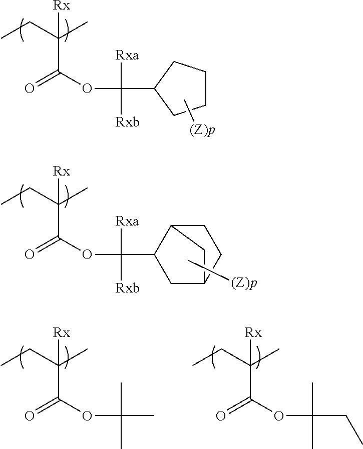

In the resin (P), one of the repeating units each containing an acid-decomposable group may be used alone, or two or more thereof may be used in combination.

It is preferred for the resin (P) to contain the repeating unit containing an acid-decomposable group (when two or more such repeating units are contained, sum thereof) that upon decomposition of the acid-decomposable group, produces a parted substance whose molecular weight (when two or more parted substances are produced, molar fraction weighted average of molecular weights (hereinafter also referred to as molar average)) is 140 or below in an amount of 50 mol % or more based on all the repeating units of the resin. If so, in the formation of a negative image, exposed areas remain as a pattern, so that the film thickness decrease in pattern areas can be prevented by lowering the molecular weight of the parted substance.

In the present invention, the “parted substance produced upon decomposition of the acid-decomposable group” refers to a substance parted upon decomposition under the action of an acid, corresponding to the group leaving upon decomposition under the action of an acid. For example, in the instance of repeating unit (α) to be shown hereinafter (repeating unit positioned upper leftmost in examples to be shown hereinafter), the alkene (H₂C═C(CH₃)₂) produced upon decomposition of the t-butyl moiety is referred to.

In the present invention, it is preferred for the molecular weight (molar average when two or more parted substances are produced) of the parted substance produced upon decomposition of the acid-decomposable group to be 100 or less from the viewpoint of preventing any film thickness decrease in pattern areas.

With respect to the molecular weight (molar average when two or more parted substances are produced) of the parted substance produced upon decomposition of the acid-decomposable group, there is no particular lower limit. From the viewpoint of the exertion of the function of the acid-decomposable group, the molecular weight is preferably 45 or greater, more preferably 55 or greater.

In the present invention, from the viewpoint of the secure retention of the film thickness in pattern areas as exposed areas, the repeating unit containing an acid-decomposable group (when two or more such repeating units are contained, sum thereof) that upon decomposition of the acid-decomposable group, produces a parted substance whose molecular weight is 140 or below is preferably contained in an amount of 60 mol % or greater, more preferably 65 mol % or greater and further more preferably 70 mol % or greater, based on all the repeating units of the resin. There is no particular upper limit. However, the amount is preferably up to 90 mol %, more preferably up to 85 mol %.

The content of the sum of repeating units each containing an acid-decomposable group is preferably 20 mol % or greater, more preferably 30 mol % or greater, further more preferably 45 mol % or greater and most preferably 50 mol % or greater, based on all the repeating units of the resin (P).

The content of the sum of repeating units each containing an acid-decomposable group is preferably up to 90 mol %, more preferably up to 85 mol %, based on all the repeating units of the resin (P).

(b) Repeating Unit Containing Lactone Structure or Sultone Structure

The resin (P) may further comprise a repeating unit containing a lactone structure or sultone structure.

Lactone and sultone structures are not particularly limited as long as lactone and sultone structures are contained respectively. A 5 to 7-membered ring lactone structure is preferred, and one resulting from the condensation of a 5 to 7-membered ring lactone structure with another cyclic structure effected in a fashion to form a bicyclo structure or spiro structure is also preferred. More preferably, the resin comprises a repeating unit with any of the lactone structures of general formulae (LC1-1) to (LC1-17) below or sultone structures of general formulae (SL1-1) to (SL1-3) below. The lactone structure or sultone structure may be directly bonded to the principal chain of the resin. Especially preferred lactone structures are those of formulae (LC1-1), (LC1-4), (LC1-5), (LC1-6), (LC1-13), (LC1-14) and (LC1-17). Lactone structure (LC1-4) is most preferred. Using these specified lactone structures enhances LWR and reduces development defects.

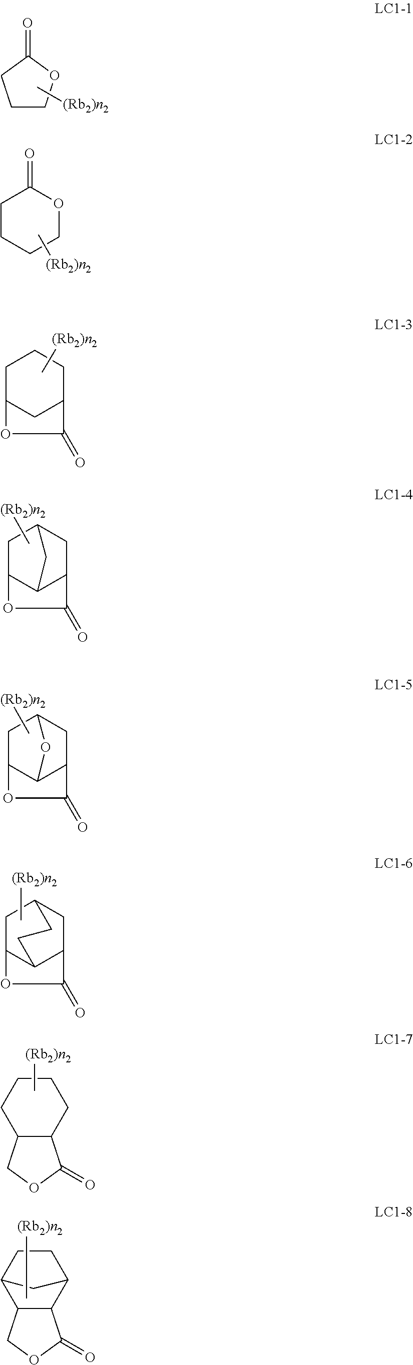

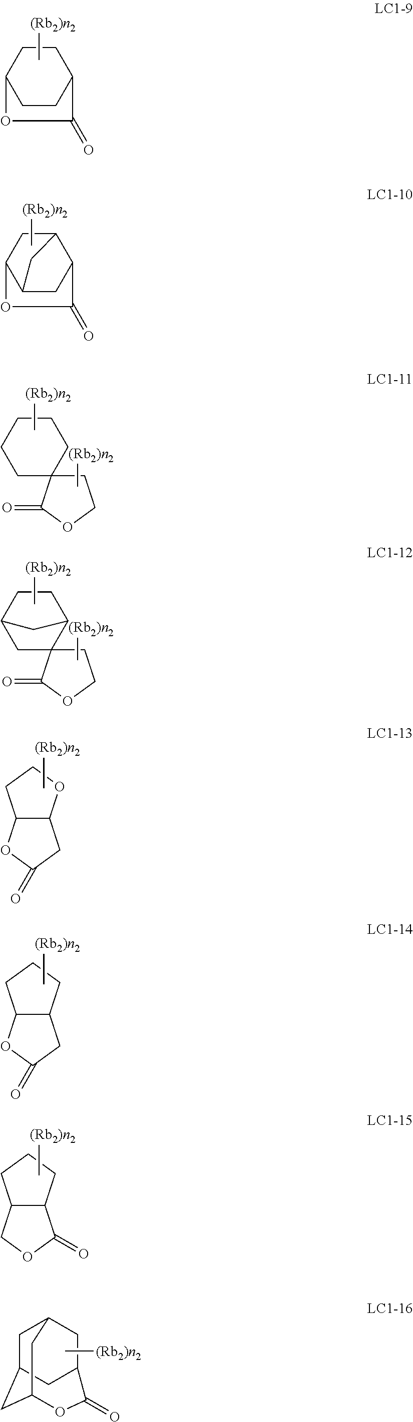

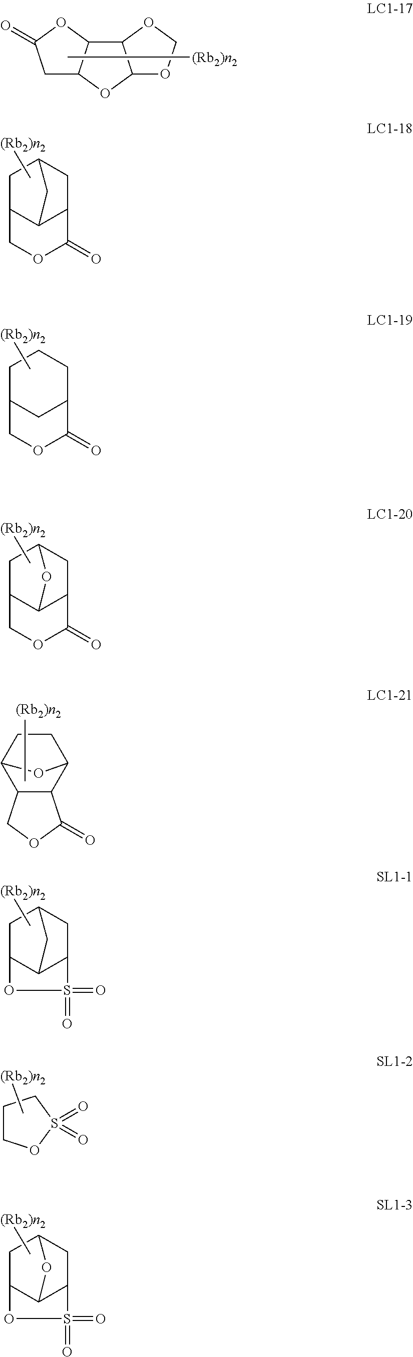

The presence of a substituent (Rb₂) on the portion of the lactone or sultone structure is optional. As a preferred substituent (Rb₂), there can be mentioned an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group or the like. Of these, an alkyl group having 1 to 4 carbon atoms, a cyano group and an acid-decomposable group are more preferred. In the formulae, n₂ is an integer of 0 to 4. When n₂ is 2 or greater, the plurality of present substituents (Rb₂) may be identical to or different from each other. Further, the plurality of present substituents (Rb₂) may be bonded to each other to thereby form a ring.

The repeating unit having a lactone structure or sultone structure is generally present in the form of optical isomers. Any of the optical isomers may be used. It is both appropriate to use a single type of optical isomer alone and to use a plurality of optical isomers in the form of a mixture. When a single type of optical isomer is mainly used, the optical purity (ee) thereof is preferably 90% or higher, more preferably 95% or higher.

As the repeating unit having a lactone structure or sultone structure, it is preferred for the resin (A) to contain any of the repeating units represented by general formula (AII) below.

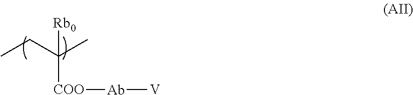

In general formula (AII),

Rb₀ represents a hydrogen atom, a halogen atom or an optionally substituted alkyl group (preferably having 1 to 4 carbon atoms).

As preferred substituents that may be introduced in the alkyl group represented by Rb₀, there can be mentioned a hydroxyl group and a halogen atom. As the halogen atom represented by Rb₀, there can be mentioned a fluorine atom, a chlorine atom, a bromine atom or an iodine atom. Rb₀ is preferably a hydrogen atom, a methyl group, a hydroxymethyl group or a trifluoromethyl group. A hydrogen atom and a methyl group are especially preferred.

Ab represents a single bond, an alkylene group, a bivalent connecting group with a mono- or polycycloalkyl structure, an ether bond, an ester bond, a carbonyl group, or a bivalent connecting group resulting from combination of these. Ab is preferably a single bond or any of the bivalent connecting groups of the formula -Ab₁-CO₂—.

Ab₁ represents a linear or branched alkylene group or a mono- or polycycloalkylene group, preferably a methylene group, an ethylene group, a cyclohexylene group, an adamantylene group or a norbornylene group.

V represents a group with a lactone structure or sultone structure, for example, a group with any of the structures of general formulae (LC1-1) to (LC1-17) and (SL1-1) to (SL1-3) above.

When the resin (P) comprises a repeating unit with a lactone structure or sultone structure, the content of repeating unit with a lactone structure or sultone structure based on all the repeating units of the resin (P) is preferably in the range of 0.5 to 80 mol %, more preferably 1 to 65 mol %, further more preferably 5 to 60 mol %, especially further more preferably 3 to 50 mol %, and most preferably 10 to 50 mol %. Any one of the repeating units each with a lactone structure or sultone structure may be used alone, or two or more thereof may be used in combination.

Particular examples of the repeating units each with a lactone structure or sultone structure are shown below, which in no way limit the scope of the present invention.

In the following particular examples, Rx represents H, CH₃, CH₂OH or CF₃.

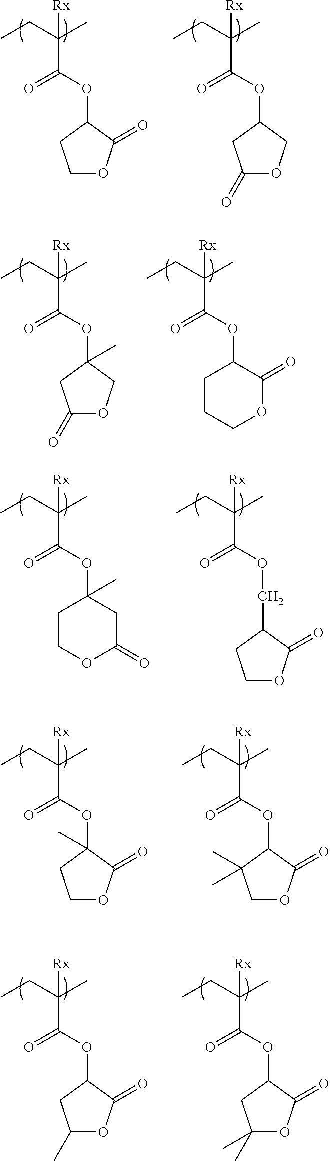

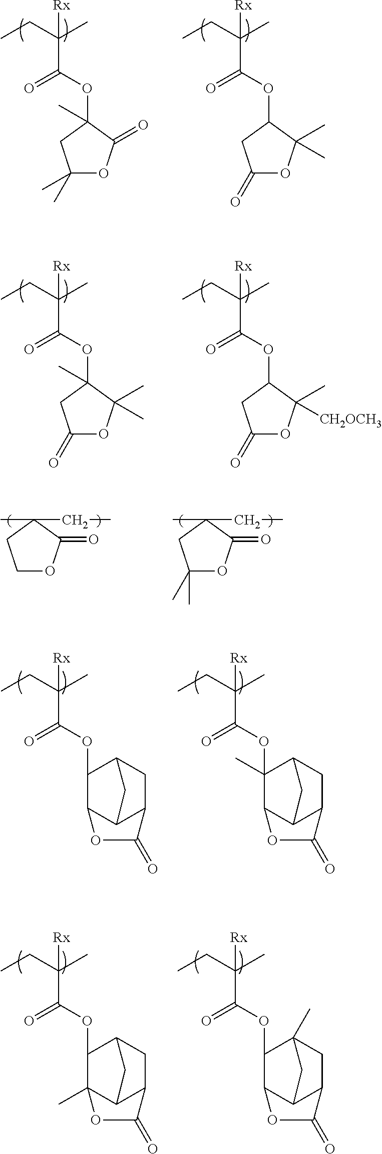

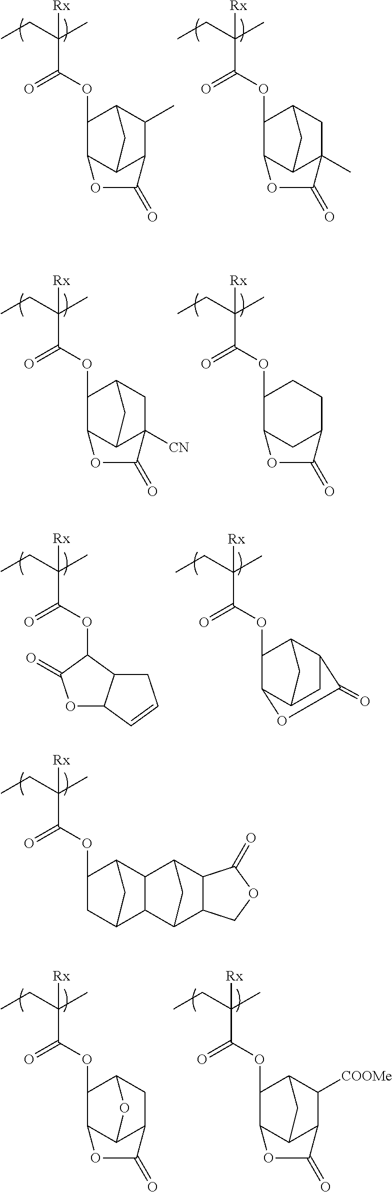

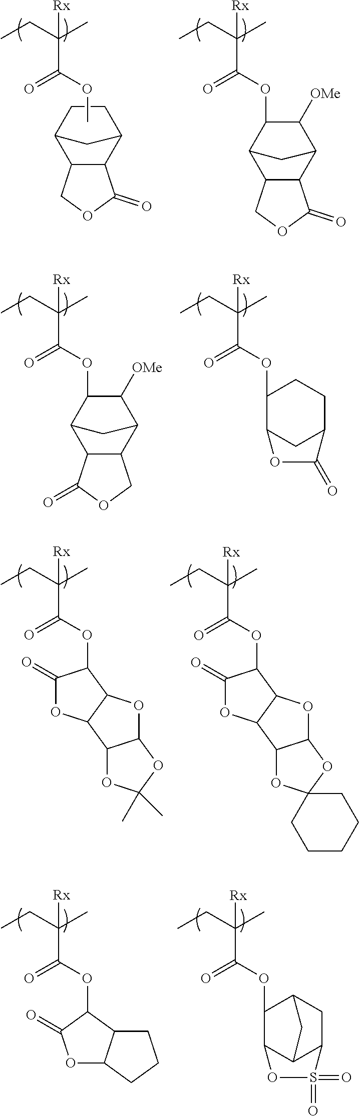

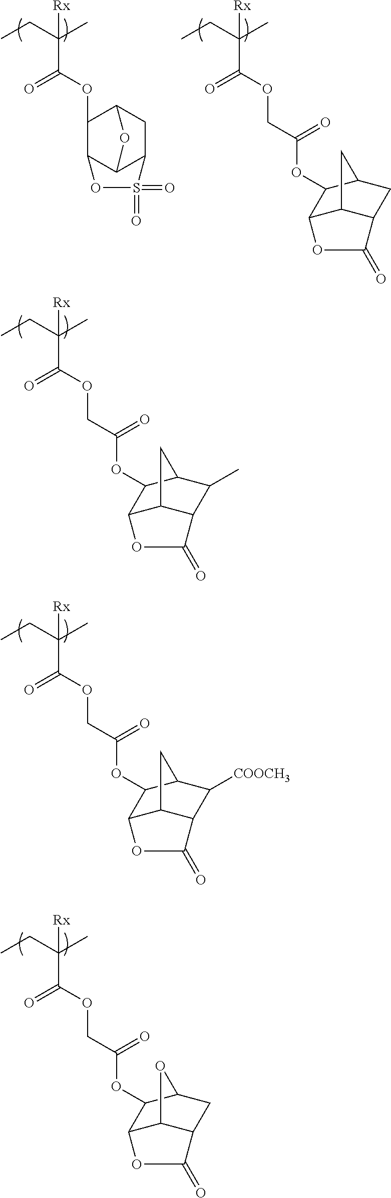

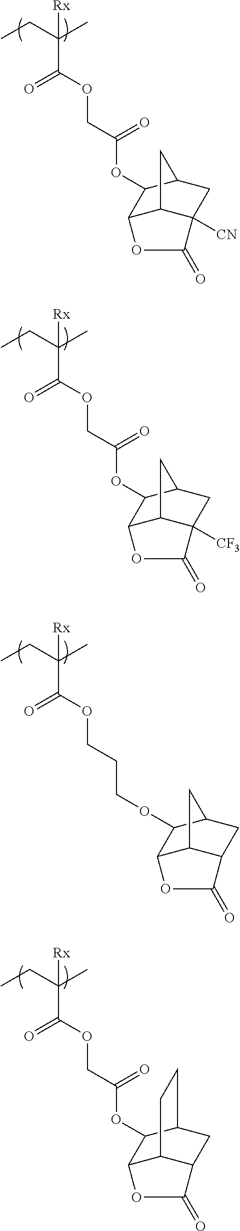

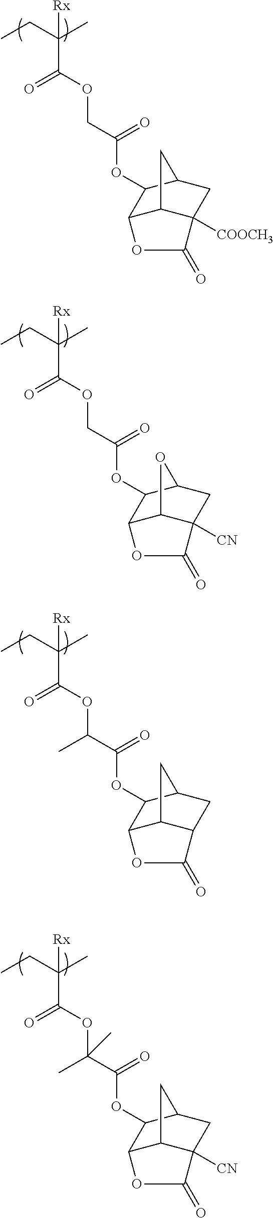

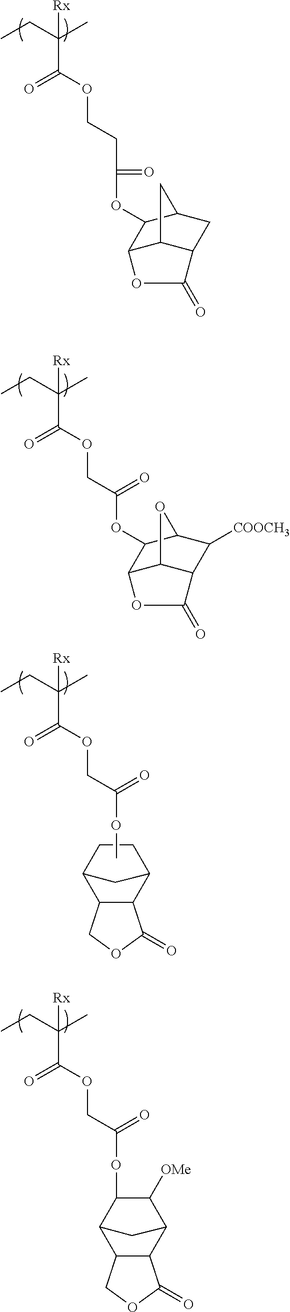

(c) Repeating Unit Containing Hydroxyl Group or Cyano Group

The resin (P) may further comprise a repeating 5 unit containing a hydroxyl group or a cyano group. This would realize enhancements of the adhesion to substrate and developer affinity. The repeating unit containing a hydroxyl group or a cyano group is preferably a repeating unit having an alicyclic hydrocarbon structure substituted with a hydroxyl group or a cyano group, which repeating unit preferably contains no acid-decomposable group.

It is preferred for the repeating unit with an alicyclic hydrocarbon structure substituted with a hydroxyl group or cyano group to be different from the repeating units of general formula (AII) above.

In the alicyclic hydrocarbon structure substituted with a hydroxyl group or a cyano group, the alicyclic hydrocarbon structure is preferably comprised of an adamantyl group, a diamantyl group or a norbornane group. As more preferred repeating units, there can be mentioned any of the repeating units of general formulae (AIIa) to (AIIc) below.

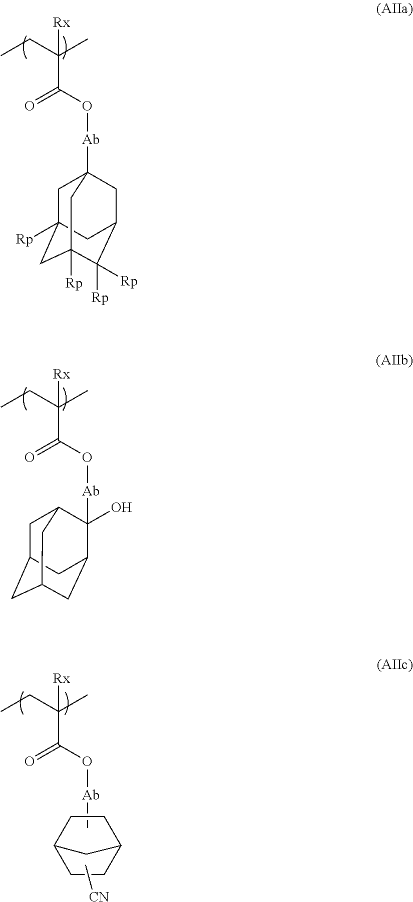

In general formulae (AIIa) to (AIIc),

Rx represents H, CH₃, CH₂OH or CF₃.

Ab is as defined above in connection with general formula (AII).

Each of Rp's represents a hydrogen atom, a hydroxyl group or a hydroxyalkyl group, provided that at least one of Rp's is a hydroxyl group or a hydroxyalkyl group.

It is optional for the resin (P) to comprise the repeating unit containing a hydroxyl group or a cyano group. When the repeating unit containing a hydroxyl group or a cyano group is contained in the resin (P), the content thereof, based on all the repeating units of resin (P), is preferably in the range of 1 to 40 mol %, more preferably 3 to 30 mol % and further more preferably 5 to 25 mol %.

Specific examples of the repeating units each containing a hydroxyl group or a cyano group are shown below, which however in no way limit the scope of the present invention.

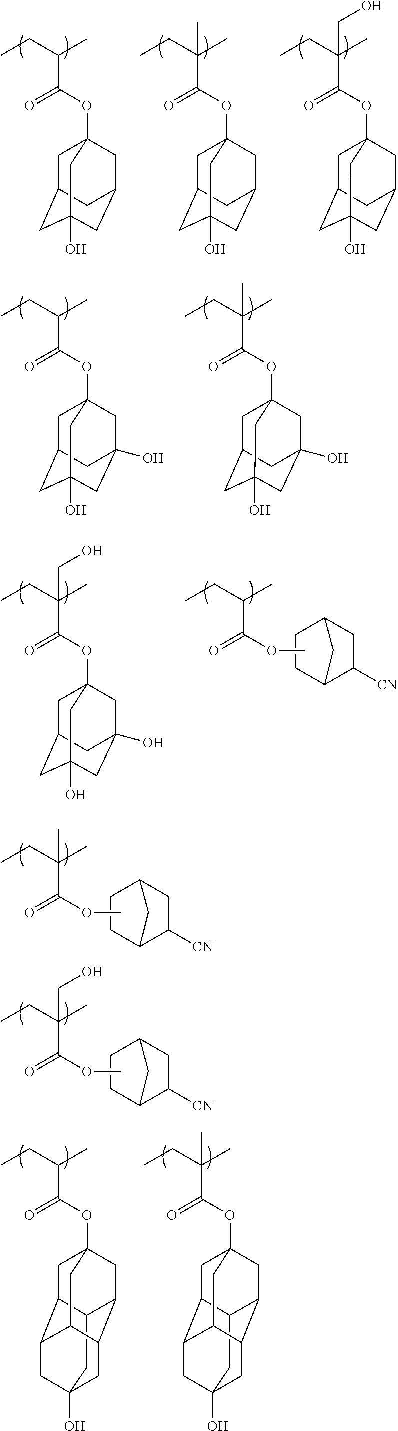

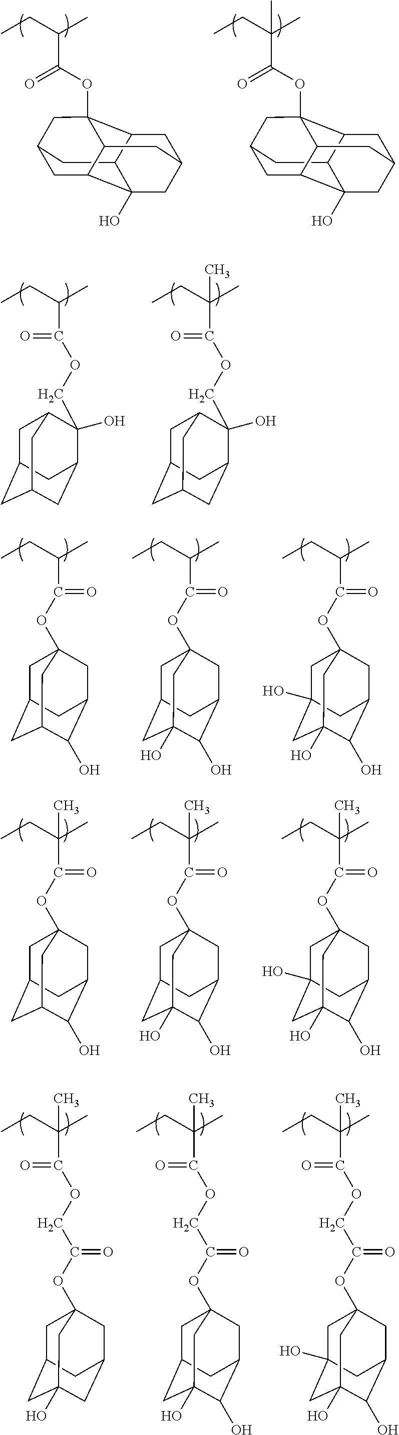

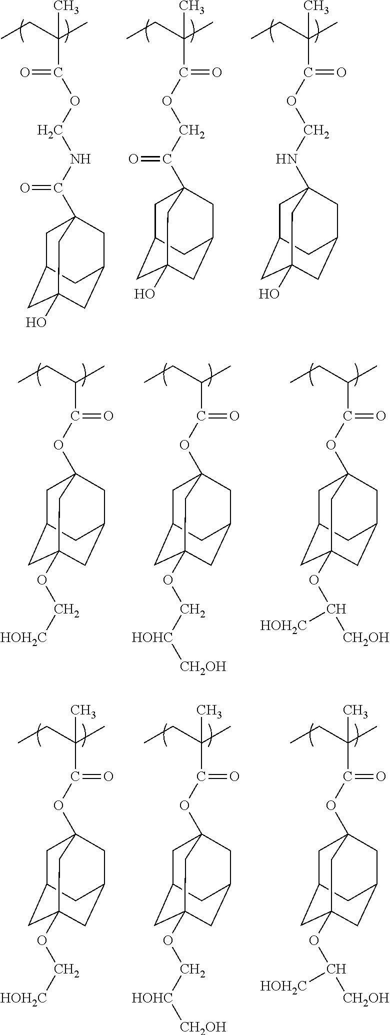

(d) Repeating Unit Containing Acid Group

The resin (P) may comprise a repeating unit containing an acid group. As the acid group, there can be mentioned a carboxyl group, a sulfonamido group, a sulfonylimido group, a bisulfonylimido group or an aliphatic alcohol substituted at its α-position with an electron-withdrawing group (for example, a hexafluoroisopropanol group). It is preferred to comprise a repeating unit containing a carboxyl group. The incorporation of the repeating unit containing an acid group would increase the resolution in, for example, contact hole usage. The repeating unit containing an acid group is preferably any of a repeating unit wherein the acid group is directly bonded to the principal chain of a resin such as a repeating unit of acrylic acid or methacrylic acid, a repeating unit wherein the acid group is bonded via a connecting group to the principal chain of a resin and a repeating unit wherein the acid group is introduced in a terminal of a polymer chain by the use of a chain transfer agent or polymerization initiator containing the acid group in the stage of polymerization. The connecting group may have a cyclohydrocarbon structure of a single ring or multiple rings. The repeating unit of acrylic acid or methacrylic acid is especially preferred.

It is optional for the resin (P) to contain the repeating unit containing an acid group. When the repeating unit containing an acid group is contained in the resin (P), the content thereof based on all the repeating units of the resin (P) is preferably 15 mol % or less, more preferably 10 mol % or less. When the repeating unit containing an acid group is contained in the resin (P), the content thereof based on all the repeating units of the resin (P) is usually 1 mol % or above.

Specific examples of the repeating units each containing an acid group are shown below, which however in no way limit the scope of the present invention.

In the specific examples, Rx represents H, CH₃, CH₂OH or CF₃.

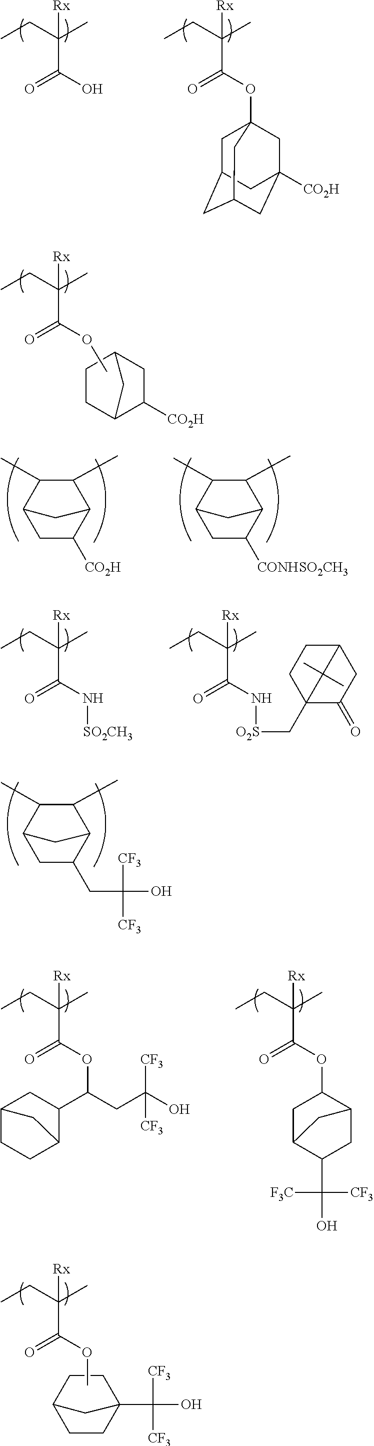

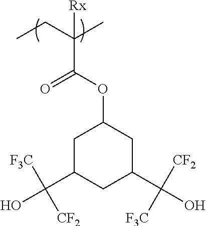

In the resin (P) for use in the composition of the present invention, the molar ratios of individual repeating structural units contained are appropriately determined from the viewpoint of regulating the dry etching resistance, standard developer adaptability, substrate adhesion and resist profile of the actinic-ray- or radiation-sensitive resin composition and generally required properties of the resist such as resolving power, heat resistance and sensitivity.

The resin (P) according to the present invention may have any of the random, block, comb and star forms. The resin (P) can be synthesized by, for example, the radical, cation or anion polymerization of unsaturated monomers corresponding to given structures. Alternatively, the intended resin can be obtained by first polymerizing unsaturated monomers corresponding to the precursors of given structures and thereafter carrying out a polymer reaction.

When the composition of the present invention is one for ArF exposure, from the viewpoint of transparency to ArF light, it is preferred for the resin (P) for use in the composition of the present invention to contain substantially no aromatic ring (in particular, the ratio of repeating unit containing an aromatic group in the resin is preferably 5 mol % or less, more preferably 3 mol % or less, and ideally 0 mol %, namely, containing no aromatic group). It is preferred for the resin (P) to have a mono- or polyalicyclic hydrocarbon structure.

When the composition of the present invention contains a hydrophobic resin (HR) to be described hereinafter, it is preferred for the resin (A) to contain neither a fluorine atom nor a silicon atom from the viewpoint of the compatibility with the hydrophobic resin (HR).

In the resin (P) for use in the composition of the present invention, preferably, all the repeating units thereof are comprised of (meth)acrylate repeating units. In that instance, use can be made of any of a resin wherein all the repeating units are comprised of methacrylate repeating units, a resin wherein all the repeating units are comprised of acrylate repeating units and a resin wherein all the repeating units are comprised of methacrylate repeating units and acrylate repeating units. However, it is preferred for the acrylate repeating units to account for 50 mol % or less of all the repeating units. It is also preferred to employ a copolymer comprising 20 to 50 mol % of (meth)acrylate repeating units containing an acid-decomposable group, 20 to 50 mol % of (meth)acrylate repeating units containing a lactone group, 5 to 30 mol % of (meth)acrylate repeating units containing an alicyclic hydrocarbon structure substituted with a hydroxyl group or a cyano group and 0 to 20 mol % of other (meth)acrylate repeating units.

In the event of exposing the composition of the present invention to KrF excimer laser beams, electron beams, X-rays or high-energy light rays of wavelength 50 nm or less (EUV, etc.), it is preferred for the resin (P) to further comprise a hydroxystyrene repeating unit. More preferably, the resin (A) comprises a hydroxystyrene repeating unit, a hydroxystyrene repeating unit protected by an acid-decomposable group and an acid-decomposable repeating unit of a (meth)acrylic acid tertiary alkyl ester, etc.

As preferred hydroxystyrene repeating units containing an acid-decomposable group, there can be mentioned, for example, repeating units derived from t-butoxycarbonyloxystyrene, a 1-alkoxyethoxystyrene and a (meth)acrylic acid tertiary alkyl ester. Repeating units derived from a 2-alkyl-2-adamantyl(meth)acrylate and a dialkyl(1-adamantyl)methyl(meth)acrylate are more preferred.

The resin (P) according to the present invention can be synthesized in accordance with routine methods (for example, radical polymerization). As general synthesizing methods, there can be mentioned, for example, a batch polymerization method in which a monomer species and an initiator are dissolved in a solvent and heated to thereby carry out polymerization, a dropping polymerization method in which a solution of monomer species and initiator is dropped into a heated solvent over a period of 1 to 10 hours, and the like. The dropping polymerization method is preferred. As a reaction solvent, there can be mentioned, for example, an ether such as tetrahydrofuran, 1,4-dioxane or diisopropyl ether, a ketone such as methyl ethyl ketone or methyl isobutyl ketone, an ester solvent such as ethyl acetate, an amide solvent such as dimethylformamide or dimethylacetamide, or the solvent capable of dissolving the composition of the present invention, such as propylene glycol monomethyl ether acetate, propylene glycol monomethyl ether or cyclohexanone, to be described hereinafter. Preferably, the polymerization is carried out with the use of the same solvent as that used in the actinic-ray- or radiation-sensitive resin composition of the present invention. This would inhibit any particle generation during storage.

The polymerization reaction is preferably carried out in an atmosphere comprised of an inert gas, such as nitrogen or argon. The polymerization is initiated by use of a commercially available radical initiator (azo initiator, peroxide, etc.) as a polymerization initiator. Among the radical initiators, an azo initiator is preferred, and azo initiators having an ester group, a cyano group and a carboxyl group are especially preferred. As specific preferred initiators, there can be mentioned azobisisobutyronitrile, azobisdimethylvaleronitrile, dimethyl 2,2′-azobis(2-methylpropionate) and the like. If desirable, the initiator may be supplemented, or may be added in fractional amounts. After the completion of the reaction, the reaction liquid is poured into a solvent, and the intended polymer is recovered by a method of powder or solid recovery or the like. The reaction concentration is in the range of 5 to 50 mass %, preferably 10 to 30 mass %. The reaction temperature is generally in the range of 10 to 150° C., preferably 30 to 120° C. and more preferably 60 to 100° C.

After the completion of the reaction, the reaction mixture is allowed to stand still to cool to room temperature and purified. In the purification, use can be made of routine methods, such as a liquid-liquid extraction method in which residual monomers and oligomer components are removed by water washing or by the use of a combination of appropriate solvents, a method of purification in solution form such as ultrafiltration capable of extraction removal of only components of a given molecular weight or below, a re-precipitation method in which a resin solution is dropped into a poor solvent to thereby coagulate the resin in the poor solvent and thus remove residual monomers, etc., and a method of purification in solid form such as washing of a resin slurry obtained by filtration with the use of a poor solvent. For example, the reaction solution is brought into contact with a solvent wherein the resin is poorly soluble or insoluble (poor solvent) amounting to 10 or less, preferably 10 to 5 times the volume of the reaction solution to thereby precipitate the resin as a solid.

The solvent for use in the operation of precipitation or re-precipitation from a polymer solution (precipitation or re-precipitation solvent) is not limited as long as the solvent is a poor solvent for the polymer. Use can be made of any solvent appropriately selected from among a hydrocarbon, a halogenated hydrocarbon, a nitro compound, an ether, a ketone, an ester, a carbonate, an alcohol, a carboxylic acid, water, a mixed solvent containing these solvents and the like, according to the type of the polymer. Of these, it is preferred to employ a solvent containing at least an alcohol (especially methanol or the like) or water as the precipitation or re-precipitation solvent.

The amount of precipitation or re-precipitation solvent used can be appropriately selected taking efficiency, yield, etc. into account. Generally, the amount is in the range of 100 to 10,000 parts by mass, preferably 200 to 2000 parts by mass and more preferably 300 to 1000 parts by mass per 100 parts by mass of polymer solution.

The temperature at which the precipitation or re-precipitation is carried out can be appropriately selected taking efficiency and operation easiness into account. Generally, the temperature is in the range of about 0 to 50° C., preferably about room temperature (for example, about 20 to 35° C.). The operation of precipitation or re-precipitation can be carried out by a routine method, such as a batch or continuous method, with the use of a customary mixing container, such as an agitation vessel.

The polymer resulting from the precipitation or re-precipitation is generally subjected to customary solid/liquid separation, such as filtration or centrifugal separation, and dried before use. The filtration is carried out with the use of a filter medium ensuring solvent resistance, preferably under pressure. The drying is performed at about 30 to 100° C., preferably about 30 to 50° C. under ordinary pressure or reduced pressure (preferably reduced pressure).

Alternatively, after the precipitation and separation of the resin, the resultant resin may be once more dissolved in a solvent and brought into contact with a solvent in which the resin is poorly soluble or insoluble. Specifically, the method may include the operations of, after the completion of the radical polymerization reaction, bringing the polymer into contact with a solvent wherein the polymer is poorly soluble or insoluble to thereby attain resin precipitation (operation a), separating the resin from the solution (operation b), re-dissolving the resin in a solvent to thereby obtain a resin solution A (operation c), thereafter bringing the resin solution A into contact with a solvent wherein the resin is poorly soluble or insoluble amounting to less than 10 times (preferably 5 times or less) the volume of the resin solution A to thereby precipitate a resin solid (operation d) and separating the precipitated resin (operation e).

Further, the operation of dissolving a synthesized resin in a solvent to thereby obtain a solution and heating the solution at about 30 to 90° C. for about 30 minutes to 4 hours as described in, for example, JP-A-2009-037108 may be added in order to inhibit any aggregation, etc. of the resin after the preparation of the composition.

The weight average molecular weight of the resin (P) for use in the composition of the present invention, in terms of polystyrene-equivalent value measured by GPC, is preferably in the range of 1000 to 200,000. It is more preferably in the range of 2000 to 100,000, further more preferably 3000 to 70,000 and most preferably 5000 to 50,000. By regulating the weight average molecular weight so as to fall within the range of 1000 to 200,000, not only can any deteriorations of heat resistance and dry etching resistance be prevented but also any deterioration of developability and any increase of viscosity leading to poor film forming property can be prevented.

The polydispersity index (molecular weight distribution) of the resin is generally in the range of 1.0 to 3.0, preferably 1.0 to 2.6, more preferably 1.1 to 2.5, further more preferably 1.2 to 2.4 and most preferably 1.3 to 2.2. Especially preferred use is made of a resin whose polydispersity index is in the range of 1.4 to 2.0. When the molecular weight distribution falls within these ranges, excellent resolution and resist shape can be attained, and the side wall of resist pattern is smooth to thereby ensure excellent roughness characteristics.

In the actinic-ray- or radiation-sensitive resin composition of the present invention, the content of resin (P) in the whole composition is preferably in the range of 30 to 99 mass %, more preferably 60 to 95 mass %, based on the total solids of the composition.

One of the above-mentioned resins (P) according to the present invention may be used alone, or two or more thereof may be used in combination.

[2] Compound (B) that when exposed to actinic rays or radiation, generates an acid

The composition of the present invention may comprise a compound (B) that when exposed to actinic rays or radiation, generates an acid (hereinafter also referred to as an “acid generator” or a “compound (B)”). It is preferred for the compound (B) that when exposed to actinic rays or radiation, generates an acid to be a compound that when exposed to actinic rays or radiation, generates an organic acid.

As the acid generator, use can be made of a member appropriately selected from among a photoinitiator for photocationic polymerization, a photoinitiator for photoradical polymerization, a photo-achromatic agent and photo-discoloring agent for dyes, any of publicly known compounds that when exposed to actinic rays or radiation, generate an acid, employed in microresists, etc., and mixtures thereof.

For example, as the acid generator, there can be mentioned a diazonium salt, a phosphonium salt, a sulfonium salt, an iodonium salt, an imide sulfonate, an oxime sulfonate, diazosulfone, disulfone or o-nitrobenzyl sulfonate.

As preferred compounds among the acid generators, there can be mentioned those of general formulae (ZI), (ZII) and (ZIII) below.

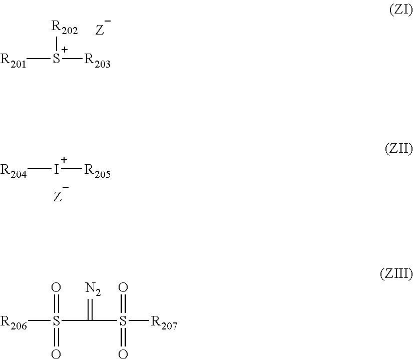

In general formula (ZI) above,

each of R₂₀₁, R₂₀₂ and R₂₀₃ independently represents an organic group.

The number of carbon atoms of each of the organic groups represented by R₂₀₁, R₂₀₂ and R₂₀₃ is generally in the range of 1 to 30, preferably 1 to 20.

Any two of R₂₀₁ to R₂₀₃ may be bonded to each other to thereby form a ring structure, and the ring within the same may contain an oxygen atom, a sulfur atom, an ester bond, an amide bond or a carbonyl group. As a group formed by the mutual bonding of two of R₂₀₁ to R₂₀₃, there can be mentioned an alkylene group (for example, a butylene group or a pentylene group).

Z⁻ represents a normucleophilic anion.

As the normucleophilic anion represented by Z⁻, there can be mentioned, for example, a sulfonate anion, a carboxylate anion, a sulfonylimide anion, a bis(alkylsulfonyl)imide anion, a tris(alkylsulfonyl)methide anion or the like.

The normucleophilic anion means an anion whose capability of inducing a nucleophilic reaction is extremely low and is an anion capable of inhibiting any temporal decomposition by intramolecular nucleophilic reaction. This anion enhances the temporal stability of the actinic-ray- or radiation-sensitive resin composition.

As the sulfonate anion, there can be mentioned, for example, an aliphatic sulfonate anion, an aromatic sulfonate anion, a camphor sulfonate anion or the like.

As the carboxylate anion, there can be mentioned, for example, an aliphatic carboxylate anion, an aromatic carboxylate anion, an aralkyl carboxylate anion or the like.

The aliphatic moiety in the aliphatic sulfonate anion and aliphatic carboxylate anion may be an alkyl group or a cycloalkyl group, being preferably an alkyl group having 1 to 30 carbon atoms or a cycloalkyl group having 3 to 30 carbon atoms. As such, there can be mentioned, for example, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a bornyl group and the like.

As a preferred aromatic group in the aromatic sulfonate anion and aromatic carboxylate anion, there can be mentioned an aryl group having 6 to 14 carbon atoms, for example, a phenyl group, a tolyl group, a naphthyl group or the like.

Substituents may be introduced in the alkyl group, cycloalkyl group and aryl group in the aliphatic sulfonate anion and aromatic sulfonate anion. As the substituents introducible in the alkyl group, cycloalkyl group and aryl group in the aliphatic sulfonate anion and aromatic sulfonate anion, there can be mentioned, for example, a nitro group, a halogen atom (fluorine atom, chlorine atom, bromine atom or iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), a cycloalkylalkyloxyalkyloxy group (preferably having 8 to 20 carbon atoms) and the like. The aryl group or ring structure in these groups may further contain an alkyl group (preferably having 1 to 15 carbon atoms) or a cycloalkyl group (preferably having 3 to 15 carbon atoms) as a substituent.

As a preferred aralkyl group in the aralkyl carboxylate anion, there can be mentioned an aralkyl group having 7 to 12 carbon atoms, for example, a benzyl group, a phenethyl group, a naphthylmethyl group, a naphthylethyl group, a naphthylbutyl group or the like.

Substituents may be introduced in the alkyl group, cycloalkyl group, aryl group and aralkyl group in the aliphatic carboxylate anion, aromatic carboxylate anion and aralkyl carboxylate anion. As the substituents, there can be mentioned, for example, the same halogen atom, alkyl group, cycloalkyl group, alkoxy group, alkylthio group, etc., as mentioned with respect to the aromatic sulfonate anion.

As the sulfonylimide anion, there can be mentioned, for example, a saccharin anion.

The alkyl group in the bis(alkylsulfonyl)imide anion and tris(alkylsulfonyl)methide anion is preferably an alkyl group having 1 to 5 carbon atoms. As such, there can be mentioned, for example, a methyl group, an ethyl group, a propyl group, an isopropyl group, an n-butyl group, an isobutyl group, a sec-butyl group, a pentyl group, a neopentyl group or the like. As substituents introducible in these alkyl groups, there can be mentioned a halogen atom, an alkyl group substituted with a halogen atom, an alkoxy group, an alkylthio group, an alkyloxysulfonyl group, an aryloxysulfonyl group, a cycloalkylaryloxysulfonyl group and the like. An alkyl group substituted with a fluorine atom is preferred.

As other normucleophilic anions, there can be mentioned, for example, phosphorus fluoride (e.g., PF₆⁻), boron fluoride (e.g., BF₄⁻), antimony fluoride (e.g., SbF₆⁻) and the like.

The normucleophilic anion represented by Z⁻ is preferably an aliphatic sulfonate anion whose at least α-position of sulfonic acid is substituted with a fluorine atom, an aromatic sulfonate anion substituted with a fluorine atom or a group containing a fluorine atom, a bis(alkylsulfonyl)imide anion whose alkyl group is substituted with a fluorine atom, or a tris(alkylsulfonyl)methide anion whose alkyl group is substituted with a fluorine atom. More preferably, the normucleophilic anion is a perfluorinated aliphatic sulfonate anion having 4 to 8 carbon atoms, or a benzene sulfonate anion containing a fluorine atom. Further more preferably, the normucleophilic anion is a nonafluorobutanesulfonate anion, a perfluorooctanesulfonate anion, a pentafluorobenzenesulfonate anion or a 3,5-bis(trifluoromethyl)benzenesulfonate anion.

It is preferred for the acid generator to be a compound that when exposed to actinic rays or radiation, generates any of acids of general formulae (IIIB) and (IVB) below. As the compound generates any of acids of general formulae (IIIB) and (IVB) below and hence contains a cyclic organic group, the compound can realize enhanced resolution and roughness characteristics.

The above-mentioned normucleophilic anions can be anions capable of generating any of organic acids of general formulae (IIIB) and (IVB) below.

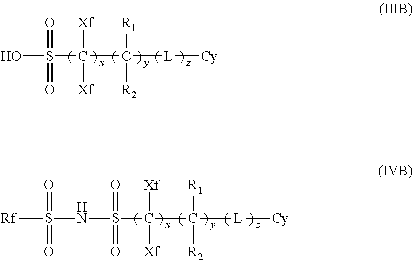

In the above general formulae,

each of Xf's independently represents a fluorine atom or an alkyl group substituted with at least one fluorine atom.

Each of R₁ and R₂ independently represents a hydrogen atom, a fluorine atom or an alkyl group.

L, or each of L's independently, represents a bivalent connecting group.

Cy represents a cyclic organic group.

Rf represents a group containing a fluorine atom.

In the formulae, x is an integer of 1 to 20,

y is an integer of 0 to 10, and

z is an integer of 0 to 10.

Xf represents a fluorine atom or an alkyl group substituted with at least one fluorine atom. This alkyl group preferably has 1 to 10 carbon atoms, more preferably 1 to 4 carbon atoms. The alkyl group substituted with at least one fluorine atom is preferably a perfluoroalkyl group.

Xf is preferably a fluorine atom or a perfluoroalkyl group having 1 to 4 carbon atoms. In particular, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉. Xf is more preferably a fluorine atom or CF₃. Both Xf's being fluorine atoms is most preferred.

Each of R₁ and R₂ independently represents a hydrogen atom, a fluorine atom or an alkyl group. A substituent (preferably a fluorine atom) may be introduced in this alkyl group. This alkyl group preferably has 1 to 4 carbon atoms, being more preferably a perfluoroalkyl group having 1 to 4 carbon atoms. As particular examples of the substituted alkyl groups represented by R₁ and R₂, there can be mentioned CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉. Of these, CF₃ is preferred.

L represents a bivalent connecting group. As the bivalent connecting group, there can be mentioned, for example, —COO—, —OCO—, —CONH—, —NHCO—, —CO—, —O—, —S—, —SO—, —SO₂—, an alkylene group (preferably 1 to 6 carbon atoms), a cycloalkylene group (preferably 3 to 10 carbon atoms), an alkenylene group (preferably 2 to 6 carbon atoms), a bivalent connecting group comprised of a combination of two or more of these, or the like. In particular, —COO—, —OCO—, —CONH—, —NHCO—, —CO—, —O—, —SO₂—, —COO-alkylene-, —OCO-alkylene-, —CONH-alkylene- and —NHCO-alkylene- are preferred. —COO—, —OCO—, —CONH—, —SO₂—, —COO-alkylene- and —OCO-alkylene- are more preferred.

Cy represents a cyclic organic group. As the cyclic organic group, there can be mentioned, for example, an alicyclic group, an aryl group or a heterocyclic group.

The alicyclic group may be monocyclic or polycyclic. As the monoalicyclic group, there can be mentioned, for example, a monocycloalkyl group, such as a cyclopentyl group, a cyclohexyl group or a cyclooctyl group. As the polyalicyclic group, there can be mentioned, for example, a polycycloalkyl group, such as a norbornyl group, a tricyclodecanyl group, a tetracyclodecanyl group, a tetracyclododecanyl group or an adamantyl group. Of the mentioned groups, alicyclic groups with a bulky structure having at least 7 carbon atoms, such as a norbornyl group, a tricyclodecanyl group, a tetracyclodecanyl group, a tetracyclododecanyl group and an adamantyl group, are preferred from the viewpoints of inhibition of any in-film diffusion in the PEB (post-exposure bake) operation and enhancement of MEEF (Mask Error Enhancement Factor).

The aryl group may be monocyclic or polycyclic. As the aryl group, there can be mentioned, for example, a phenyl group, a naphthyl group, a phenanthryl group or an anthryl group. Of these, a naphthyl group exhibiting a relatively low light absorbance at 193 nm is preferred.

The heterocyclic group may be monocyclic or polycyclic. The polycyclic structure is superior in the inhibition of any acid diffusion. It is optional for the heterocyclic group to have aromaticity. As the heterocycle having aromaticity, there can be mentioned, for example, a furan ring, a thiophene ring, a benzofuran ring, a benzothiophene ring, a dibenzofuran ring, a dibenzothiophene ring or a pyridine ring. As the heterocycle having no aromaticity, there can be mentioned, for example, a tetrahydropyran ring, a lactone ring, a sultone ring or a decahydroisoquinoline ring. It is especially preferred for the heterocycle in the heterocyclic group to be a furan ring, a thiophene ring, a pyridine ring or a decahydroisoquinoline ring. As examples of the lactone rings and sultone rings, there can be mentioned the lactone structures and sultone structures set forth above by way of example in connection with the resin (P).

Substituents may be introduced in these cyclic organic groups. As the substituents, there can be mentioned, for example, an alkyl group (may be linear or branched, preferably having 1 to 12 carbon atoms), a cycloalkyl group (may be any of a monocycle, a polycycle and a spiro ring, preferably having 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group and a sulfonic ester group. The carbon (carbon contributing to ring formation) as a constituent of each of the cyclic organic groups, aryl group and heterocyclic group may be a carbonyl carbon.

In the formulae, x is preferably 1 to 8, more preferably 1 to 4 and most preferably 1; y is preferably 0 to 4, more preferably 0; and z is preferably 0 to 8, more preferably 0 to 4 and further more preferably 1.

As the group containing a fluorine atom represented by Rf, there can be mentioned, for example, an alkyl group containing at least one fluorine atom, a cycloalkyl group containing at least one fluorine atom or an aryl group containing at least one fluorine atom.

These alkyl group, cycloalkyl group and aryl group may be substituted with a fluorine atom, or another substituent containing a fluorine atom. When Rf is a cycloalkyl group containing at least one fluorine atom or an aryl group containing at least one fluorine atom, the other substituent containing a fluorine atom can be, for example, an alkyl group substituted with at least one fluorine atom.

Further, these alkyl group, cycloalkyl group and aryl group may further be substituted with a substituent containing no fluorine atom. As this substituent, there can be mentioned, for example, any of those mentioned above with respect to Cy wherein no fluorine atom is contained.

As the alkyl group containing at least one fluorine atom represented by Rf, there can be mentioned, for example, any of those mentioned hereinbefore as the alkyl group substituted with at least one fluorine atom, represented by Xf. As the cycloalkyl group containing at least one fluorine atom represented by Rf, there can be mentioned, for example, a perfluorocyclopentyl group or a perfluorocyclohexyl group. As the aryl group containing at least one fluorine atom represented by Rf, there can be mentioned, for example, a perfluorophenyl group.

In the above general formulae, an especially preferred form is one in which x is 1; two Xf's are fluorine atoms; y is 0 to 4; all R₁s and R₂s are hydrogen atoms; and z is 1. In this form, the number of fluorine atoms is small, so that the localization in the surface during the formation of a resist film can be inhibited and the uniform dispersion in the resist film can be facilitated.

As the organic groups represented by R₂₀₁, R₂₀₂ and R₂₀₃, there can be mentioned, for example, corresponding groups in the compounds (ZI-1), (ZI-2), (ZI-3) and (ZI-4) to be described hereinafter.

Use can be made of a compound containing a plurality of structures of general formula (ZI). For example, use can be made of a compound with a structure in which at least one of R₂₀₁ to R₂₀₃ of a compound expressed by general formula (ZI) is bonded through a single bond or a connecting group to at least one of R₂₀₁ to R₂₀₃ of another compound expressed by general formula (ZI).

As further preferred components (ZI), there can be mentioned compounds (ZI-1), (ZI-2), (ZI-3) and (ZI-4) to be described below.

The compound (ZI-1) is any of arylsulfonium compounds of general formula (ZI) above in which at least one of R₂₀₁ to R₂₀₃ is an aryl group, namely, a compound containing an arylsulfonium as a cation.

In the arylsulfonium compound, all of R₂₀₁ to R₂₀₃ may be aryl groups. Alternatively, R₂₀₁ to R₂₀₃ may be an aryl group in part and may be an alkyl group or a cycloalkyl group in the remainder.

As the arylsulfonium compound, there can be mentioned, for example, a triarylsulfonium compound, a diarylalkylsulfonium compound, an aryldialkylsulfonium compound, a diarylcycloalkylsulfonium compound or an aryldicycloalkylsulfonium compound.

The aryl group in the arylsulfonium compound is preferably a phenyl group or a naphthyl group, more preferably a phenyl group. The aryl group may be one with a heterocyclic structure containing an oxygen atom, a nitrogen atom, a sulfur atom or the like. As the heterocyclic structure, there can be mentioned a pyrrole residue, a furan residue, a thiophene residue, an indole residue, a benzofuran residue, a benzothiophene residue or the like. When the arylsulfonium compound contains two or more aryl groups, the two or more aryl groups may be identical to or different from each other.

The alkyl group or cycloalkyl group contained in the arylsulfonium compound according to necessity is preferably a linear or branched alkyl group having 1 to 15 carbon atoms or a cycloalkyl group having 3 to 15 carbon atoms. As such, there can be mentioned, for example, a methyl group, an ethyl group, a propyl group, an n-butyl group, a sec-butyl group, a t-butyl group, a cyclopropyl group, a cyclobutyl group, a cyclohexyl group or the like.

Each of the aryl groups, alkyl groups and cycloalkyl groups represented by R₂₀₁ to R₂₀₃ may contain as a substituent thereof an alkyl group (for example, 1 to 15 carbon atoms), a cycloalkyl group (for example, 3 to 15 carbon atoms), an aryl group (for example, 6 to 14 carbon atoms), an alkoxy group (for example, 1 to 15 carbon atoms), a halogen atom, a hydroxyl group or a phenylthio group. Preferred substituents are a linear or branched alkyl group having 1 to 12 carbon atoms, a cycloalkyl group having 3 to 12 carbon atoms and a linear, branched or cyclic alkoxy group having 1 to 12 carbon atoms. An alkyl group having 1 to 4 carbon atoms and an alkoxy group having 1 to 4 carbon atoms are more preferred. Each of the substituents may be introduced in any one of the three R₂₀₁ to R₂₀₃, or alternatively may be introduced in all of the three R₂₀₁ to R₂₀₃. When R₂₀₁ to R₂₀₃ represent aryl groups, each of the substituents is preferably introduced in the p-position of the aryl group.

Now, the compound (ZI-2) will be described.

The compound (ZI-2) is any of those of general formula (ZI) wherein each of R₂₀₁ to R₂₀₃ independently represents an organic group containing no aromatic ring. The aromatic rings include an aromatic ring containing a heteroatom.

Each of the organic groups containing no aromatic ring represented by R₂₀₁ to R₂₀₃ generally has 1 to 30 carbon atoms, preferably 1 to 20 carbon atoms.

Preferably, each of R₂₀₁ to R₂₀₃ independently represents an alkyl group, a cycloalkyl group, an allyl group or a vinyl group. A linear or branched 2-oxoalkyl group, a 2-oxocycloalkyl group and an alkoxycarbonylmethyl group are more preferred. A linear or branched 2-oxoalkyl group is most preferred.

As preferred alkyl groups and cycloalkyl groups represented by R₂₀₁ to R₂₀₃, there can be mentioned a linear or branched alkyl group having 1 to 10 carbon atoms (for example, a methyl group, an ethyl group, a propyl group, a butyl group or a pentyl group) and a cycloalkyl group having 3 to 10 carbon atoms (a cyclopentyl group, a cyclohexyl group or a norbornyl group). The alkyl group is more preferably a 2-oxoalkyl group or an alkoxycarbonylmethyl group. The cycloalkyl group is more preferably a 2-oxocycloalkyl group.

The 2-oxoalkyl group may be linear or branched, preferably being a group resulting from the introduction of >C═O in the 2-position of any of the above alkyl groups.

The 2-oxocycloalkyl group is preferably a group resulting from the introduction of >C═O in the 2-position of any of the above cycloalkyl groups.

As preferred alkoxy groups in the alkoxycarbonylmethyl groups, there can be mentioned alkoxy groups each having 1 to 5 carbon atoms (a methoxy group, an ethoxy group, a propoxy group, a butoxy group and a pentoxy group).

These R₂₀₁ to R₂₀₃ may be further substituted with a halogen atom, an alkoxy group (for example, 1 to 5 carbon atoms), a hydroxyl group, a cyano group or a nitro group.

The compound (ZI-3) will be described below.

The compound (ZI-3) is any of compounds of general formula (ZI-3) below, being a compound with a phenacylsulfonium salt structure.

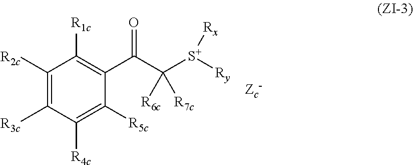

In general formula (ZI-3),

each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Each of R_{6c} and R_{7c} independently represents a hydrogen atom, an alkyl group, a cycloalkyl group, a halogen atom, a cyano group or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group or a vinyl group.

Any two or more of R_{1c} to R_{5c}, R_{5c} and R_{6c}, R_{6c} and R_{7c}, R_{5c} and Rx, and Rx and Ry may be bonded to each other to thereby form a ring structure, in which an oxygen atom, a sulfur atom, a ketone group, an ester bond and/or an amide bond may be contained.

As the above ring structure, there can be mentioned an aromatic or nonaromatic hydrocarbon ring, an aromatic or nonaromatic heterocycle, or a polycyclic condensed ring comprised of a combination of two or more of these. As the ring structure, there can be mentioned a 3- to 10-membered ring. A 4- to 8-membered ring is preferred. A 5- or 6-membered ring is more preferred.

As the group formed by the mutual bonding of any two or more of R_{1c} to R_{5c}, R_{6c} and R_{7c}, or Rx and Ry, there can be mentioned a butylene group, a pentylene group or the like.

The group formed by the mutual bonding of R_{5c} and R_{6c}, or R_{5c} and Rx, is preferably a single bond or an alkylene group. As the alkylene group, there can be mentioned a methylene group, an ethylene group or the like.

Zc⁻ represents a normucleophilic anion, which is the same as mentioned above in connection with Z⁻ in general formula (ZI).

Each of the alkyl groups represented by R_{1c} to R_{7c} may be linear or branched. As such, there can be mentioned, for example, an alkyl group having 1 to 20 carbon atoms, preferably a linear or branched alkyl group having 1 to 12 carbon atoms (for example, a methyl group, an ethyl group, a linear or branched propyl group, a linear or branched butyl group or a linear or branched pentyl group). As the cycloalkyl group, there can be mentioned, for example, a cycloalkyl group having 3 to 10 carbon atoms (for example, a cyclopentyl group or a cyclohexyl group).

Each of the aryl groups represented by R_{1c} to R_{5c} preferably has 5 to 15 carbon atoms. For example, there can be mentioned a phenyl group or a naphthyl group.

Each of the alkoxy groups represented by R_{1c} to R_{5c} may be linear, or branched, or cyclic. As such, there can be mentioned, for example, an alkoxy group having 1 to 10 carbon atoms, preferably a linear or branched alkoxy group having 1 to 5 carbon atoms (for example, a methoxy group, an ethoxy group, a linear or branched propoxy group, a linear or branched butoxy group or a linear or branched pentoxy group), and a cycloalkoxy group having 3 to 10 carbon atoms (for example, a cyclopentyloxy group or a cyclohexyloxy group).

Particular examples of the alkoxy groups in the alkoxycarbonyl groups represented by R_{1c} to R_{5c} are the same as those of the alkoxy groups represented by R_{1c} to R_{5c}.

Particular examples of the alkyl groups in the alkylcarbonyloxy groups and alkylthio groups represented by R_{1c} to R_{5c} are the same as those of the alkyl groups represented by R_{1c} to R_{5c}.

Particular examples of the cycloalkyl groups in the cycloalkylcarbonyloxy groups represented by R_{1c} to R_{5c} are the same as those of the cycloalkyl groups represented by R_{1c} to R_{5c}.

Particular examples of the aryl groups in the aryloxy groups and arylthio groups represented by R_{1c} to R_{5c} are the same as those of the aryl groups represented by R_{1c} to R_{5c}.

Preferably, any one of R_{1c} to R_{5c} is a linear or branched alkyl group, a cycloalkyl group or a linear, branched or cyclic alkoxy group. More preferably, the sum of carbon atoms of R_{1c} to R_{5c} is in the range of 2 to 15. Accordingly, there can be attained an enhancement of solvent solubility and inhibition of particle occurrence during storage.

The ring structure that may be formed by the mutual bonding of any two or more of R_{1c} to R_{5c} is preferably a 5- or 6-membered ring, most preferably a 6-membered ring (for example, a phenyl ring).

As the ring structure that may be formed by the mutual bonding of R_{5c} and R_{6c}, there can be mentioned a 4- or more membered ring (most preferably a 5- or 6-membered ring) formed in cooperation with the carbonyl carbon atom and carbon atom in general formula (I) by virtue of the formation of a single bond or an alkylene group (a methylene group, an ethylene group or the like) through the mutual bonding of R_{5c} and R_{6c}.

Each of the aryl groups represented by R_{6c} and R_{7c} preferably has 5 to 15 carbon atoms. For example, there can be mentioned a phenyl group or a naphthyl group.

With respect to forms of R_{6c} and R_{7c}, it is preferred for both thereof to be alkyl groups. In particular, it is preferred for each of R_{6c} and R_{7c} to be a linear or branched alkyl group having 1 to 4 carbon atoms. It is especially preferred for both thereof to be methyl groups.

When R_{6c} and R_{7c} are bonded to each other to thereby form a ring, the group formed by the mutual bonding of R_{6c} and R_{7c} is preferably an alkylene group having 2 to 10 carbon atoms. As such, there can be mentioned, for example, an ethylene group, a propylene group, a butylene group, a pentylene group, a hexylene group or the like. Further, the ring formed by the mutual bonding of R_{6c} and R_{7c} may contain a heteroatom, such as an oxygen atom, within the ring.

As the alkyl groups and cycloalkyl groups represented by Rₓ and R_{y}, there can be mentioned the same alkyl groups and cycloalkyl groups as set forth above with respect to R_{1c} to R_{7c}.

As the 2-oxoalkyl group and 2-oxocycloalkyl group represented by Rₓ and R_{y}, there can be mentioned the alkyl group and cycloalkyl group represented by R_{1c} to R_{7c} having >C═O introduced in the 2-position thereof.

With respect to the alkoxy group in the alkoxycarbonylalkyl groups represented by Rₓ and R_{y}, there can be mentioned the same alkoxy groups as mentioned above with respect to R_{1c} to R_{5c}. As the alkyl group thereof, there can be mentioned, for example, an alkyl group having 1 to 12 carbon atoms, preferably a linear alkyl group having 1 to 5 carbon atoms (e.g., a methyl group or an ethyl group).

The allyl groups represented by Rₓ and R_{y} are not particularly limited. However, preferred use is made of an unsubstituted allyl group or an allyl group substituted with a mono- or polycycloalkyl group (preferably a cycloalkyl group having 3 to 10 carbon atoms).

The vinyl groups represented by Rₓ and R_{y} are not particularly limited. However, preferred use is made of an unsubstituted vinyl group or a vinyl group substituted with a mono- or polycycloalkyl group (preferably a cycloalkyl group having 3 to 10 carbon atoms).

As the ring structure that may be formed by the mutual bonding of R_{5c} and Rₓ, there can be mentioned a 5- or more membered ring (most preferably a 5-membered ring) formed in cooperation with the sulfur atom and carbonyl carbon atom in general formula (I) by virtue of the formation of a single bond or an alkylene group (a methylene group, an ethylene group or the like) through the mutual bonding of R_{5c} and Rₓ.

As the ring structure that may be formed by the mutual bonding of Rₓ and R_{y}, there can be mentioned a 5-membered or 6-membered ring, most preferably a 5-membered ring (namely, a tetrahydrothiophene ring), formed by bivalent Rₓ and R_{y} (for example, a methylene group, an ethylene group, a propylene group or the like) in cooperation with the sulfur atom in general formula (ZI-3) above. An oxygen atom is preferably introduced in the ring formed by the mutual bonding of Rₓ and R_{y}.

Each of Rₓ and R_{y} is preferably an alkyl group or cycloalkyl group having 4 or more carbon atoms, more preferably 6 or more carbon atoms and further more preferably 8 or more carbon atoms.

A substituent may further be introduced in each of the groups represented by R_{1c} to R_{7c}, Rₓ and R_{y}. As such a substituent, there can be mentioned a halogen atom (for example, a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, an aryloxycarbonyloxy group or the like.

In general formula (ZI-3) above, preferably, each of R_{1c}, R_{2c}, R_{4c} and R_{5c} independently is a hydrogen atom, and R_{3c} is a non-hydrogen-atom group, namely, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

As the cations in the compounds (ZI-2) and (ZI-3) according to the present invention, there can be mentioned the cations described in section [0036] et seq. of US Patent Application Publication 2012/0076996.

The compounds (ZI-4) will be described below.

The compounds (ZI-4) are expressed by general formula (ZI-4) below.

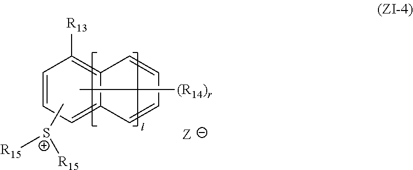

In general formula (ZI-4),

R₁₃ represents a hydrogen atom, a fluorine atom, a hydroxyl group, an alkyl group, a cycloalkyl group, an alkoxy group, an alkoxycarbonyl group or a group containing a cycloalkyl group. Substituents may be introduced in these groups.

R₁₄, or each of R₁₄s independently, represents a hydroxyl group, an alkyl group, a cycloalkyl group, an alkoxy group, an alkoxycarbonyl group, an alkylcarbonyl group, an alkylsulfonyl group, a cycloalkylsulfonyl group or a group containing a cycloalkyl group.

Substituents may be introduced in these groups. Each of R₁₅s independently represents an alkyl group, a cycloalkyl group or a naphthyl group, provided that two R₁₅s may be bonded to each other to thereby form a ring. Substituents may be introduced in these groups.

In the formula, 1 is an integer of 0 to 2, and

r is an integer of 0 to 8.

Z⁻ represents a normucleophilic anion, which is the same as set forth above in connection with Z⁻ in general formula (ZI).

Each of the alkyl groups represented by R₁₃, R₁₄ and R₁₅ in general formula (ZI-4) is linear or branched, preferably having 1 to 10 carbon atoms. A methyl group, an ethyl group, an n-butyl group, a t-butyl group and the like are preferred.

As the cycloalkyl groups represented by R₁₃, R₁₄ and R₁₅, there can be mentioned mono- and polycycloalkyl groups (preferably a cycloalkyl group having 3 to 20 carbon atoms). In particular, cyclopropyl, cyclopentyl, cyclohexyl, cycloheptyl and cyclooctyl are preferred.

Each of the alkoxy groups represented by R₁₃ and R₁₄ is linear or branched, preferably having 1 to 10 carbon atoms. A methoxy group, an ethoxy group, an n-propoxy group, an n-butoxy group and the like are preferred.

Each of the alkoxycarbonyl groups represented by R₁₃ and R₁₄ is linear or branched, preferably having 2 to 11 carbon atoms. A methoxycarbonyl group, an ethoxycarbonyl group, an n-butoxycarbonyl group and the like are preferred.

As the groups containing a cycloalkyl group represented by R₁₃ and R₁₄, there can be mentioned mono- and polycycloalkyl groups (preferably a cycloalkyl group having 3 to 20 carbon atoms). For example, there can be mentioned a mono- and polycycloalkyloxy group and an alkoxy group containing a mono- and polycycloalkyl group. Substituents may further be introduced in these groups.

Each of the mono- and polycycloalkyloxy groups represented by R₁₃ and R₁₄ preferably has 7 or more carbon atoms in total, more preferably 7 to 15 carbon atoms in total. Preferably, a monocycloalkyl group is contained therein. The monocycloalkyloxy group having 7 or more carbon atoms in total refers to a monocycloalkyloxy group comprised of a cycloalkyloxy group, such as a cyclopropyloxy group, a cyclobutyloxy group, a cyclopentyloxy group, a cyclohexyloxy group, a cycloheptyloxy group, a cyclooctyloxy group or a cyclododecanyloxy group, optionally substituted with an alkyl group such as methyl, ethyl, propyl, butyl, pentyl, hexyl, heptyl, octyl, dodecyl, 2-ethylhexyl, isopropyl, sec-butyl, t-butyl or isoamyl, a hydroxyl group, a halogen atom (fluorine, chlorine, bromine or iodine), a nitro group, a cyano group, an amido group, a sulfonamido group, an alkoxy group such as methoxy, ethoxy, hydroxyethoxy, propoxy, hydroxypropoxy or butoxy, an alkoxycarbonyl group such as methoxycarbonyl or ethoxycarbonyl, an acyl group such as formyl, acetyl or benzoyl, an acyloxy group such as acetoxy or butyryloxy, a carboxyl group or the like, wherein the sum of carbon atoms thereof including those of any optional substituents introduced in the cycloalkyl group is 7 or greater.

As the polycycloalkyloxy group having 7 or more carbon atoms in total, there can be mentioned a norbornyloxy group, a tricyclodecanyloxy group, a tetracyclodecanyloxy group, an adamantyloxy group or the like.

Each of the alkoxy groups containing a mono- and polycycloalkyl group represented by R₁₃ and R₁₄ preferably has 7 or more carbon atoms in total, more preferably 7 to 15 carbon atoms in total. The alkoxy group containing a monocycloalkyl group is preferred. The alkoxy group containing a monocycloalkyl group, which has 7 or more carbon atoms in total, refers to an alkoxy group, such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy or isoamyloxy, substituted with any of the above-mentioned optionally substituted monocycloalkyl groups, wherein the sum of carbon atoms thereof including those of substituents is 7 or greater. For example, there can be mentioned a cyclohexylmethoxy group, a cyclopentylethoxy group, a cyclohexylethoxy group or the like. A cyclohexylmethoxy group is preferred.

As the alkoxy group containing a polycycloalkyl group, which has 7 or more carbon atoms in total, there can be mentioned a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, an adamantylethoxy group or the like. Of these, a norbornylmethoxy group, a norbornylethoxy group and the like are preferred.

With respect to the alkyl group in the alkylcarbonyl group represented by R₁₄, there can be mentioned the same particular examples as mentioned above with respect to the alkyl groups represented by R₁₃ to R₁₅.

Each of the alkylsulfonyl group and cycloalkylsulfonyl group represented by R₁₄ may be linear, branched or cyclic and preferably has 1 to 10 carbon atoms. As preferred examples thereof, there can be mentioned a methanesulfonyl group, an ethanesulfonyl group, an n-propanesulfonyl group, an n-butanesulfonyl group, a cyclopentanesulfonyl group, a cyclohexanesulfonyl group and the like.

As substituents that may be introduced in these groups, there can be mentioned a halogen atom (e.g., a fluorine atom), a hydroxyl group, a carboxyl group, a cyano group, a nitro group, an alkoxy group, an alkoxyalkyl group, an alkoxycarbonyl group, an alkoxycarbonyloxy group and the like.

As the alkoxy group, there can be mentioned, for example, a linear, branched or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group or a cyclohexyloxy group.

As the alkoxyalkyl group, there can be mentioned, for example, a linear, branched or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group or a 2-ethoxyethyl group.

As the alkoxycarbonyl group, there can be mentioned, for example, a linear, branched or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group or a cyclohexyloxycarbonyl group.

As the alkoxycarbonyloxy group, there can be mentioned, for example, a linear, branched or cyclic alkoxycarbonyloxy group having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group or a cyclohexyloxycarbonyloxy group.

As the ring structure that may be formed by the mutual bonding of two R₁₅s, there can be mentioned a 5- or 6-membered ring, most preferably a 5-membered ring (namely, a tetrahydrothiophene ring), formed by two R₁₅s in cooperation with the sulfur atom in general formula (ZI-4). The ring structure may be condensed with an aryl group or a cycloalkyl group. Substituents may be introduced in bivalent R₁₅s. As such substituents, there can be mentioned, for example, a hydroxyl group, a carboxyl group, a cyano group, a nitro group, an alkyl group, a cycloalkyl group, an alkoxy group, an alkoxyalkyl group, an alkoxycarbonyl group, an alkoxycarbonyloxy group and the like. A plurality of substituents may be introduced in the ring structure. The substituents may be bonded to each other to thereby form a ring (e.g., an aromatic or nonaromatic hydrocarbon ring, an aromatic or nonaromatic heterocycle or a polycyclic condensed ring resulting from the combination of two or more mentioned rings).

R₁₅ in general formula (ZI-4) is preferably a methyl group, an ethyl group, a naphthyl group, a bivalent group occurring at the formation of a tetrahydrothiophene ring structure upon the mutual bonding of two R₁₅s in cooperation with the sulfur atom, or the like.

Preferred substituents that can be introduced in R₁₃ and R₁₄ are a hydroxyl group, an alkoxy group, an alkoxycarbonyl group and a halogen atom (especially, a fluorine atom).

In the formula, 1 is preferably 0 or 1, more preferably 1; and

r is preferably from 0 to 2.

As the cations contained in the compounds of general formula (ZI-4) according to the present invention, there can be mentioned those set forth in, for example, sections [0121], [0123] and [0124] of JP-A-2010-256842 and sections [0127], [0129] and [0130] of JP-A-2011-76056.

General formulae (ZII) and (ZIII) will be described below.

In general formulae (ZII) and (ZIII),

each of R₂₀₄ to R₂₀₇ independently represents an aryl group, an alkyl group or a cycloalkyl group.

Each of the aryl groups represented by R₂₀₄ to R₂₀₇ is preferably a phenyl group or a naphthyl group, more preferably a phenyl group. Each of the aryl groups represented by R₂₀₄ to R₂₀₇ may be one having a heterocyclic structure containing an oxygen atom, a nitrogen atom, a sulfur atom or the like. As the skeleton of each of the aryl groups having a heterocyclic structure, there can be mentioned, for example, pyrrole, furan, thiophene, indole, benzofuran, benzothiophene or the like.

As preferred alkyl groups and cycloalkyl groups represented by R₂₀₄ to R₂₀₇, there can be mentioned a linear or branched alkyl group having 1 to 10 carbon atoms (for example, a methyl group, an ethyl group, a propyl group, a butyl group or a pentyl group) and a cycloalkyl group having 3 to 10 carbon atoms (a cyclopentyl group, a cyclohexyl group or a norbornyl group).

Substituents may be introduced in the aryl groups, alkyl groups and cycloalkyl groups represented by R₂₀₄ to R₂₀₇. As the substituents optionally introduced in the aryl groups, alkyl groups and cycloalkyl groups represented by R₂₀₄ to R₂₀₇, there can be mentioned, for example, an alkyl group (for example, 1 to 15 carbon atoms), a cycloalkyl group (for example, 3 to 15 carbon atoms), an aryl group (for example, 6 to 15 carbon atoms), an alkoxy group (for example, 1 to 15 carbon atoms), a halogen atom, a hydroxyl group, a phenylthio group and the like.

Z⁻ represents a normucleophilic anion, which is the same as set forth above in connection with Z⁻ in general formula (ZI).

As further acid generators, there can be mentioned the compounds of general formulae (ZIV), (ZV) and (ZVI) below.

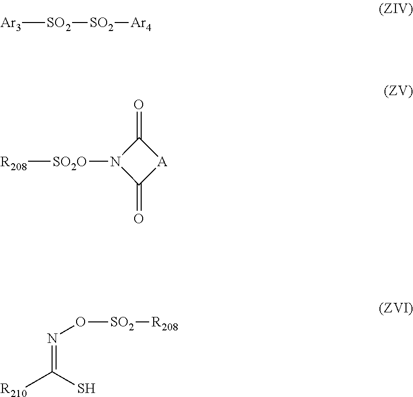

In general formulae (ZIV) to (ZVI),

each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Particular examples of the aryl groups represented by Ar₃, Ar₄, R₂₀₈, R₂₀₉ and R₂₁₀ are the same as set forth above in connection with the aryl groups represented by R₂₀₁, R₂₀₂ and R₂₀₃ in general formula (ZI-1).

Particular examples of the alkyl groups and cycloalkyl groups represented by R₂₀₈, R₂₀₉ and R₂₁₀ are the same as set forth above in connection with the alkyl groups and cycloalkyl groups represented by R₂₀₁, R₂₀₂ and R₂₀₃ in general formula (ZI-2).

As the alkylene group represented by A, there can be mentioned an alkylene group having 1 to 12 carbon atoms (e.g., a methylene group, an ethylene group, a propylene group, an isopropylene group, a butylene group, an isobutylene group or the like). As the alkenylene group represented by A, there can be mentioned an alkenylene group having 2 to 12 carbon atoms (e.g., an ethenylene group, a propenylene group, a butenylene group or the like). As the arylene group represented by A, there can be mentioned an arylene group having 6 to 10 carbon atoms (e.g., a phenylene group, a tolylene group, a naphthylene group or the like).

As still further acid generators, there can be mentioned the compounds of any of general formulae (B-1) to (B-3) below. First, the compounds (B) of general formula (B-1) below will be described.

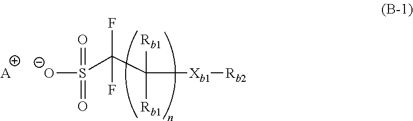

In general formula (B-1) above,

A⁺ represents a sulfonium cation or an iodonium cation.

Each of R_{b1}s independently represents a hydrogen atom, a fluorine atom or a trifluoromethyl group (CF₃); and

n is an integer of 1 to 4.

Preferably, n is an integer of 1 to 3. More preferably, n is 1 or 2.

X_{b1} represents a single bond, an ether bond, an ester bond (—OCO— or —COO—) or a sulfonic ester bond (—OSO₂— or —SO₃—).

X_{b1} is preferably an ester bond (—OCO— or —COO—) or a sulfonic ester bond (—OSO₂— or —SO₃—).

R_{b2} represents a substituent having 6 or more carbon atoms.

It is preferred for the substituent having 6 or more carbon atoms represented by R_{b2} to be a bulky group. As examples thereof, there can be mentioned an alkyl group, an alicyclic group, an aryl group and a heterocyclic group each having 6 or more carbon atoms.

The alkyl group having 6 or more carbon atoms represented by R_{b2} may be linear or branched. A linear or branched alkyl group having 6 to 20 carbon atoms is preferred. As examples thereof, there can be mentioned a linear or branched hexyl group, a linear or branched heptyl group and a linear or branched octyl group. From the viewpoint of bulkiness, branched alkyl groups are preferred.

The alicyclic group having 6 or more carbon atoms represented by R_{b2} may be monocyclic or polycyclic. The monoalicyclic group is, for example, a monocycloalkyl group, such as a cyclohexyl group or a cyclooctyl group. The polyalicyclic group is, for example, a polycycloalkyl group, such as a norbornyl group, a tricyclodecanyl group, a tetracyclodecanyl group, a tetracyclododecanyl group or an adamantyl group. Of the mentioned groups, alicyclic groups each with a bulky structure having 7 or more carbon atoms, such as a norbornyl group, a tricyclodecanyl group, a tetracyclodecanyl group, a tetracyclododecanyl group and an adamantyl group, are preferred from the viewpoint of inhibiting any in-film diffusion in the operation of post-exposure bake (PEB) and enhancing MEEF (mask error enhancement factor).

The aryl group having 6 or more carbon atoms represented by R_{b2} may be monocyclic or polycyclic. As the aryl group, there can be mentioned, for example, a phenyl group, a naphthyl group, a phenanthryl group or an anthryl group. Of these, a naphthyl group exhibiting a relatively low light absorbance at 193 nm is preferred.

The heterocyclic group having 6 or more carbon atoms represented by R_{b2} may be monocyclic or polycyclic. The polycyclic structure is superior in the inhibition of any acid diffusion. It is optional for the heterocyclic group to have aromaticity. As the heterocycle having aromaticity, there can be mentioned, for example, a benzofuran ring, a benzothiophene ring, a dibenzofuran ring or a dibenzothiophene ring. As the heterocycle having no aromaticity, there can be mentioned, for example, a tetrahydropyran ring, a lactone ring or a decahydroisoquinoline ring. It is especially preferred for the heterocycle in the heterocyclic group to be a benzofuran ring or a decahydroisoquinoline ring. As examples of the lactone rings, there can be mentioned the lactone structures set forth above by way of example in connection with the resin (P).

A further substituent may be introduced in the substituent having 6 or more carbon atoms represented by R_{b2}. As the further substituent, there can be mentioned, for example, an alkyl group (may be linear or branched, preferably having 1 to 12 carbon atoms), a cycloalkyl group (may be any of a monocycle, a polycycle and a spiro ring, preferably having 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group or a sulfonic ester group. The carbon (carbon contributing to ring formation) as a constituent of the above alicyclic group, aryl group and heterocyclic group may be a carbonyl carbon.

Particular examples of the anion structures in the compounds (B) of general formula (B-1) are shown below, which in no way limit the scope of the present invention.

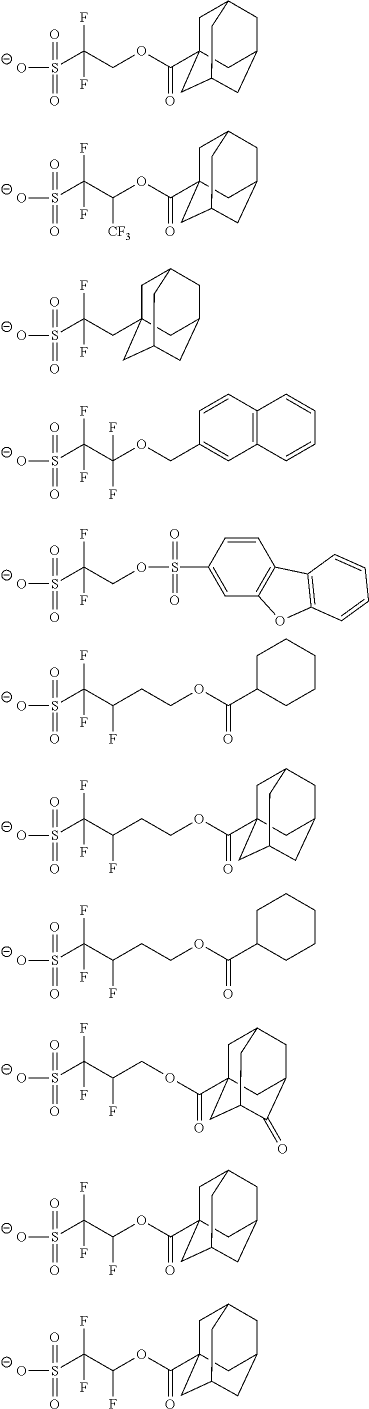

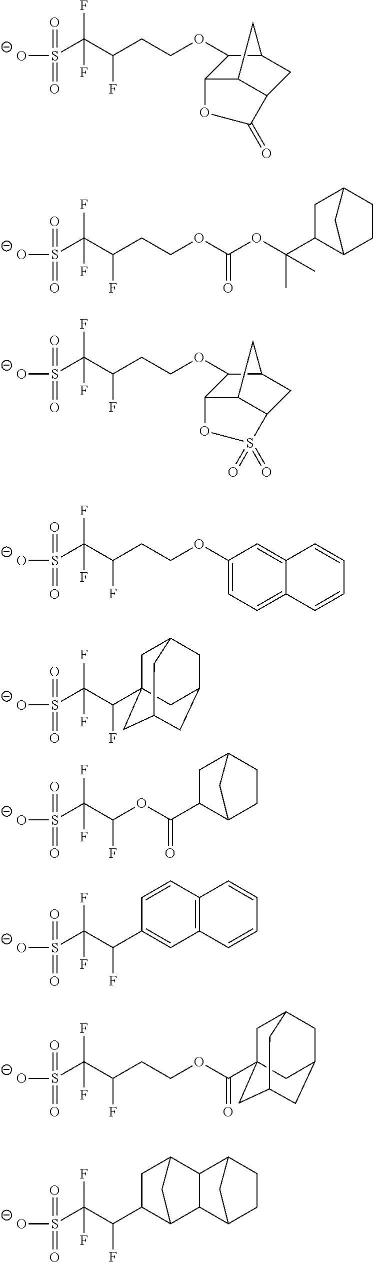

Now, the compounds (B) of general formula (B-2) below will be described.

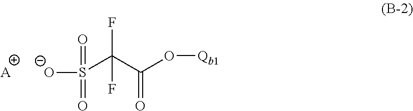

In general formula (B-2) above,

A⁺ represents a sulfonium cation or an iodonium cation.

Q_{b1} represents a group containing a lactone structure, a group containing a sultone structure or a group containing a cyclocarbonate structure.

As the lactone structure and sultone structure in Q_{b1}, there can be mentioned, for example, those in the repeating units with a lactone structure or sultone structure set forth above in connection with the resin (P). In particular, there can be mentioned the lactone structures of any of general formulae (LC1-1) to (LC1-17) above and the sultone structures of any of general formulae (SL1-1) to (SL1-3) above.

The lactone structure or sultone structure may be directly bonded to the oxygen atom of the ester group in general formula (B-2) above. Alternatively, the lactone structure or sultone structure may be bonded to the oxygen atom of the ester group via an alkylene group (for example, a methylene group or an ethylene group). In that instance, the group containing a lactone structure or sultone structure can be stated as being an alkyl group containing the lactone structure or sultone structure as a substituent.

The cyclocarbonate structure in Q_{b1} is preferably a 5- to 7-membered cyclocarbonate structure. As such, there can be mentioned a 1,3-dioxoran-2-one, a 1,3-dioxan-2-one or the like.

The cyclocarbonate structure may be directly bonded to the oxygen atom of the ester group in general formula (B-2) above. Alternatively, the cyclocarbonate structure may be bonded to the oxygen atom of the ester group via an alkylene group (for example, a methylene group or an ethylene group). In that instance, the group containing a cyclocarbonate structure can be stated as being an alkyl group containing the cyclocarbonate structure as a substituent.

Particular examples of the anion structures in the compounds (B) of general formula (B-2) are shown below, which in no way limit the scope of the present invention.

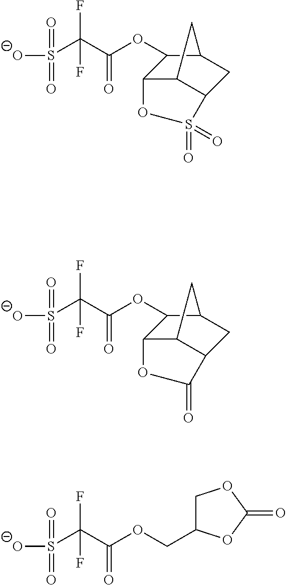

Now, the compounds (B) of general formula (B-3) below will be described.

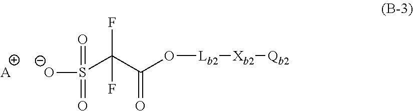

In general formula (B-3) above,

A⁺ represents a sulfonium cation or an iodonium cation.

L_{b2} represents an alkylene group having 1 to 6 carbon atoms, for example, a methylene group, an ethylene group, a propylene group, a butylene group or the like. An alkylene group having 1 to 4 carbon atoms is preferred.

X_{b2} represents an ether bond or an ester bond (—OCO— or —COO—).

Q_{b2} represents an alicyclic group or a group containing an aromatic ring.

The alicyclic group represented by Q_{b2} may be monocyclic or polycyclic. As the monoalicyclic group, there can be mentioned, for example, a monocycloalkyl group, such as a cyclopentyl group, a cyclohexyl group or a cyclooctyl group. As the polyalicyclic group, there can be mentioned, for example, a polycycloalkyl group, such as a norbornyl group, a tricyclodecanyl group, a tetracyclodecanyl group, a tetracyclododecanyl group or an adamantyl group. Of these, alicyclic groups with a bulky structure having 7 or more carbon atoms, such as a norbornyl group, a tricyclodecanyl group, a tetracyclodecanyl group, a tetracyclododecanyl group and an adamantyl group, are preferred.

The aromatic ring in the group containing an aromatic ring represented by Q_{b2} is preferably an aromatic ring having 6 to 20 carbon atoms. As such, there can be mentioned a benzene ring, a naphthalene ring, a phenanthrene ring, an anthracene ring or the like. A benzene ring or a naphthalene ring is preferred. This aromatic ring may be substituted with at least one fluorine atom. The aromatic ring substituted with at least one fluorine atom is, for example, a perfluorophenyl group.

The aromatic ring may be directly bonded to X_{b2}. Alternatively, the aromatic ring may be bonded to X_{b2} via an alkylene group (for example, a methylene group or an ethylene group). In that instance, the group containing an aromatic ring can be stated as being an alkyl group containing the aromatic ring as a substituent.

Particular examples of the anion structures in the compounds (B) of general formula (B-3) are shown below, which in no way limit the scope of the present invention.

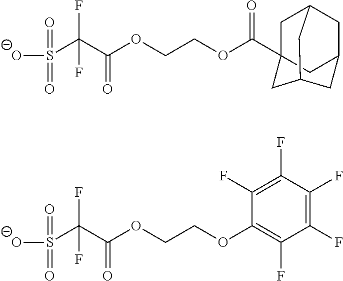

In general formulae (B-1) to (B-3) above, it is preferred for A⁺ to be the sulfonium cation in general formula (ZI) above or the iodonium cation in general formula (ZII) above. Particular examples of the cations represented by A⁺ are the same as set forth above in connection with general formulae (ZI) and (ZII) above.

Among the acid generators, the compounds of general formulae (B-1) to (B-3) are preferred. The compounds of general formula (B-1) are especially preferred.

As the acid generator, a compound capable of generating an acid containing one sulfonic acid group or imido group is preferred. More preferably, the acid generator is a compound capable of generating a monovalent perfluoroalkanesulfonic acid, or a compound capable of generating a monovalent aromatic sulfonic acid substituted with a fluorine atom or a group containing a fluorine atom, or a compound capable of generating a monovalent imidic acid substituted with a fluorine atom or a group containing a fluorine atom. Further more preferably, the acid generator is a sulfonium salt of fluorinated alkanesulfonic acid, fluorinated benzenesulfonic acid, fluorinated imidic acid or fluorinated methide acid. With respect to useful acid generators, it is especially preferred for the generated acid to be a fluorinated alkanesulfonic acid, fluorinated benzenesulfonic acid or fluorinated imidic acid of −1 or below pKa. When these acid generators are used, the sensitivity can be enhanced.

Most preferred examples of the acid generators are shown below.

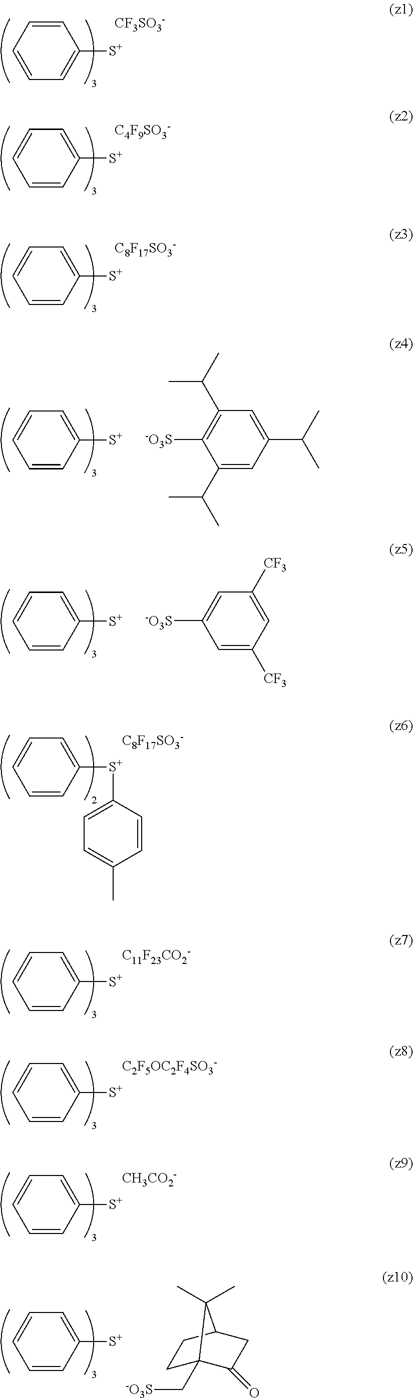

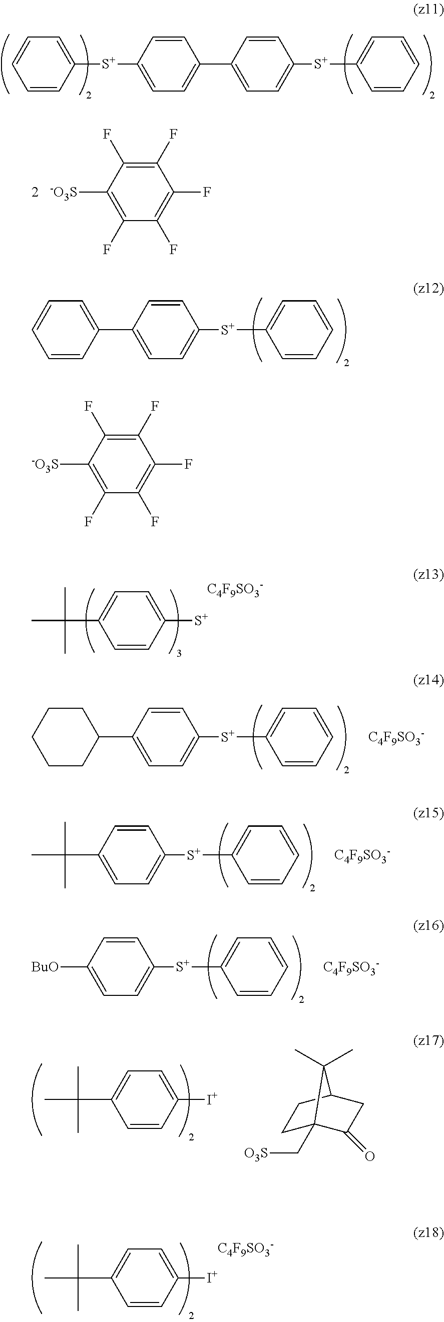

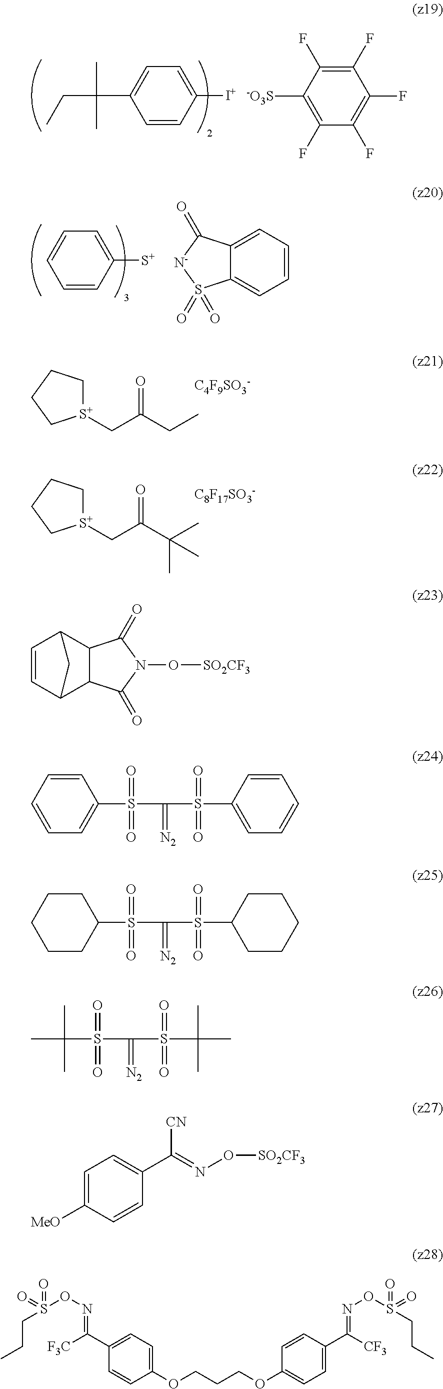

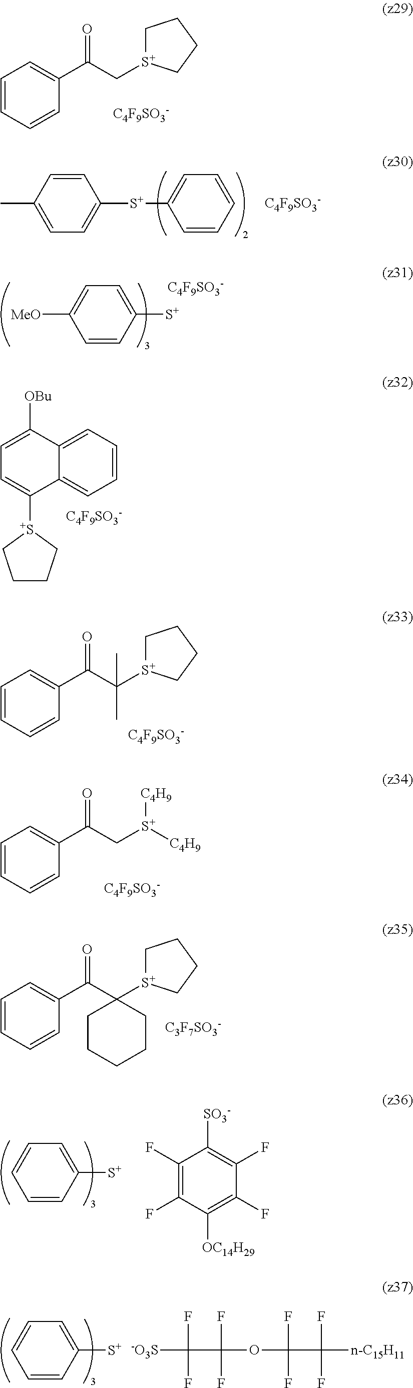

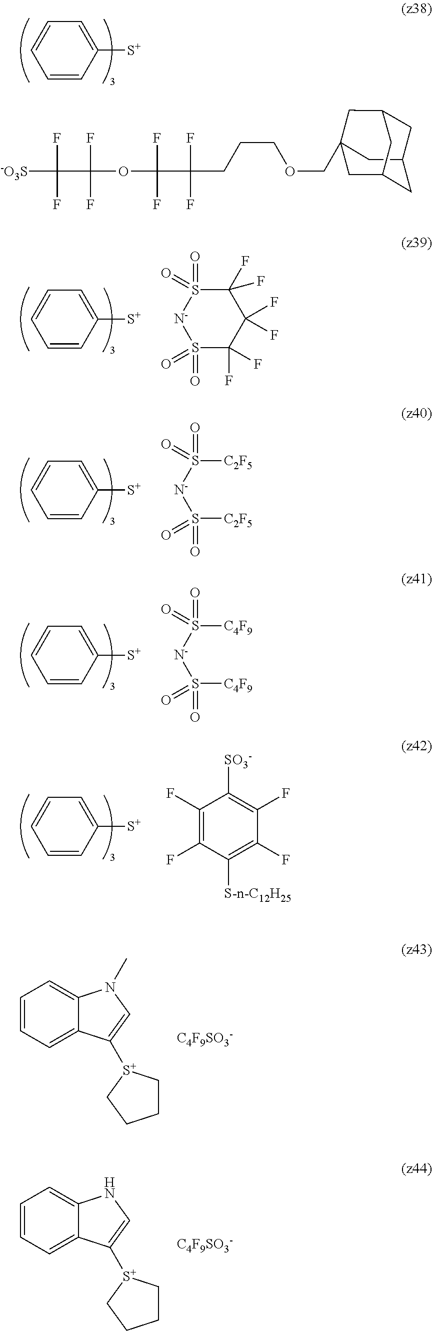

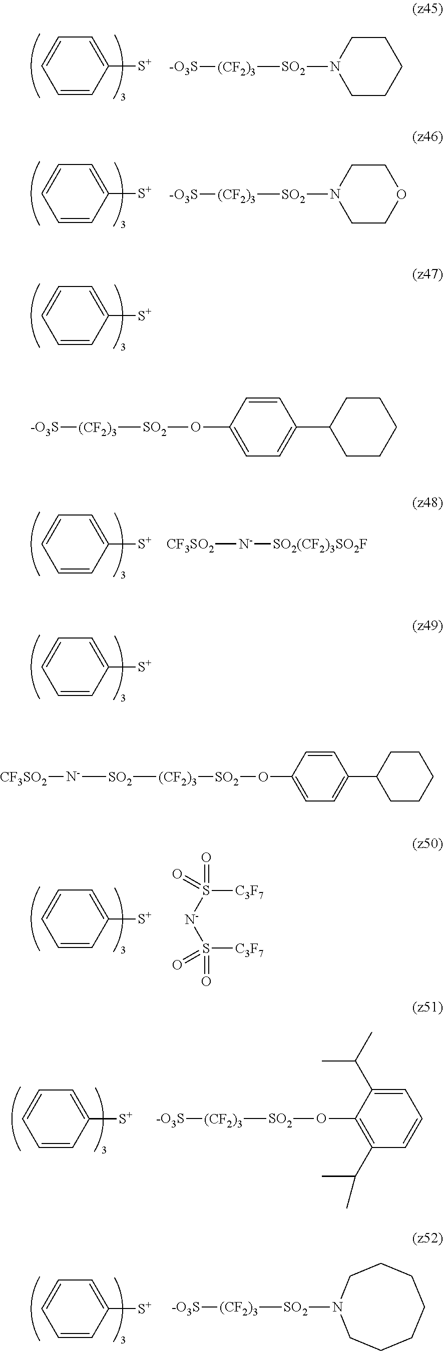

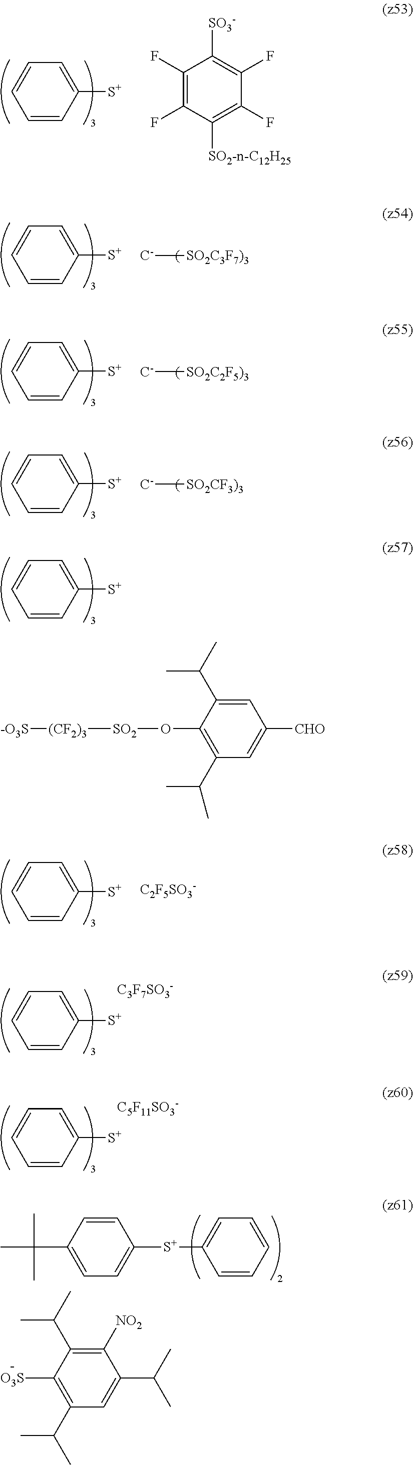

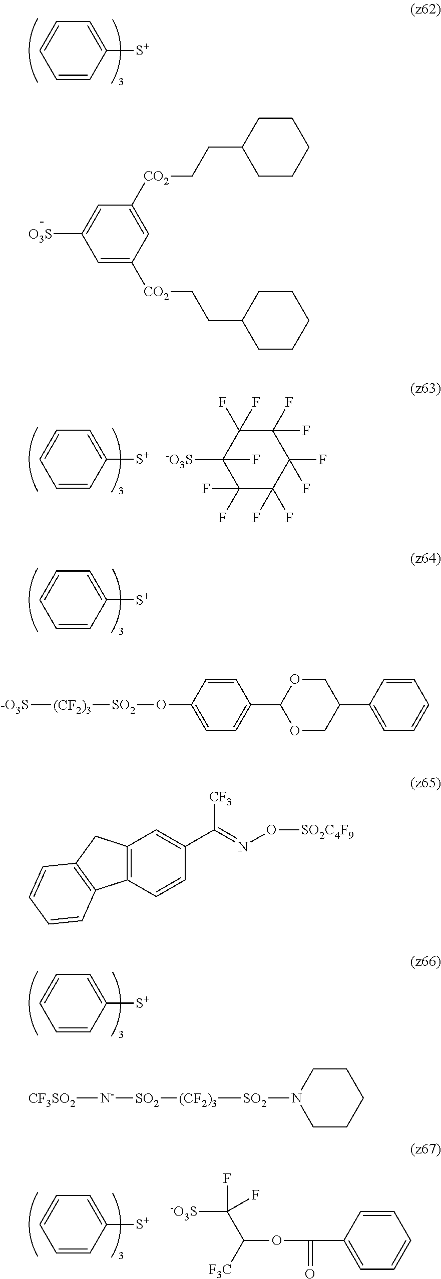

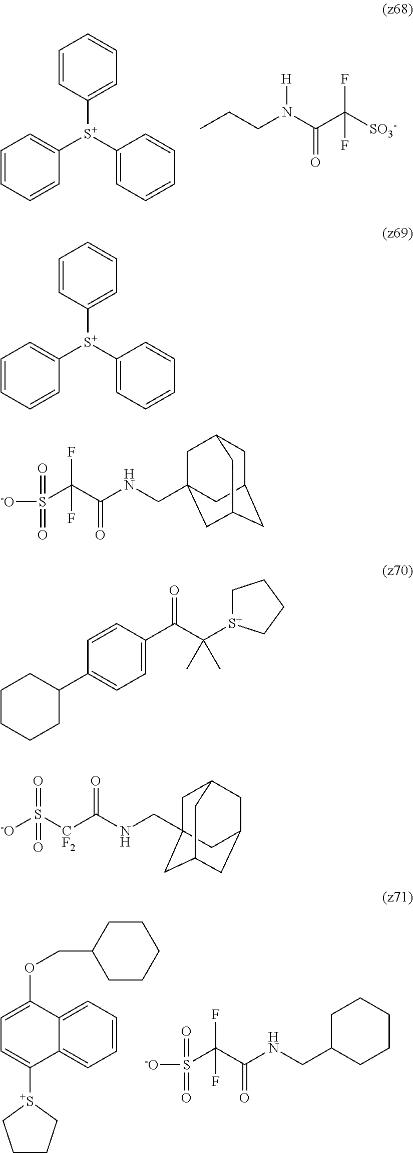

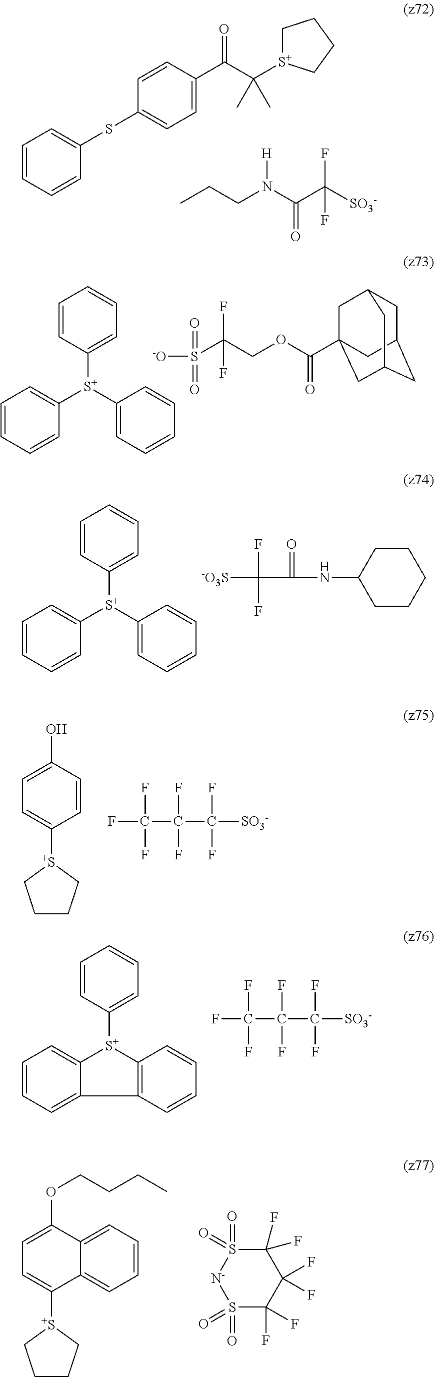

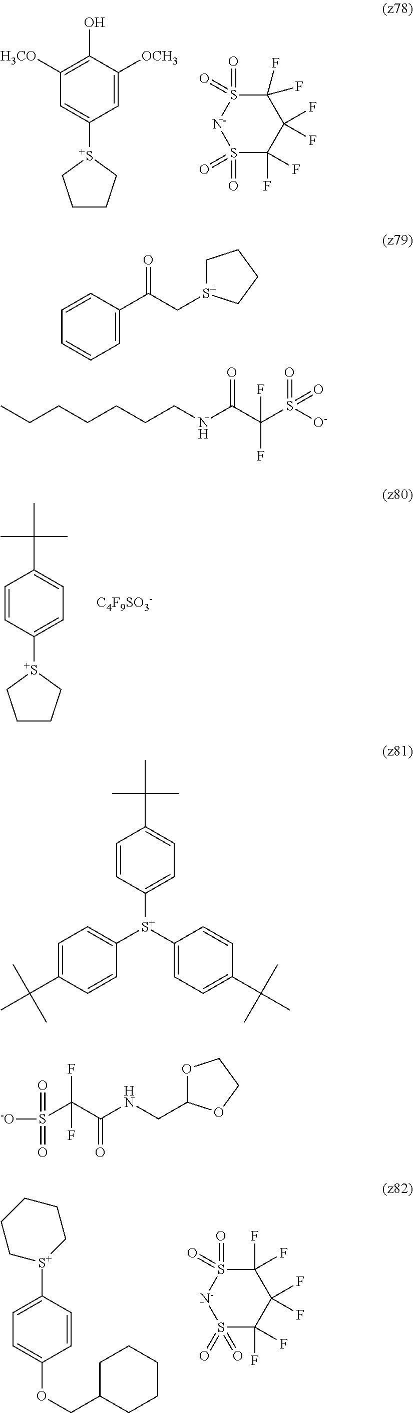

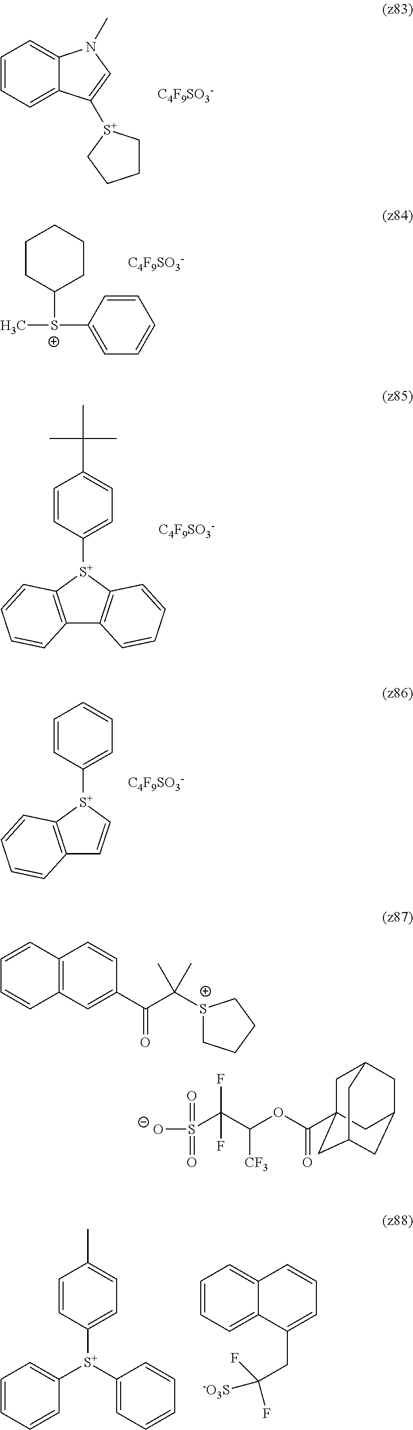

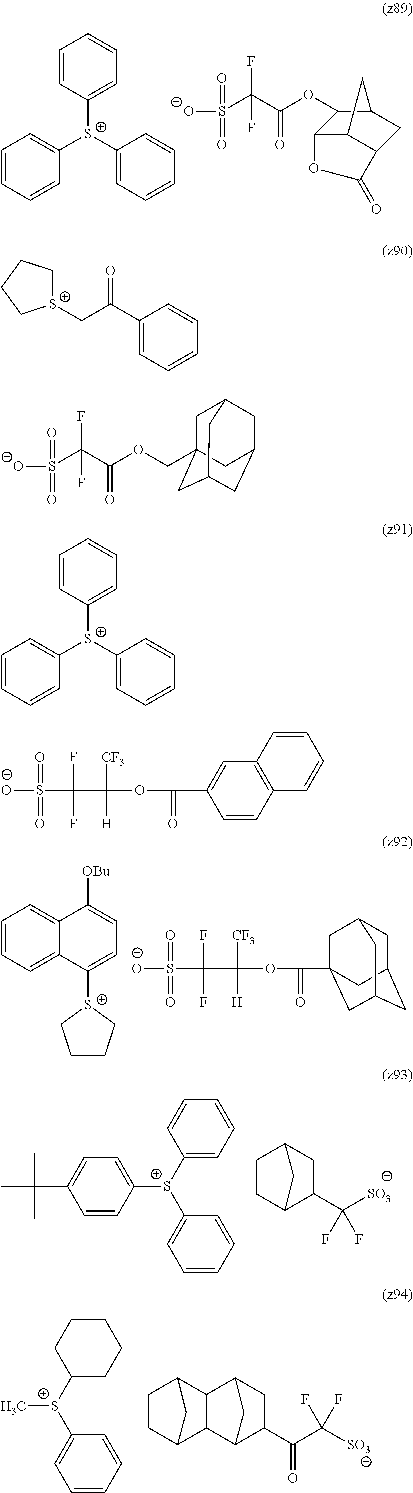

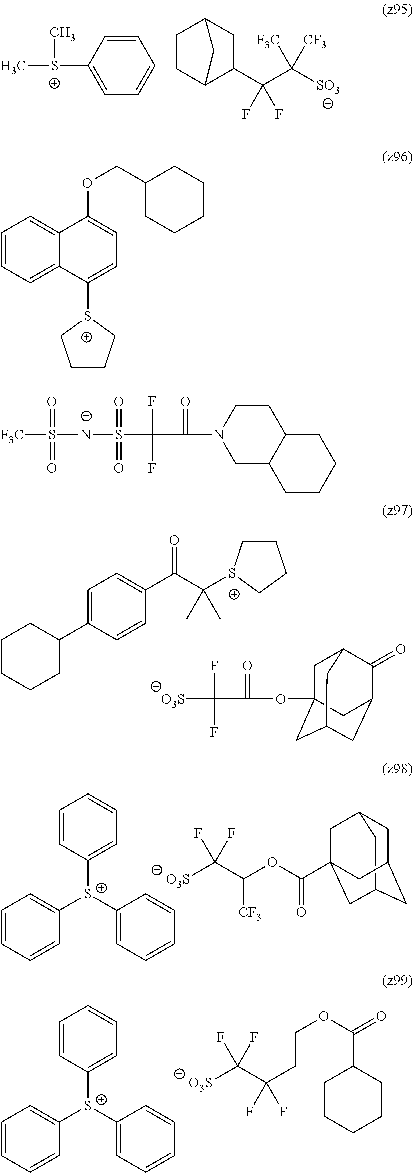

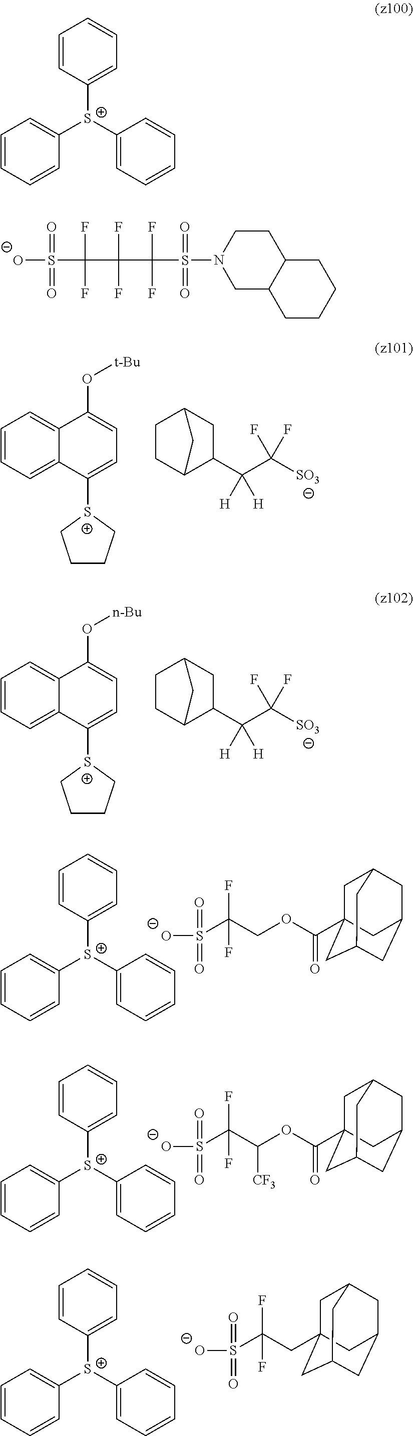

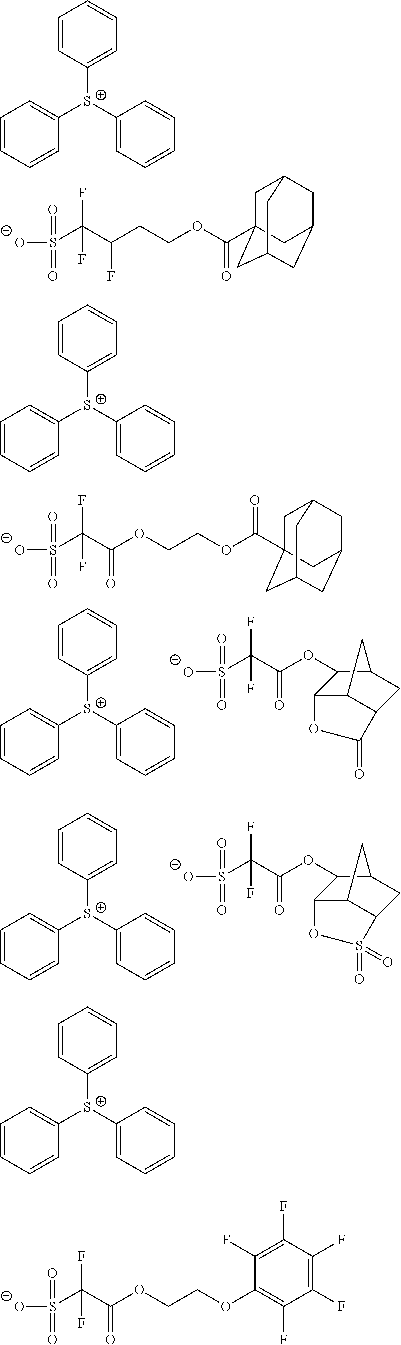

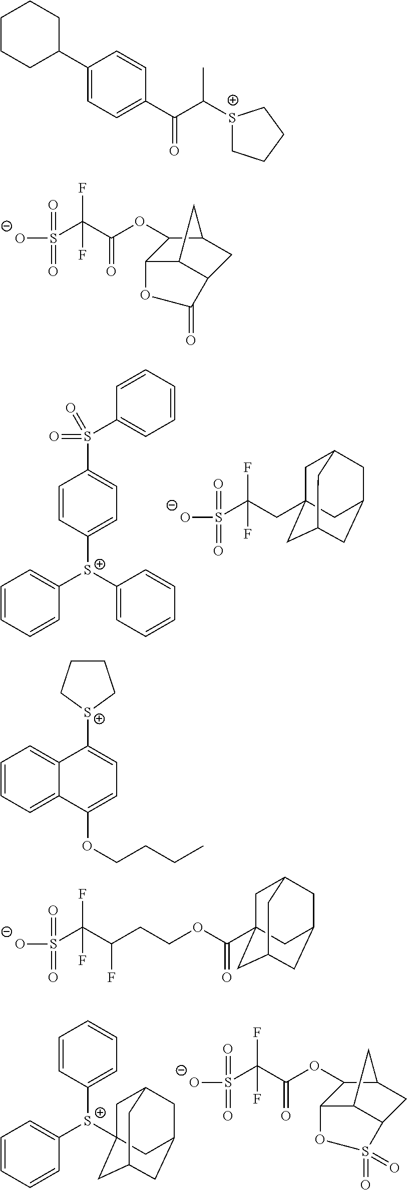

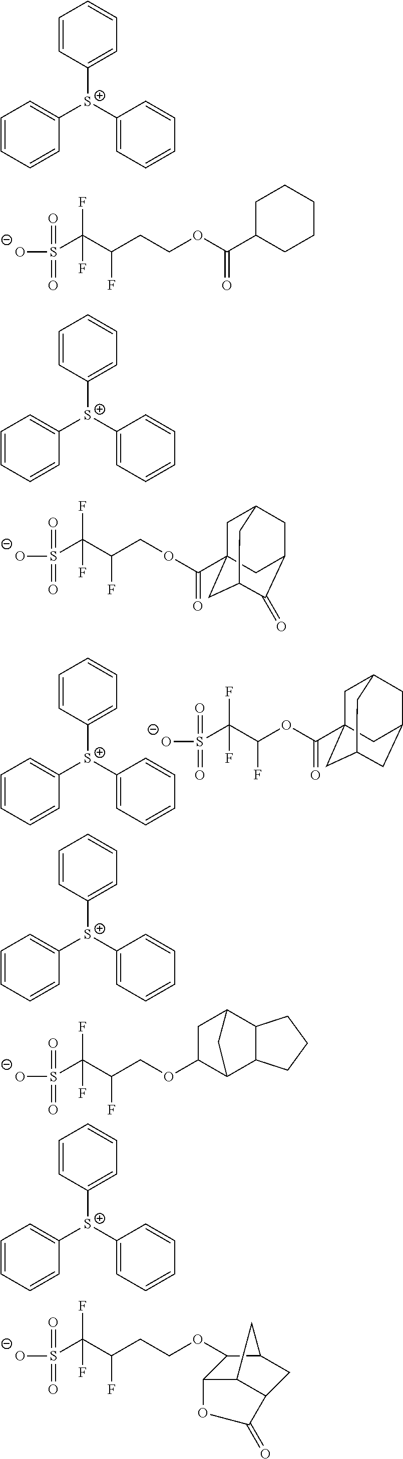

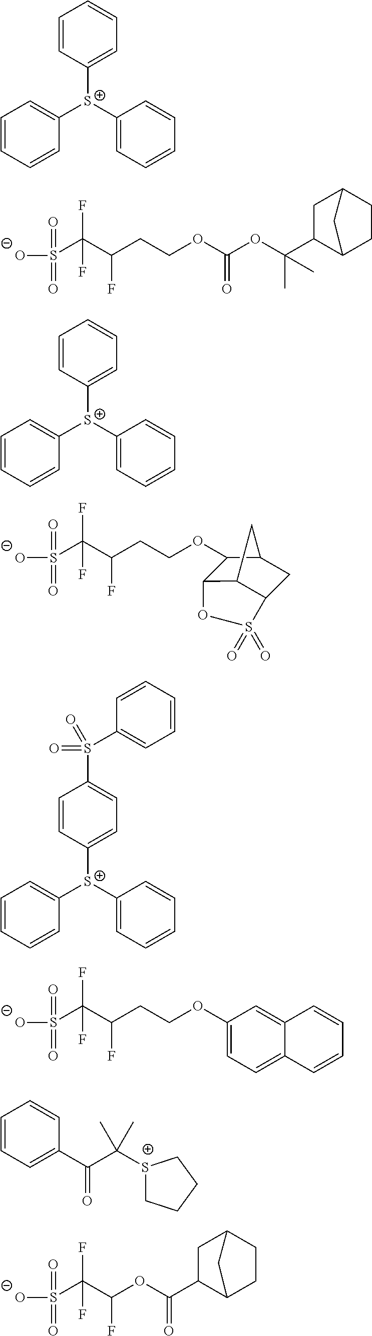

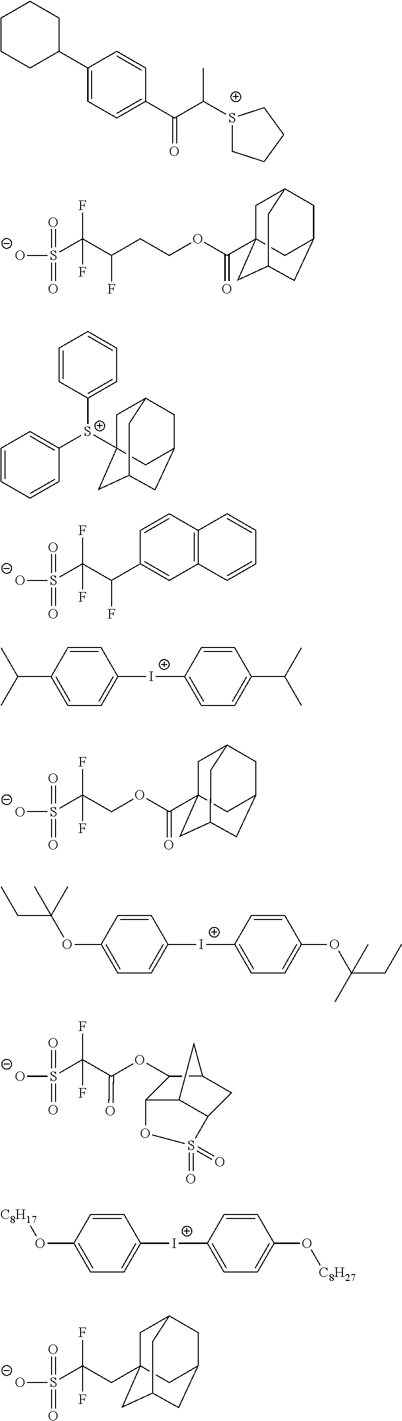

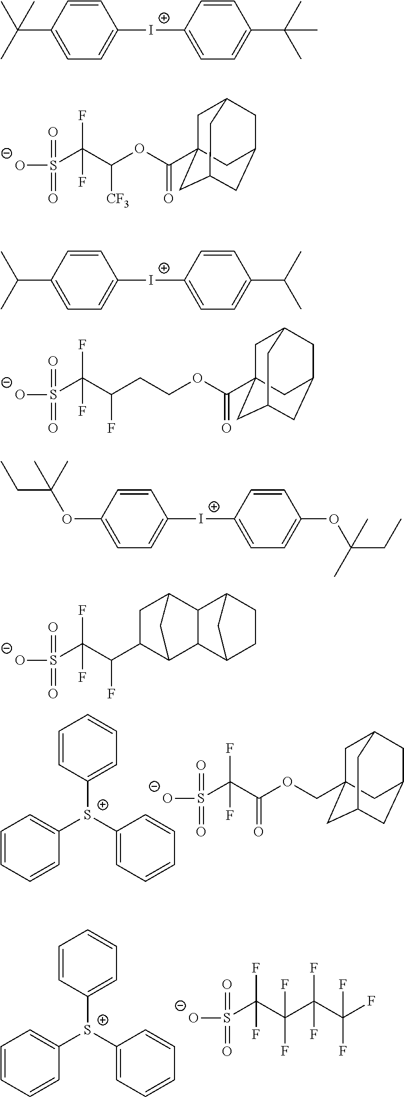

The acid generators can be synthesized by heretofore known methods, for example, by the method described in JP-A-2007-161707.

One type of acid generator may be used alone, or two or more types thereof may be used in combination.

The content of compound that when exposed to actinic rays or radiation, generates an acid in the composition, based on the total solids of the actinic-ray- or radiation-sensitive resin composition, is preferably in the range of 0.1 to 30 mass %, more preferably 0.5 to 25 mass %, further more preferably 3 to 20 mass % and most preferably 3 to 15 mass %.

When the acid generator is any of those of general formulae (ZI-3) and (ZI-4) above, the content thereof based on the total solids of the composition is preferably in the range of 5 to 35 mass %, more preferably 8 to 30 mass %, further more preferably 9 to 30 mass % and most preferably 9 to 25 mass %.

[3] Solvent (C)

The actinic-ray- or radiation-sensitive resin composition of the present invention may contain a solvent. The solvent is not particularly limited as long as it can be used in the preparation of the actinic-ray- or radiation-sensitive resin composition of the present invention. As the solvent, there can be mentioned, for example, an organic solvent, such as an alkylene glycol monoalkyl ether carboxylate, an alkylene glycol monoalkyl ether, an alkyl lactate, an alkyl alkoxypropionate, a cyclolactone (preferably having 4 to 10 carbon atoms), an optionally cyclized monoketone compound (preferably having 4 to 10 carbon atoms), an alkylene carbonate, an alkyl alkoxyacetate or an alkyl pyruvate.

As particular examples of these solvents, there can be mentioned those set forth in Sections [0441] to [0455] of US Patent Application Publication No. 2008/0187860.

In the present invention, a mixed solvent comprised of a mixture of a solvent containing a hydroxyl group in its structure and a solvent containing no hydroxyl group may be used as the organic solvent.

Compounds set forth above by way of example can be appropriately selected as the solvent containing a hydroxyl group and solvent containing no hydroxyl group. The solvent containing a hydroxyl group is preferably an alkylene glycol monoalkyl ether, an alkyl lactate or the like, more preferably propylene glycol monomethyl ether (PGME, also known as 1-methoxy-2-propanol) or ethyl lactate. The solvent containing no hydroxyl group is preferably an alkylene glycol monoalkyl ether acetate, an alkyl alkoxypropionate, an optionally cyclized monoketone compound, a cyclolactone, an alkyl acetate or the like. Of these, propylene glycol monomethyl ether acetate (PGMEA, also known as 1-methoxy-2-acetoxypropane), ethyl ethoxypropionate, 2-heptanone, γ-butyrolactone, cyclohexanone and butyl acetate are especially preferred. Propylene glycol monomethyl ether acetate, ethyl ethoxypropionate and 2-heptanone are most preferred.

The mixing ratio (mass) of a solvent having a hydroxyl group and a solvent having no hydroxyl group is in the range of 1/99 to 99/1, preferably 10/90 to 90/10 and more preferably 20/80 to 60/40. A mixed solvent containing 50 mass % or more of solvent containing no hydroxyl group is especially preferred from the viewpoint of uniform coatability.

The solvent preferably contains propylene glycol monomethyl ether acetate, being preferably a solvent comprised only of propylene glycol monomethyl ether acetate, or a mixed solvent comprised of two or more types of solvents in which propylene glycol monomethyl ether acetate is contained.

[4] Hydrophobic Resin (HR)

The actinic-ray- or radiation-sensitive resin composition of the present invention may further comprise a hydrophobic resin (hereinafter also referred to as “hydrophobic resin (HR)” or “resin (HR)”) different from the above-described resins (A) especially when a liquid immersion exposure is applied thereto.

This localizes the hydrophobic resin (HR) in the surface layer of the film. Accordingly, when the immersion medium is water, the static/dynamic contact angle of the surface of the resist film with respect to water can be increased, thereby enhancing the immersion liquid tracking property.

Although the hydrophobic resin (HR) is preferably designed so as to be localized in the interface as mentioned above, as different from surfactants, the hydrophobic resin does not necessarily have to contain a hydrophilic group in its molecule and does not need to contribute toward uniform mixing of polar/nonpolar substances.

From the viewpoint of localization in the surface layer of the film, it is preferred for the hydrophobic resin (HR) to contain at least one member selected from among a “fluorine atom,” a “silicon atom” and a “CH₃ partial structure introduced in a side chain portion of the resin.” Two or more members may be contained.

When the hydrophobic resin (HR) contains a fluorine atom and/or a silicon atom, in the hydrophobic resin (HR), the fluorine atom and/or silicon atom may be introduced in the principal chain of the resin, or a side chain thereof.

When the hydrophobic resin (HR) contains a fluorine atom, it is preferred for the resin to comprise, as a partial structure containing a fluorine atom, an alkyl group containing a fluorine atom, a cycloalkyl group containing a fluorine atom or an aryl group containing a fluorine atom.

The alkyl group containing a fluorine atom is a linear or branched alkyl group having at least one hydrogen atom thereof substituted with a fluorine atom. This alkyl group preferably has 1 to 10 carbon atoms, more preferably 1 to 4 carbon atoms. A substituent other than the fluorine atom may further be introduced in the alkyl group containing a fluorine atom.

The cycloalkyl group containing a fluorine atom is a mono- or polycycloalkyl group having at least one hydrogen atom thereof substituted with a fluorine atom. A substituent other than the fluorine atom may further be introduced in the cycloalkyl group containing a fluorine atom.

The aryl group containing a fluorine atom is an aryl group having at least one hydrogen atom thereof substituted with a fluorine atom. As the aryl group, there can be mentioned, for example, a phenyl or naphthyl group. A substituent other than the fluorine atom may further be introduced in the aryl group containing a fluorine atom.

As preferred examples of the alkyl groups each containing a fluorine atom, cycloalkyl groups each containing a fluorine atom and aryl groups each containing a fluorine atom, there can be mentioned the groups of general formulae (F2) to (F4) below, which however in no way limit the scope of the present invention.

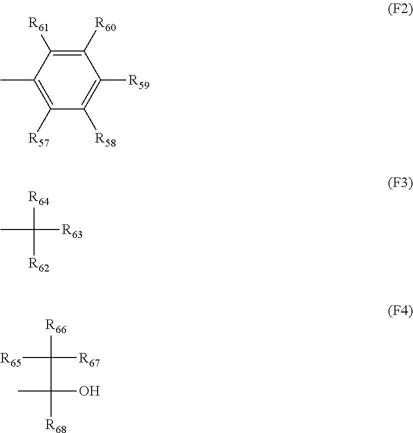

In general formulae (F2) to (F4),

each of R₅₇ to R₆₈ independently represents a hydrogen atom, a fluorine atom or an alkyl group (linear or branched), provided that at least one of each of R₅₇-R₆₁, at least one of each of R₆₂-R₆₄ and at least one of each of R₆₅-R₆₈ represent a fluorine atom or an alkyl group (preferably having 1 to 4 carbon atoms) having at least one hydrogen atom thereof substituted with a fluorine atom.

It is preferred that all of R₅₇-R₆₁ and R₆₅-R₆₇ represent fluorine atoms. Each of R₆₂, R₆₃ and R₆₈ preferably represents a fluoroalkyl group (especially having 1 to 4 carbon atoms), more preferably a perfluoroalkyl group having 1 to 4 carbon atoms. When each of R₆₂ and R₆₃ represents a perfluoroalkyl group, R₆₄ preferably represents a hydrogen atom. R₆₂ and R₆₃ may be bonded with each other to thereby form a ring.

Specific examples of the groups of general formula (F2) include a p-fluorophenyl group, a pentafluorophenyl group, a 3,5-di(trifluoromethyl)phenyl group and the like.

Specific examples of the groups of general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. Of these, a hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred. A hexafluoroisopropyl group and a heptafluoroisopropyl group are more preferred.

Specific examples of the groups of general formula (F4) include —C(CF₃)₂OH, —C(C₂F₅)₂OH, —C(CF₃)(CF₃)OH, —CH(CF₃)OH and the like. —C(CF₃)₂OH is preferred.

The partial structure containing a fluorine atom may be directly bonded to the principal chain, or may be bonded to the principal chain through a group selected from the group consisting of an alkylene group, a phenylene group, an ether group, a thioether group, a carbonyl group, an ester group, an amido group, a urethane group and a ureylene group, or through a group composed of a combination of two or more of these groups.

Particular examples of the repeating units each containing a fluorine atom are shown below, which in no way limit the scope of the present invention.

In the particular examples, X₁ represents a hydrogen atom, —CH₃, —F or —CF₃, and X₂ represents —F or —CF₃.

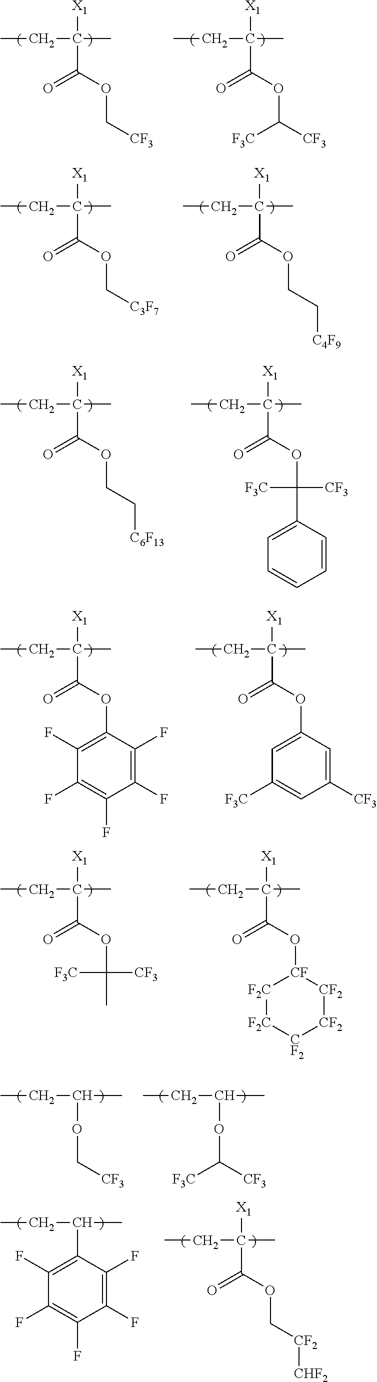

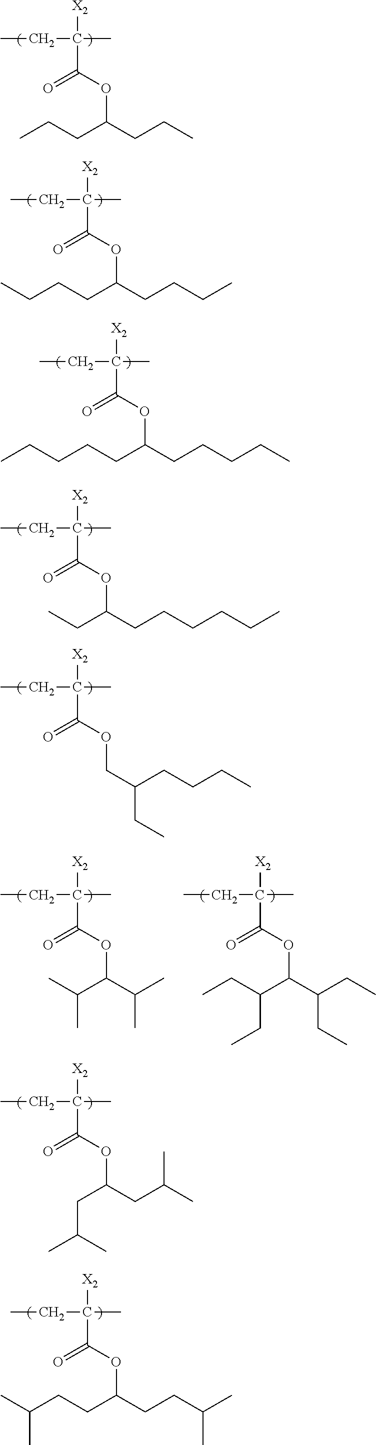

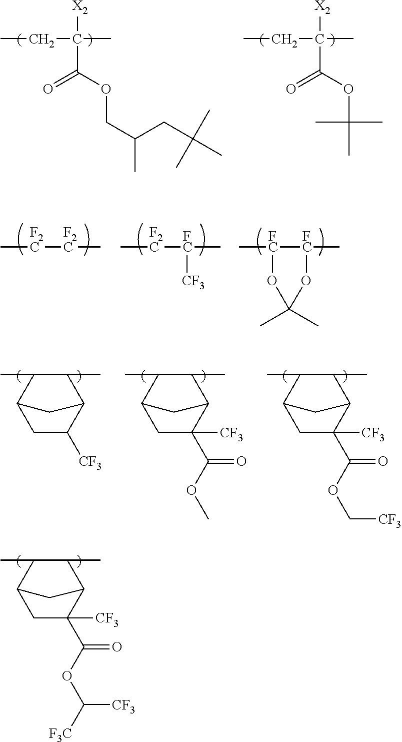

The hydrophobic resin (HR) may contain a silicon atom. It is preferred for the hydrophobic resin (D) to have an alkylsilyl structure (preferably a trialkylsilyl group) or a cyclosiloxane structure as a partial structure having a silicon atom.

As the alkylsilyl structure or cyclosiloxane structure, there can be mentioned, for example, any of the groups of the following general formulae (CS-1) to (CS-3) or the like.

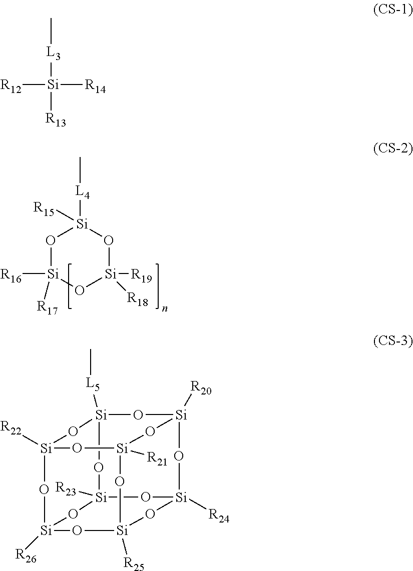

In general formulae (CS-1) to (CS-3),

each of R₁₂ to R₂₆ independently represents a linear or branched alkyl group (preferably having 1 to 20 carbon atoms) or a cycloalkyl group (preferably having 3 to 20 carbon atoms).

Each of L₃ to L₅ represents a single bond or a bivalent connecting group. As the bivalent connecting group, there can be mentioned any one or a combination of two or more groups selected from the group consisting of an alkylene group, a phenylene group, an ether group, a thioether group, a carbonyl group, an ester group, an amido group, a urethane group and a urea group. The sum of carbon atoms of the bivalent connecting group is preferably 12 or less.

In the formulae, n is an integer of 1 to 5. n is preferably an integer of 2 to 4.

Particular examples of the repeating units having any of the groups of general formulae (CS-1) to (CS-3) are shown below, which in no way limit the scope of the present invention.

In the particular examples, X₁ represents a hydrogen atom, —CH₃, —F or —CF₃.

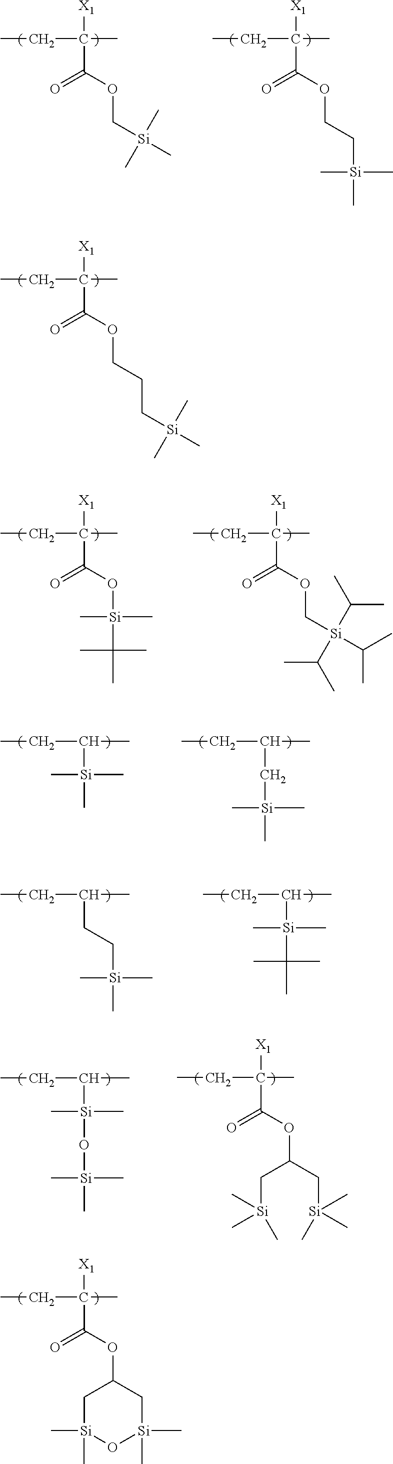

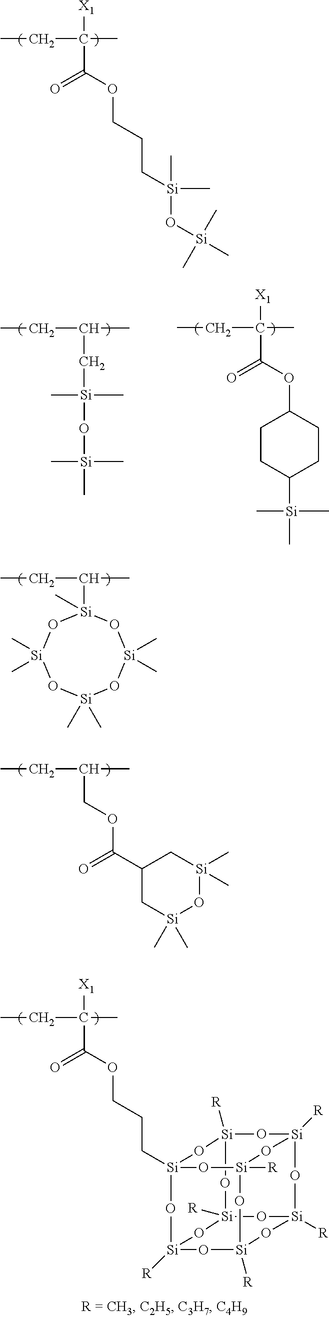

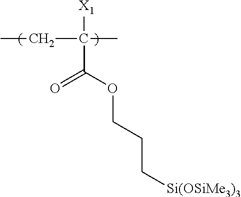

As mentioned above, it is preferred for the hydrophobic resin (HR) to contain a CH₃ partial structure in its side chain portion.

Herein, the CH₃ partial structure (hereinafter also simply referred to as “side-chain CH₃ partial structure”) contained in a side chain portion of the hydrophobic resin (HR) includes a CH₃ partial structure contained in an ethyl group, a propyl group or the like.

In contrast, a methyl group (for example, an α-methyl group in the repeating unit with a methacrylic acid structure) directly bonded to the principal chain of the resin (HR) is not included in the side-chain CH₃ partial structure according to the present invention, since the contribution thereof to the surface localization of the resin (HR) is slight due to the influence of the principal chain.

In particular, when the resin (HR) comprises, for example, a repeating unit derived from a monomer containing a polymerizable moiety having a carbon-carbon double bond, such as any of repeating units of general formula (M) below, and when each of R₁₁ to R₁₄ is CH₃ “per se,” the CH₃ is not included in the CH₃ partial structure contained in a side chain portion according to the present invention.

In contrast, a CH₃ partial structure arranged via some atom apart from the C—C principal chain corresponds to the side-chain CH₃ partial structure according to the present invention. For example, when R₁₁ is an ethyl group (CH₂CH₃), it is stated that “one” side-chain CH₃ partial structure according to the present invention is contained.

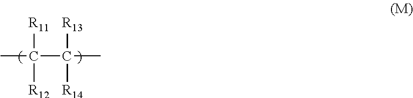

In general formula (M) above,

each of R₁₁ to R₁₄ independently represents a side chain portion.

Each of R₁₁ to R₁₄ as a side chain portion represents a hydrogen atom, a monovalent organic group or the like.

As the monovalent organic group represented by each of R₁₁ to R₁₄, there can be mentioned an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, an arylaminocarbonyl group or the like. Substituents may further be introduced in these groups.

It is preferred for the hydrophobic resin (HR) to be a resin comprising a repeating unit containing a CH₃ partial structure in its side chain portion. More preferably, the hydrophobic resin (HR) comprises, as such a repeating unit, at least one repeating unit (x) selected from among the repeating units of general formula (II) below and repeating units of general formula (III) below.

The repeating units of general formula (II) will be described in detail below.

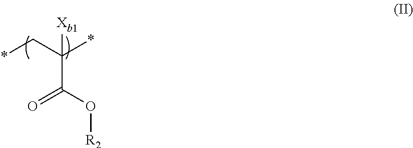

In general formula (II) above, X_{b1} represents a hydrogen atom, an alkyl group, a cyano group or a halogen atom. R₂ represents an organic group having at least one CH₃ partial structure and being stable against acids. Herein, in particular, it is preferred for the organic group stable against acids to be an organic group not containing “any group that when acted on by an acid, is decomposed to thereby produce a polar group” described above in connection with the resin (A).

The alkyl group represented by X_{b1} is preferably one having 1 to 4 carbon atoms, such as a methyl group, an ethyl group, a propyl group, a hydroxymethyl group or a trifluoromethyl group. A methyl group is more preferred.

Preferably, X_{b1} is a hydrogen atom or a methyl group.

As R₂, there can be mentioned an alkyl group, a cycloalkyl group, an alkenyl group, a cycloalkenyl group, an aryl group and an aralkyl group each containing at least one CH₃ partial structure. An alkyl group as a substituent may further be introduced in each of the cycloalkyl group, alkenyl group, cycloalkenyl group, aryl group and aralkyl group.

R₂ is preferably an alkyl group or alkyl-substituted cycloalkyl group containing at least one CH₃ partial structure.

The organic group stable against acids containing at least one CH₃ partial structure represented by R₂ preferably contains 2 to 10 CH₃ partial structures, more preferably 2 to 8 CH₃ partial structures.

The alkyl group containing at least one CH₃ partial structure represented by R₂ is preferably a branched alkyl group having 3 to 20 carbon atoms. As preferred alkyl groups, there can be mentioned, for example, an isopropyl group, an isobutyl group, a t-butyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group and the like. An isobutyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group and a 2,3,5,7-tetramethyl-4-heptyl group are more preferred.

The cycloalkyl group containing at least one CH₃ partial structure represented by R₂ may be monocyclic or polycyclic. In particular, there can be mentioned groups with, for example, monocyclo, bicyclo, tricyclo and tetracyclo structures each having 5 or more carbon atoms, preferably 6 to 30 carbon atoms and most preferably 7 to 25 carbon atoms. As preferred cycloalkyl groups, there can be mentioned an adamantyl group, a noradamantyl group, a decalin residue, a tricyclodecanyl group, a tetracyclododecanyl group, a norbornyl group, a cedrol group, a cyclopentyl group, a cyclohexyl group, a cycloheptyl group, a cyclooctyl group, a cyclodecanyl group and a cyclododecanyl group. As more preferred cycloalkyl groups, there can be mentioned an adamantyl group, a norbornyl group, a cyclohexyl group, a cyclopentyl group, a tetracyclododecanyl group and a tricyclodecanyl group. A norbornyl group, a cyclopentyl group and a cyclohexyl group are further more preferred.

The alkenyl group containing at least one CH₃ partial structure represented by R₂ is preferably a linear or branched alkenyl group having 1 to 20 carbon atoms. A branched alkenyl group is more preferred.

The aryl group containing at least one CH₃ partial structure represented by R₂ is preferably an aryl group having 6 to 20 carbon atoms, such as a phenyl group or a naphthyl group. A phenyl group is more preferred.

The aralkyl group containing at least one CH₃ partial structure represented by R₂ is preferably one having 7 to 12 carbon atoms. For example, there can be mentioned a benzyl group, a phenethyl group, a naphthylmethyl group or the like.

Examples of hydrocarbon groups each containing two or more CH₃ partial structures represented by R₂ include an isopropyl group, an isobutyl group, a t-butyl group, a 3-pentyl group, a 2-methyl-3-butyl group, a 3-hexyl group, a 2,3-dimethyl-2-butyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 3,5-di-tert-butylcyclohexyl group, a 4-isopropylcyclohexyl group, a 4-t-butylcyclohexyl group, an isobornyl group and the like. An isobutyl group, a t-butyl group, a 2-methyl-3-butyl group, a 2,3-dimethyl-2-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 3,5-di-tert-butylcyclohexyl group, a 4-isopropylcyclohexyl group, a 4-t-butylcyclohexyl group and an isobornyl group are more preferred.

Preferred particular examples of the repeating units of general formula (II) are shown below, which in no way limit the scope of the present invention.

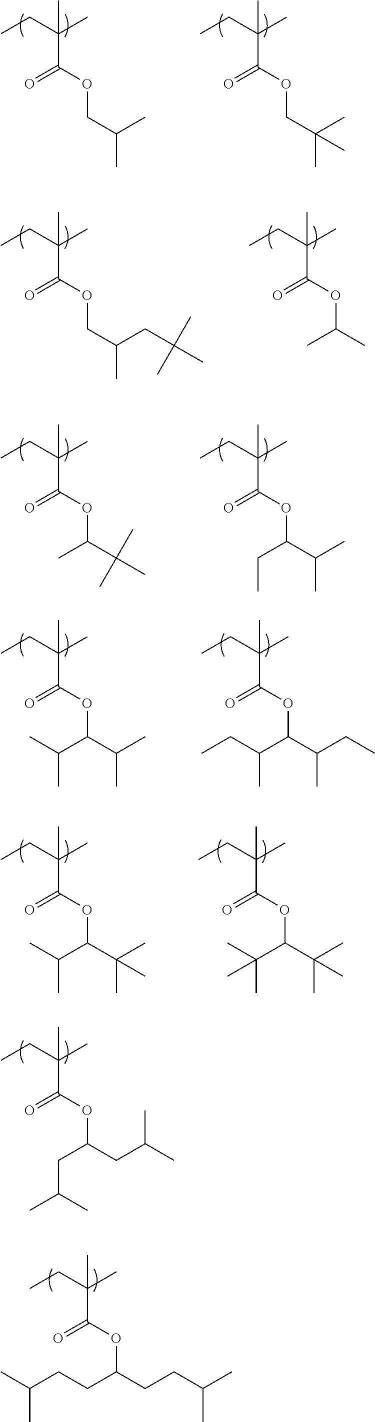

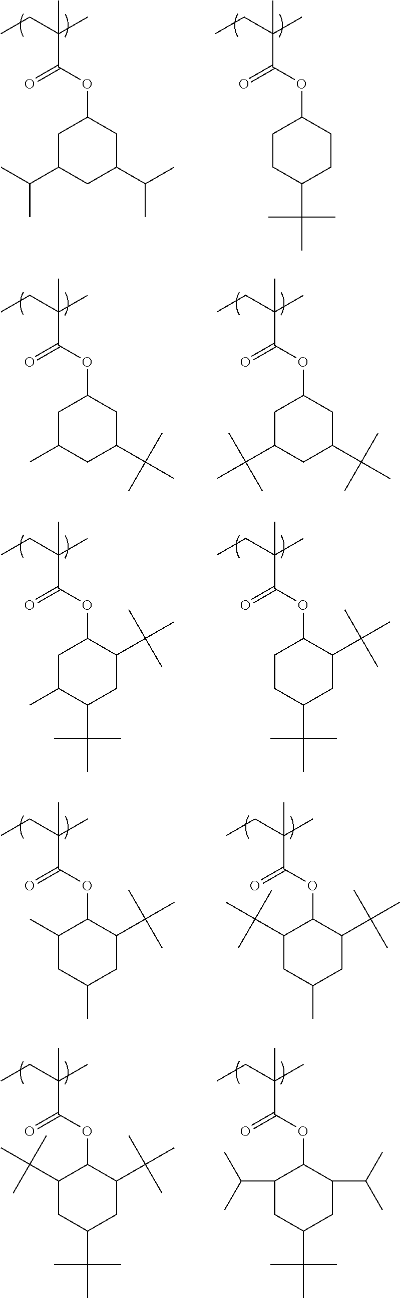

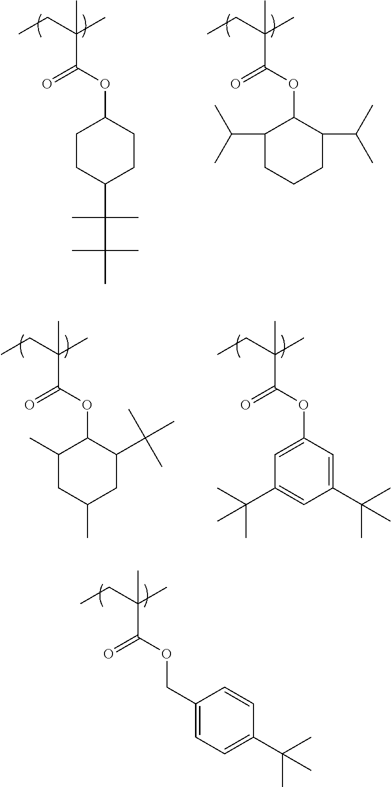

It is preferred for the repeating units of general formula (II) to be those stable against acids (non-acid-decomposable), in particular, repeating units containing no groups that are decomposed under the action of an acid to thereby produce polar groups.

The repeating units of general formula (III) will be described in detail below.

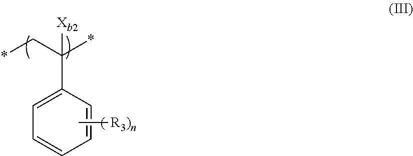

In general formula (III) above, X_{b2} represents a hydrogen atom, an alkyl group, a cyano group or a halogen atom. R₃ represents an organic group having at least one CH₃ partial structure and being stable against acids; and n is an integer of 1 to 5.

The alkyl group represented by X_{b2} is preferably one having 1 to 4 carbon atoms, such as a methyl group, an ethyl group, a propyl group, a hydroxymethyl group or a trifluoromethyl group. A methyl group is more preferred.

Preferably, X_{b2} is a hydrogen atom.

R₃ is an organic group stable against acids. In particular, R₃ is preferably an organic group not containing “any group that when acted on by an acid, is decomposed to thereby produce a polar group” described above in connection with the resin (A).

As R₃, there can be mentioned an alkyl group containing at least one CH₃ partial structure.

The organic group stable against acids containing at least one CH₃ partial structure represented by R₃ preferably contains 1 to 10 CH₃ partial structures, more preferably 1 to 8 CH₃ partial structures and further more preferably 1 to 4 CH₃ partial structures.

The alkyl group containing at least one CH₃ partial structure represented by R₃ is preferably a branched alkyl group having 3 to 20 carbon atoms. As preferred alkyl groups, there can be mentioned, for example, an isopropyl group, an isobutyl group, a t-butyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group and the like. An isobutyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group and a 2,3,5,7-tetramethyl-4-heptyl group are more preferred.

Examples of alkyl groups each containing two or more CH₃ partial structures represented by R₃ include an isopropyl group, an isobutyl group, a t-butyl group, a 3-pentyl group, a 2,3-dimethylbutyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group and the like. Alkyl groups having 5 to 20 carbon atoms are preferred, including an isopropyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group and a 2,3,5,7-tetramethyl-4-heptyl group are more preferred.

In the formula, n is an integer of 1 to 5, preferably 1 to 3, and more preferably 1 or 2.

Preferred particular examples of the repeating units of general formula (III) are shown below, which in no way limit the scope of the present invention.

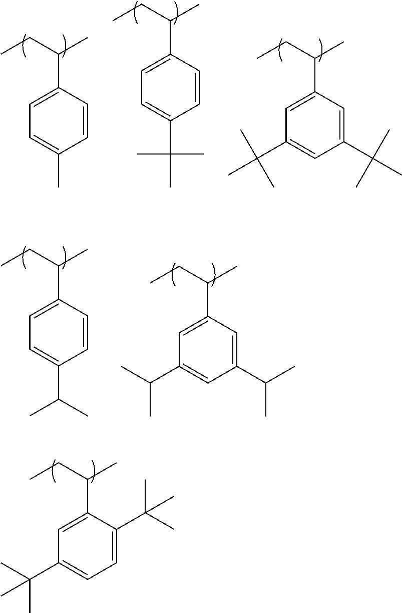

It is preferred for the repeating units of general formula (III) to be those stable against acids (non-acid-decomposable), in particular, repeating units containing no groups that are decomposed under the action of an acid to thereby produce polar groups.

When the resin (HR) contains a CH₃ partial structure in its side chain portion and contains neither a fluorine atom nor a silicon atom, the content of at least one repeating unit (x) selected from among the repeating units of general formula (II) and repeating units of general formula (III) based on all the repeating units of the resin (HR) is preferably 90 mol % or more, more preferably 95 mol % or more. The content based on all the repeating units of the resin (HR) is generally 100 mol % or less.

When the resin (HR) contains at least one repeating unit (x) selected from among the repeating units of general formula (II) and repeating units of general formula (III) in an amount of 90 mol % or more based on all the repeating units of the resin (HR), the surface free energy of the resin (HR) is increased. As a result, the localization of the resin (HR) in the surface of the resist film is promoted, so that the static/dynamic contact angle of the resist film with respect to water can be securely increased, thereby enhancing the immersion liquid tracking property.

In the instance of containing a fluorine atom and/or a silicon atom (i) and also in the instance of containing a CH₃ partial structure in its side chain (ii), the hydrophobic resin (HR) may contain at least one group selected from among the following groups (x) to (z).

Namely,

(x) an acid group,

(y) a group with a lactone structure, an acid anhydride group or an acid imido group, and

(y) a group that when acted on by an acid, is decomposed.

As the acid group (x), there can be mentioned a phenolic hydroxyl group, a carboxylic acid group, a fluoroalcohol group, a sulfonic acid group, a sulfonamido group, a sulfonimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group or a tris(alkylsulfonyl)methylene group or the like.

As preferred acid groups, there can be mentioned a fluoroalcohol group, a sulfonimido group and a bis(alkylcarbonyl)methylene group. As a preferred fluoroalcohol group, there can be mentioned a hexafluoroisopropanol group.

The repeating unit containing an acid group (x) is, for example, a repeating unit wherein the acid group is directly bonded to the principal chain of a resin, such as a repeating unit derived from acrylic acid or methacrylic acid. Alternatively, this repeating unit may be a repeating unit wherein the acid group is bonded via a connecting group to the principal chain of a resin. Still alternatively, this repeating unit may be a repeating unit wherein the acid group is introduced in a terminal of the resin by using a chain transfer agent or polymerization initiator containing the acid group in the stage of polymerization. The repeating unit containing an acid group (x) may have at least either a fluorine atom or a silicon atom.

The content of the repeating unit containing an acid group (x) based on all the repeating units of the hydrophobic resin (HR) is preferably in the range of 1 to 50 mol %, more preferably 3 to 35 mol % and further more preferably 5 to 20 mol %.

Particular examples of the repeating units each containing an acid group (x) are shown below. In the formulae, Rx represents a hydrogen atom, CH₃, CF₃ or CH₂OH.

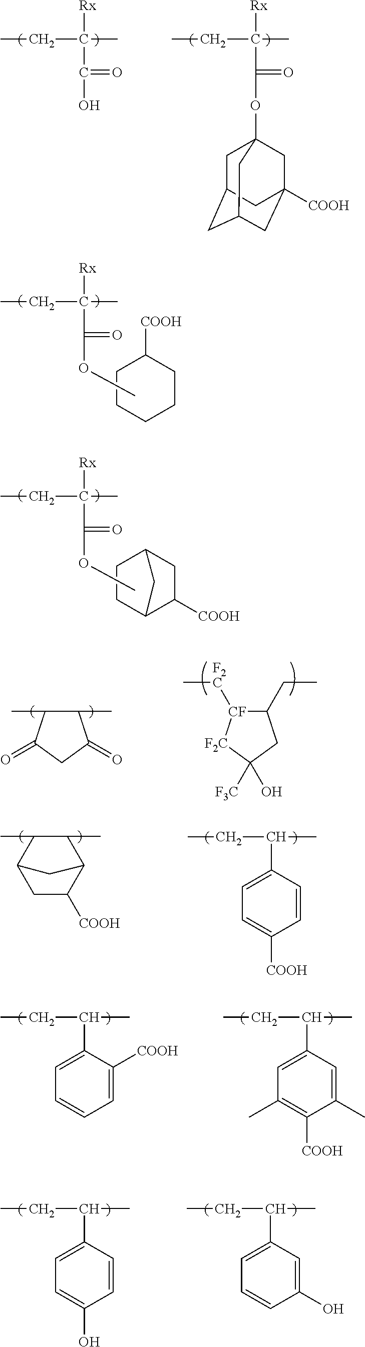

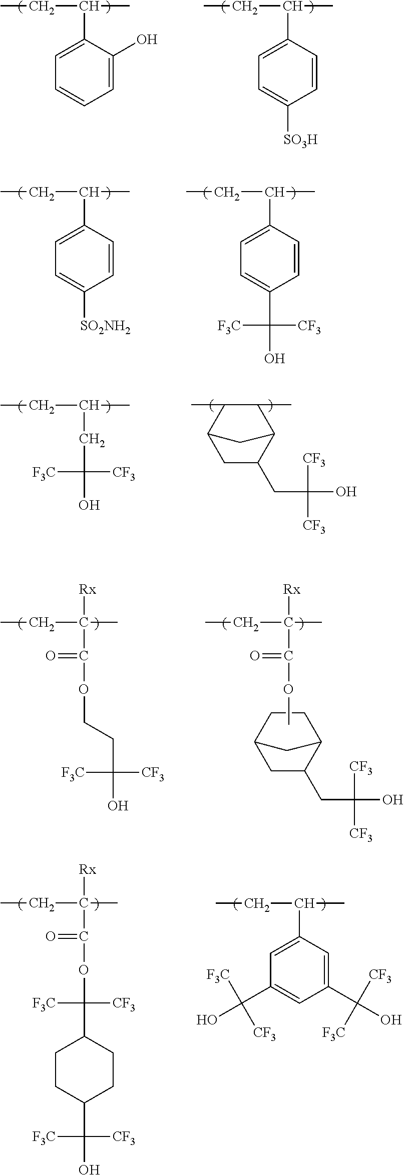

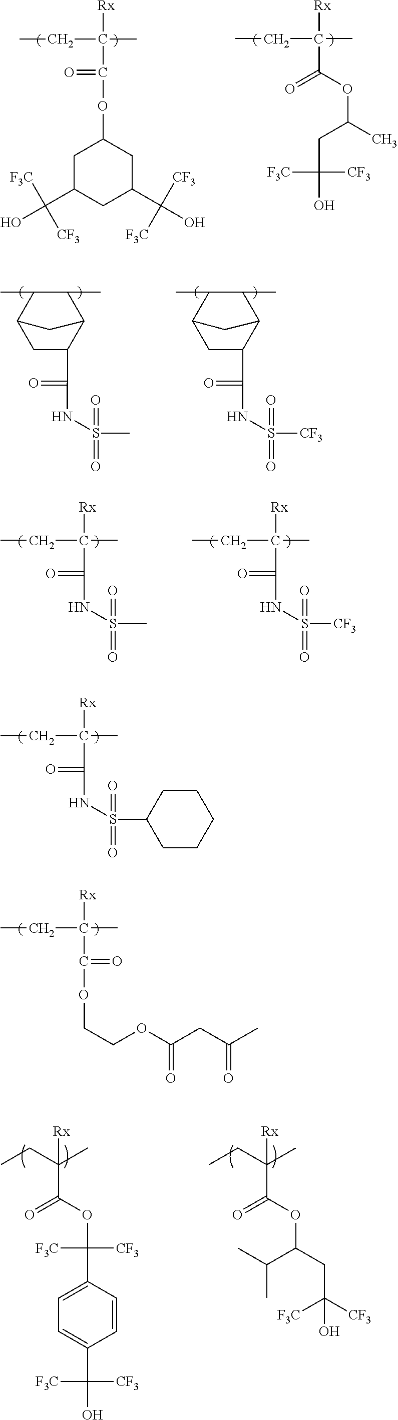

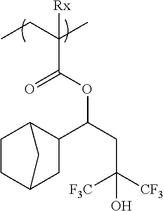

Among the group with a lactone structure, acid anhydride group and acid imido group (y), the group with a lactone structure is especially preferred.

The repeating unit containing any of these groups is, for example, a repeating unit wherein the group is directly bonded to the principal chain of a resin, such as a repeating unit derived from an acrylic ester or a methacrylic ester. Alternatively, this repeating unit may be a repeating unit wherein the group is bonded via a connecting group to the principal chain of a resin. Still alternatively, this repeating unit may be a repeating unit wherein the group is introduced in a terminal of the resin by using a chain transfer agent or polymerization initiator containing the group in the stage of polymerization.

As the repeating unit containing a group with a lactone structure, there can be mentioned, for example, any of the same repeating units with lactone structures as set forth above in connection with the acid-decomposable resin (P).

The content of repeating unit containing a group with a lactone structure, an acid anhydride group or an acid imido group, based on all the repeating units of the hydrophobic resin (HR), is preferably in the range of 1 to 100 mol %, more preferably 3 to 98 mol % and further more preferably 5 to 95 mol %.

As the repeating unit containing a group (z) decomposable under the action of an acid introduced in the hydrophobic resin (HR), there can be mentioned any of the same repeating units containing acid-decomposable groups as set forth above in connection with the resin (P). The repeating unit having a group (z) decomposed under the action of an acid may contain at least either a fluorine atom or a silicon atom. The content of repeating unit having a group (z) decomposed under the action of an acid in the hydrophobic resin (HR), based on all the repeating units of the hydrophobic resin (HR), is preferably in the range of 1 to 80 mol %, more preferably 10 to 80 mol % and further more preferably 20 to 60 mol %.

The hydrophobic resin (HR) may further contain any of the repeating units represented by general formula (V) below.

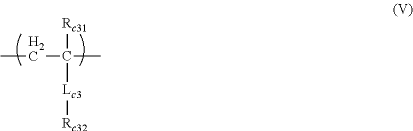

In general formula (V),

R_{c31} represents a hydrogen atom, an alkyl group, an alkyl group optionally substituted with one or more fluorine atoms, a cyano group or a group of the formula —CH₂—O—R_{ac2} in which R_{ac2} represents a hydrogen atom, an alkyl group or an acyl group. R_{c31} is preferably a hydrogen atom, a methyl group, a hydroxymethyl group, or a trifluoromethyl group, more preferably a hydrogen atom or a methyl group.

R_{c32} represents a group containing an alkyl group, a cycloalkyl group, an alkenyl group, a cycloalkenyl group, or an aryl group. These groups may be substituted with fluorine atom and/or silicon atom.

L_{c3} represents a single bond or a bivalent connecting group.

In general formula (V), the alkyl group represented by R_{c32} is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms. A phenyl group and a naphthyl group are more preferred. Substituents may be introduced therein.

Preferably, R_{c32} represents an unsubstituted alkyl group or an alkyl group substituted with a fluorine atom.

The bivalent connecting group represented by L_{c3} is preferably an alkylene group (preferably having 1 to 5 carbon atoms), an ether bond, a phenylene group or an ester bond (group of the formula —COO—).

The content of repeating unit expressed by general formula (V), based on all the repeating units of the hydrophobic resin, is preferably in the range of 1 to 100 mol %, more preferably 10 to 90 mol % and further more preferably 30 to 70 mol %.

The hydrophobic resin (HR) may further contain any of the repeating units represented by general formula (CII-AB) below.

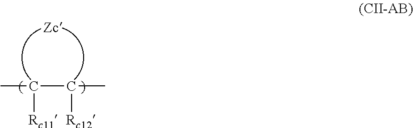

In formula (CII-AB),

each of R_{c11′} and R_{c12′} independently represents a hydrogen atom, a cyano group, a halogen atom or an alkyl group.

Zc′ represents an atomic group required for forming an alicyclic structure in cooperation with two carbon atoms (C—C) to which R_{c11′} and R_{c12′} are respectively bonded.

The content of repeating unit expressed by general formula (CII-AB), based on all the repeating units of the hydrophobic resin, is preferably in the range of 1 to 100 mol %, more preferably 10 to 90 mol % and further more preferably 30 to 70 mol %.

Specific examples of the repeating unit represented by general formulae (V) or (CII-AB) will be shown below, which however in no way limit the scope of the present invention. In the formulae, Ra represents H, CH₃, CH₂OH, CF₃ or CN.

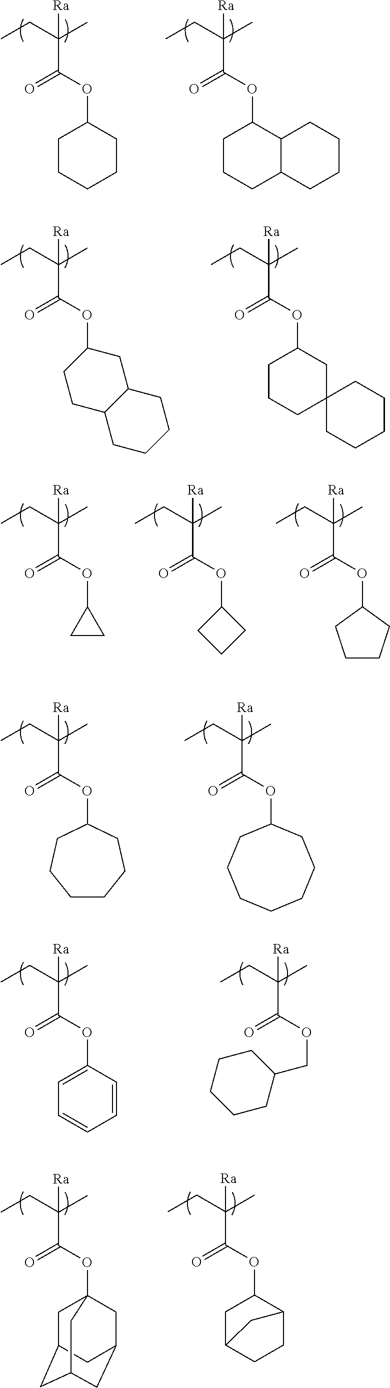

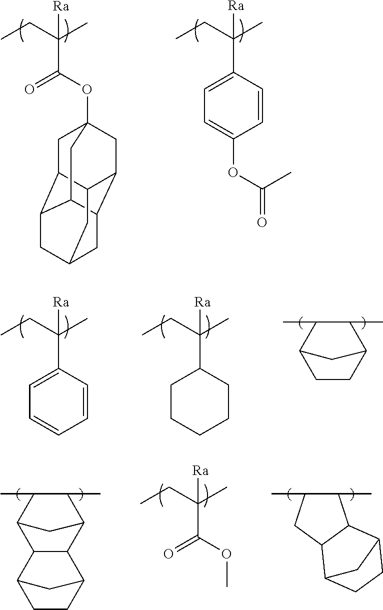

When the hydrophobic resin (HR) contains a fluorine atom, the content of fluorine atom(s) is preferably in the range of 5 to 80 mass %, more preferably 10 to 80 mass %, based on the weight average molecular weight of the hydrophobic resin. The content of the repeating unit containing a fluorine atom is preferably in the range of 10 to 100 mol %, more preferably 30 to 100 mol %, based on all the repeating units of the hydrophobic resin (HR).

When the hydrophobic resin (HR) contains a silicon atom, the content of silicon atom(s) is preferably in the range of 2 to 50 mass %, more preferably 2 to 30 mass %, based on the weight average molecular weight of the hydrophobic resin. The content of the repeating unit containing a silicon atom is preferably in the range of 10 to 100 mol %, more preferably 20 to 100 mol %, based on all the repeating units of the hydrophobic resin (HR).

Meanwhile, when the resin (HR) contains a CH₃ partial structure in its side chain portion, an embodiment in which the resin (HR) contains substantially none of fluorine and silicon atoms is preferred. In that instance, in particular, the content of repeating unit containing a fluorine atom or a silicon atom based on all the repeating units of the resin (HR) is preferably 5 mol % or less, more preferably 3 mol % or less, further more preferably 1 mol % or less, and ideally 0 mol %, namely, containing none of fluorine and silicon atoms. Moreover, it is preferred for the resin (HR) to be comprised of substantially only a repeating unit comprised of only an atom(s) selected from among a carbon atom, an oxygen atom, a hydrogen atom, a nitrogen atom and a sulfur atom. In particular, the content of repeating unit comprised of only an atom(s) selected from among a carbon atom, an oxygen atom, a hydrogen atom, a nitrogen atom and a sulfur atom based on all the repeating units of the resin (HR) is preferably 95 mol % or more, more preferably 97 mol % or more, further more preferably 99 mol % or more, and ideally 100 mol %.

The weight average molecular weight of the hydrophobic resin (HR) in terms of standard polystyrene molecular weight is preferably in the range of 1000 to 100,000, more preferably 1000 to 50,000 and still more preferably 2000 to 15,000.

The hydrophobic resin (HR) may be used either individually or in combination.

The content of the hydrophobic resin (HR) in the composition is preferably in the range or 0.01 to 10 mass %, more preferably 0.05 to 8 mass % and still more preferably 0.1 to 5 mass % based on the total solid of the composition of the present invention.

In the hydrophobic resin (HR), impurities, such as metals, should naturally be of low quantity as in the resin (P). The content of residual monomers and oligomer components is preferably in the range of 0.01 to 5 mass %, more preferably 0.01 to 3 mass % and further more preferably 0.05 to 1 mass %. If so, there can be obtained an actinic-ray- or radiation-sensitive resin composition being free from any in-liquid foreign matter and a change of sensitivity, etc. over time. From the viewpoint of resolution, resist shape, side wall of resist pattern, roughness, etc., the molecular weight distribution (Mw/Mn, also referred to as polydispersity index) thereof is preferably in the range of 1 to 5, more preferably 1 to 3 and further more preferably 1 to 2.

A variety of commercially available products can be used as the hydrophobic resin (HR). Alternatively, the hydrophobic resin (HR) can be synthesized in accordance with routine methods (for example, radical polymerization). As general synthesizing methods, there can be mentioned, for example, a batch polymerization method in which a monomer species and an initiator are dissolved in a solvent and heated to thereby carry out polymerization, a dropping polymerization method in which a solution of monomer species and initiator is dropped into a heated solvent over a period of 1 to 10 hours, etc. The dropping polymerization method is preferred.

The reaction solvent, polymerization initiator, reaction conditions (temperature, concentration, etc.) and purification method after reaction are the same as described above in connection with the resin (P). In the synthesis of the hydrophobic resin (HR), it is preferred for the concentration condition of the reaction to be in the range of 30 to 50 mass %.

Specific examples of the hydrophobic resin (HR) will be shown below. The following Table 1 shows the molar ratio of individual repeating units (corresponding to individual repeating units in order from the left), weight average molecular weight, and degree of dispersal with respect to each of the resins.

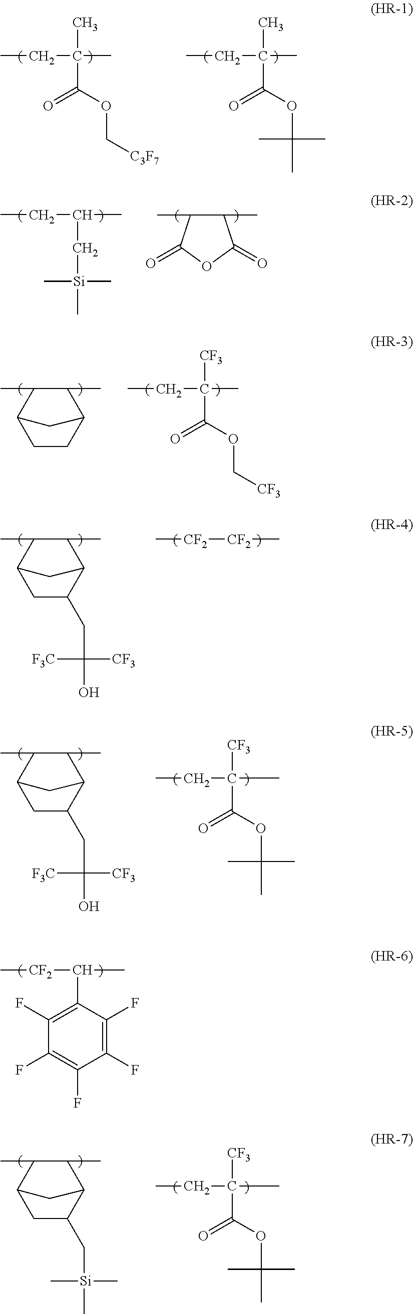

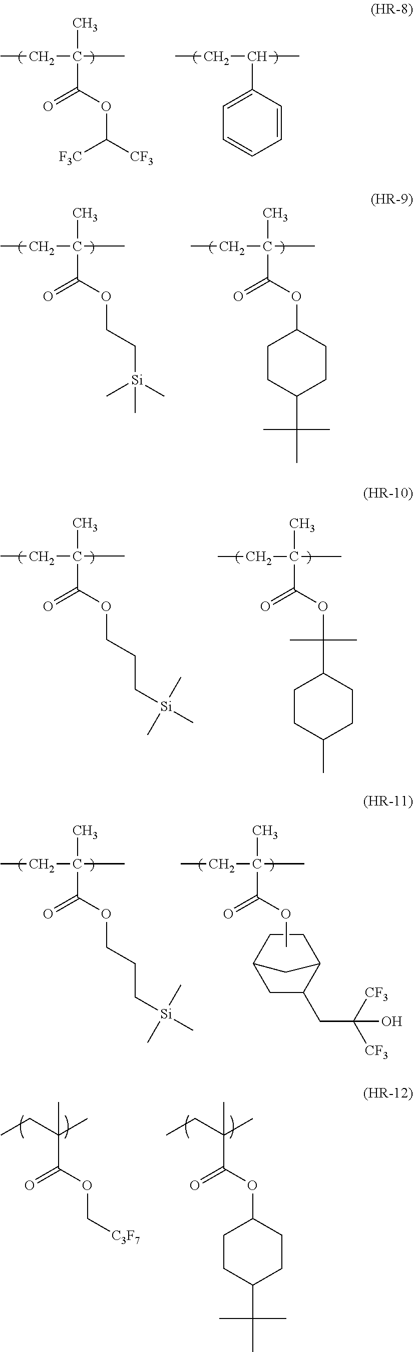

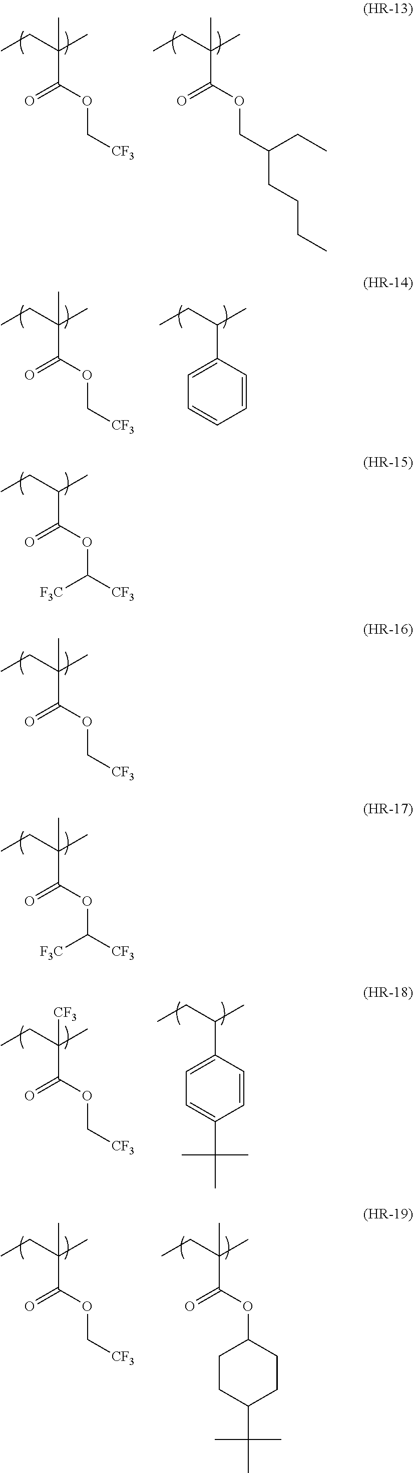

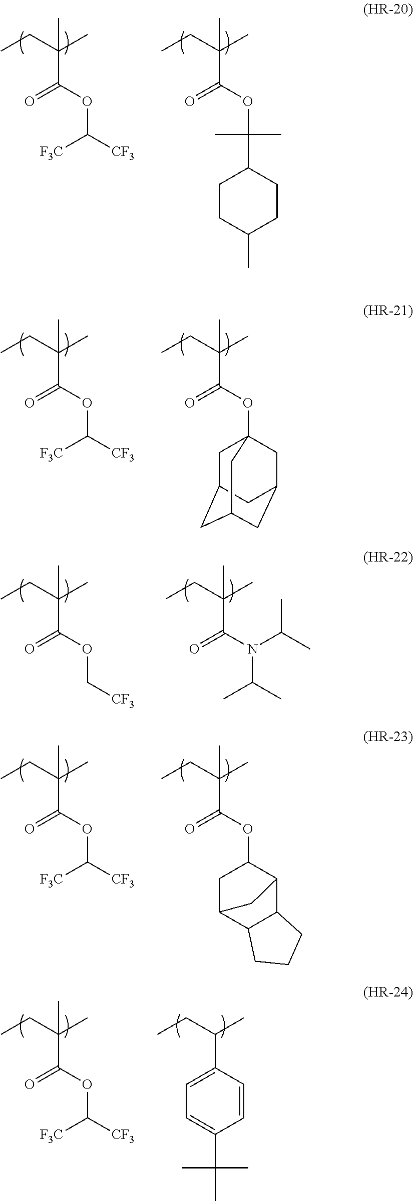

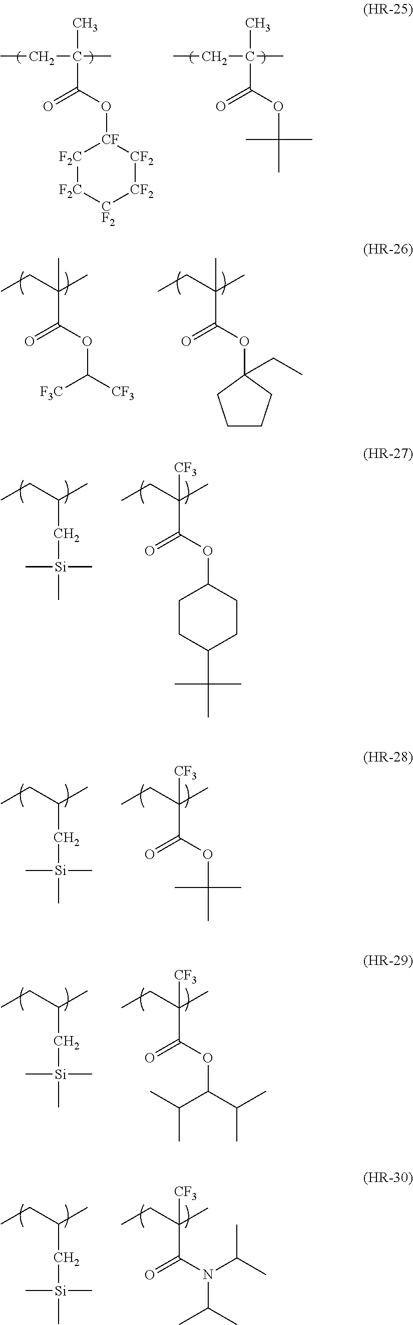

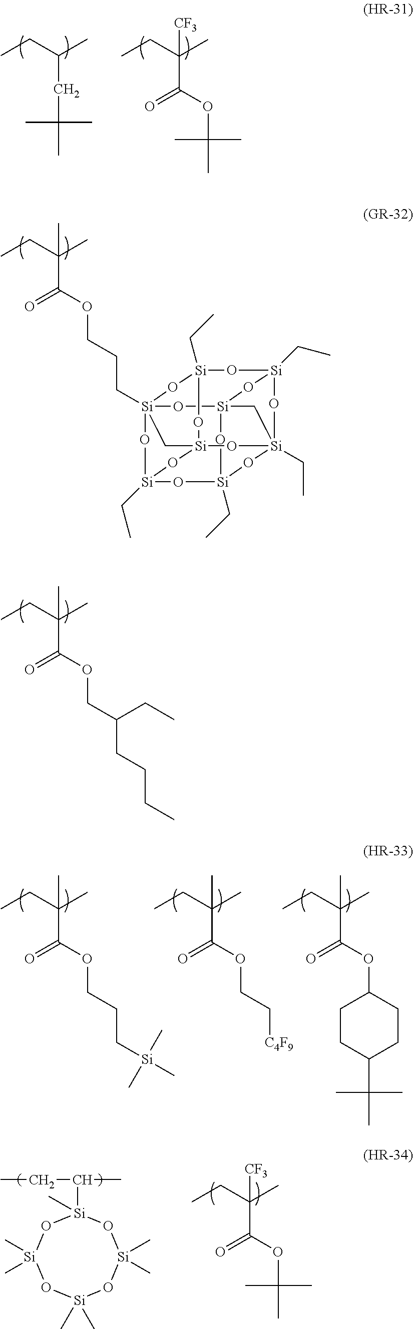

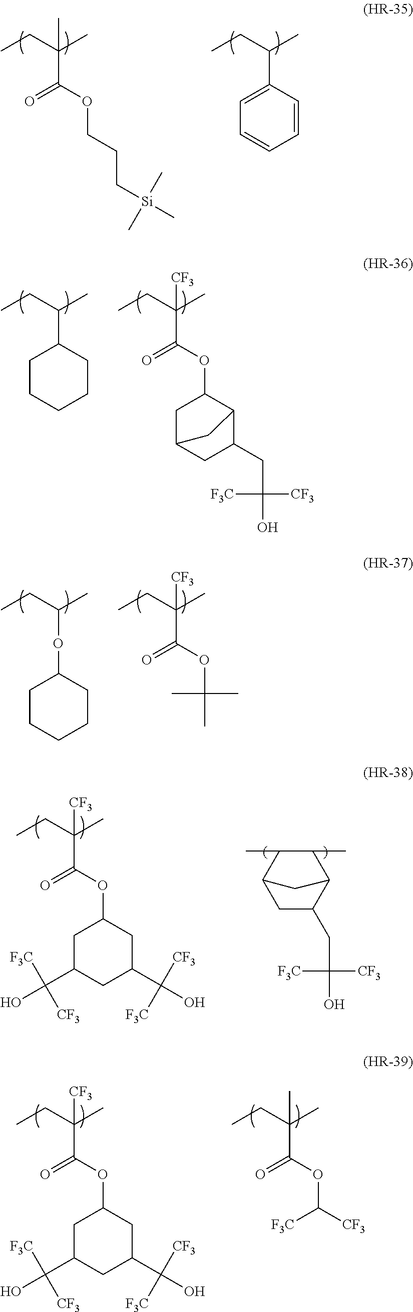

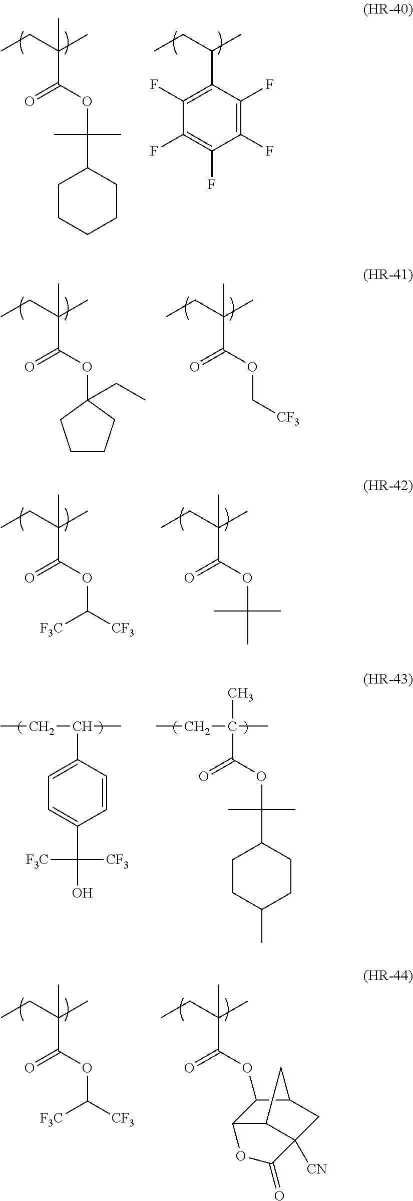

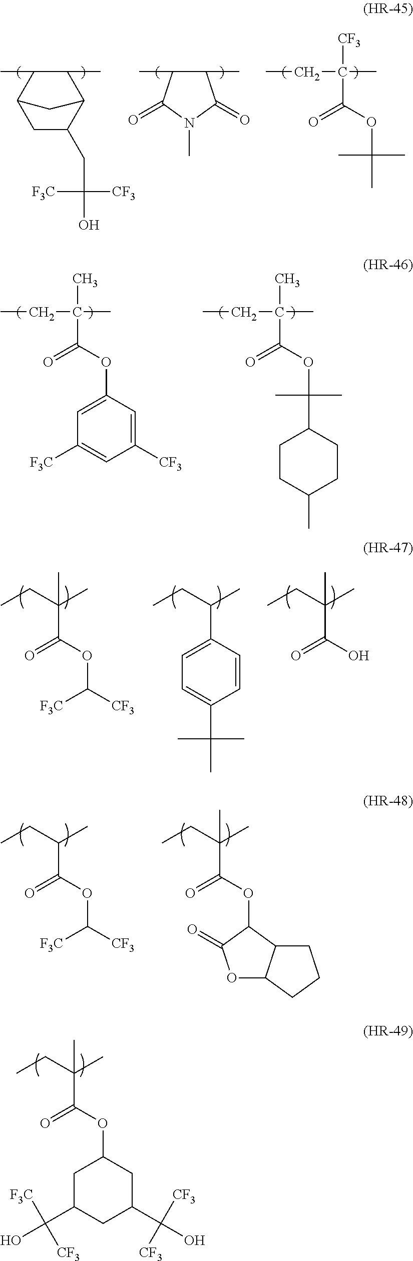

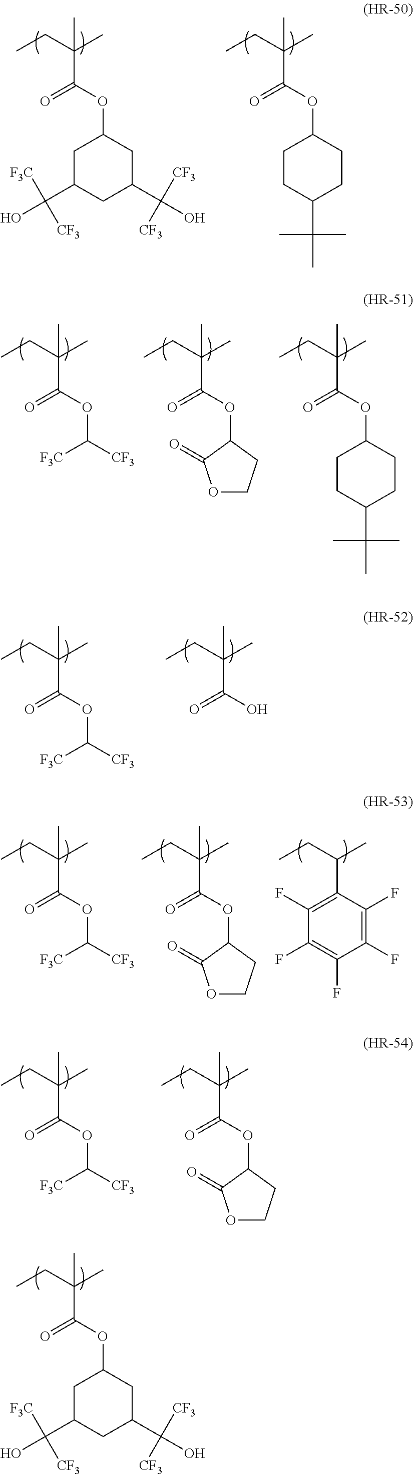

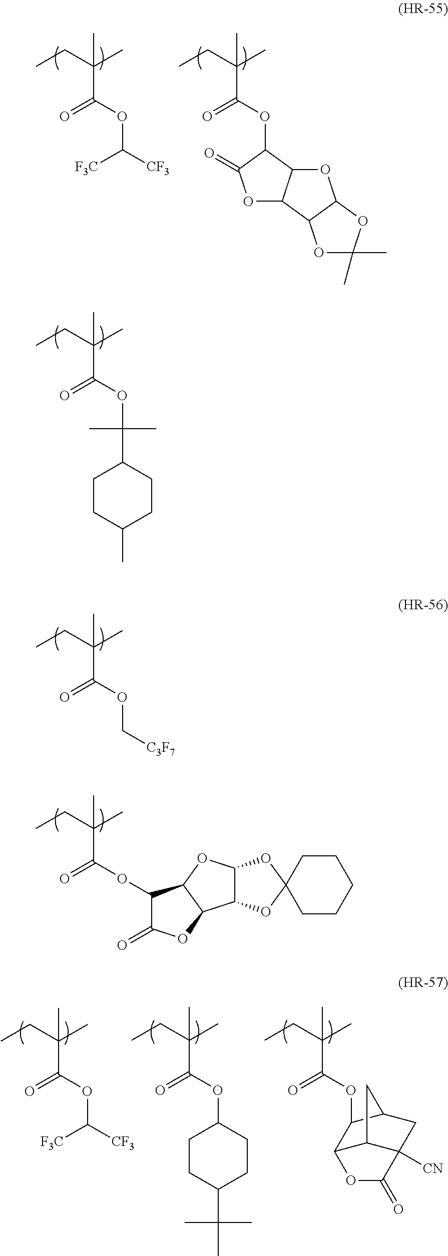

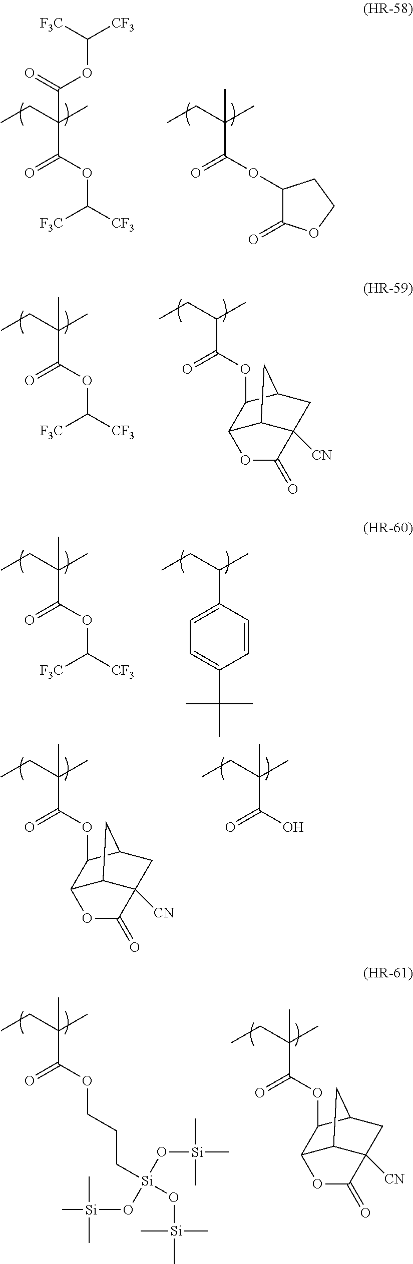

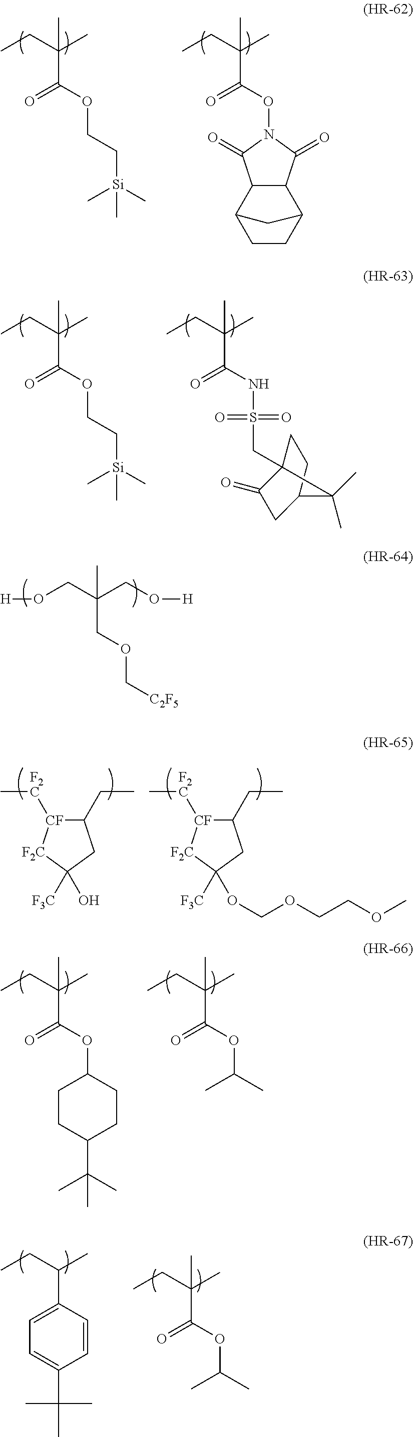

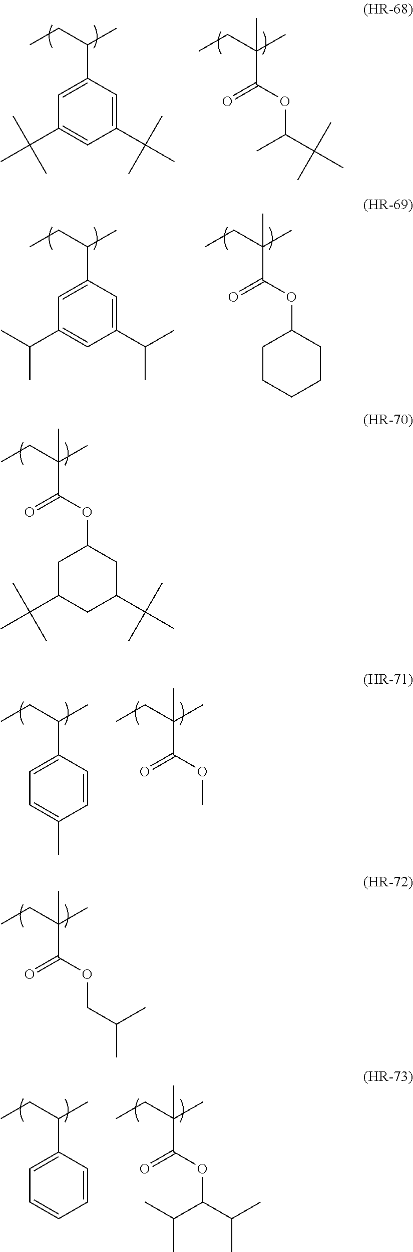

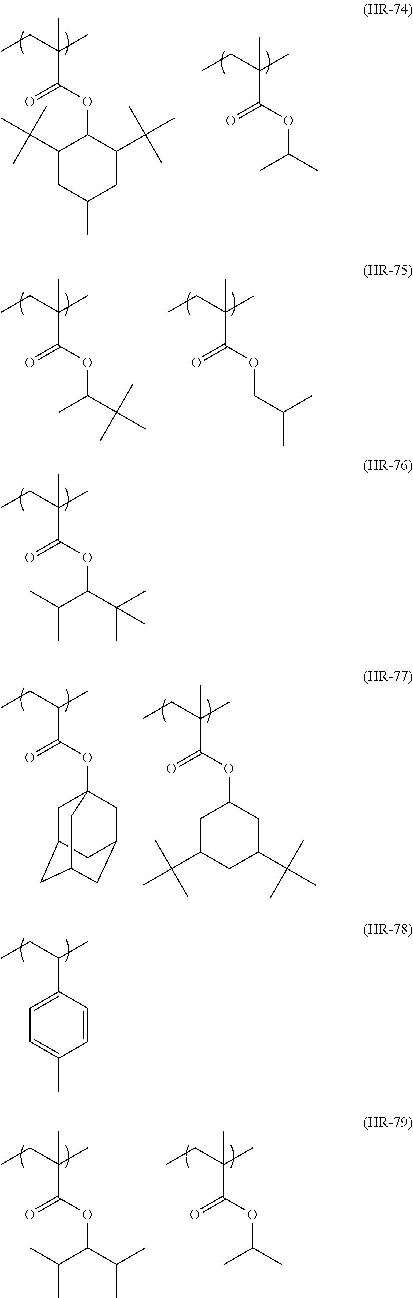

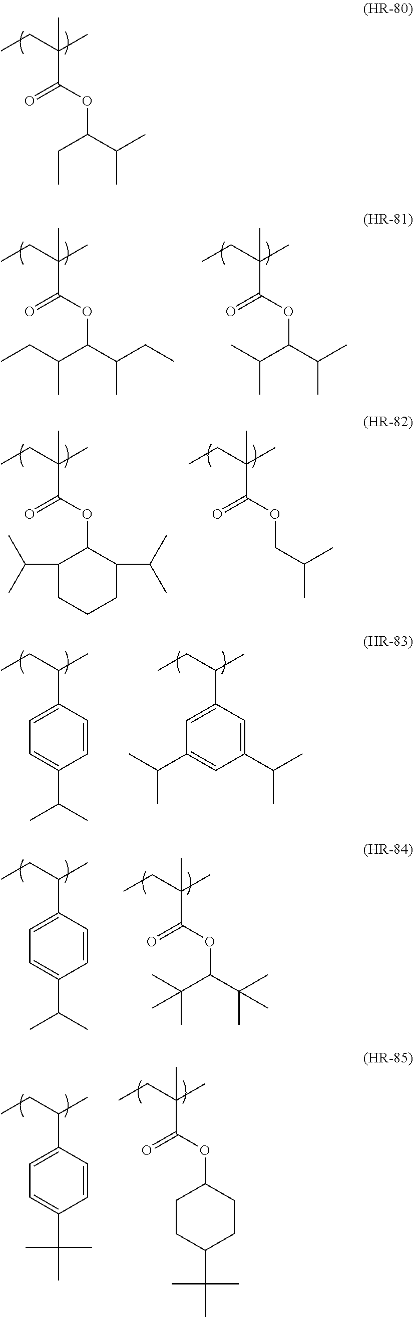

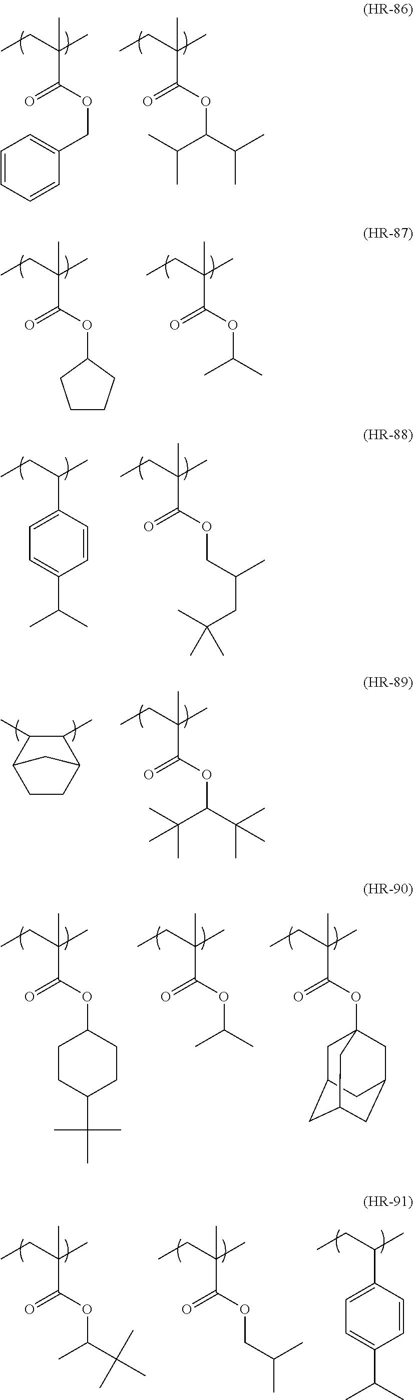

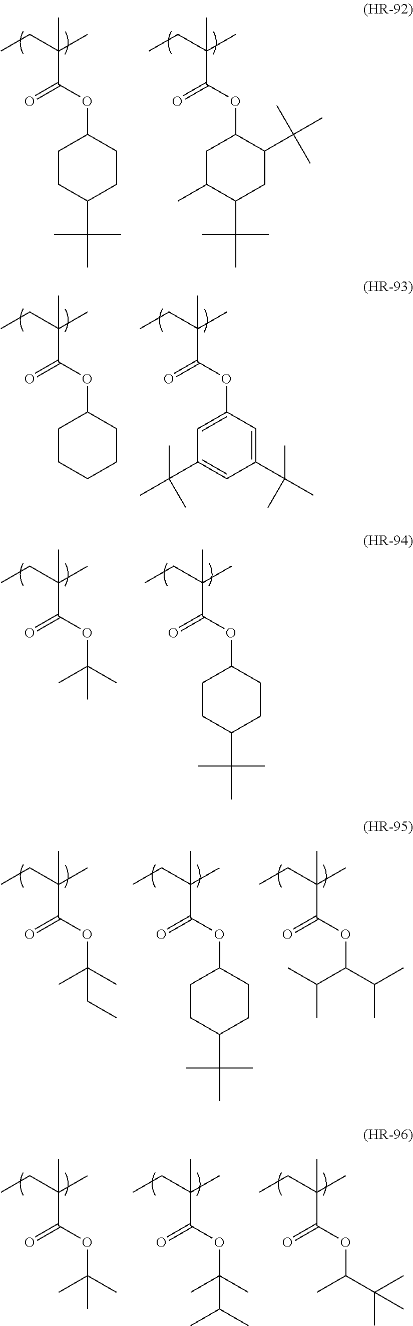

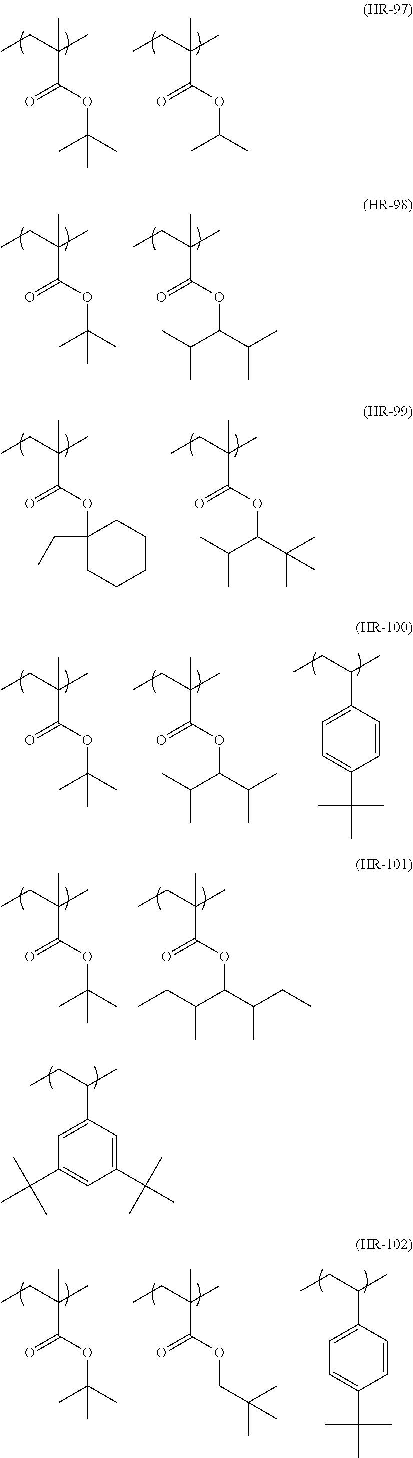

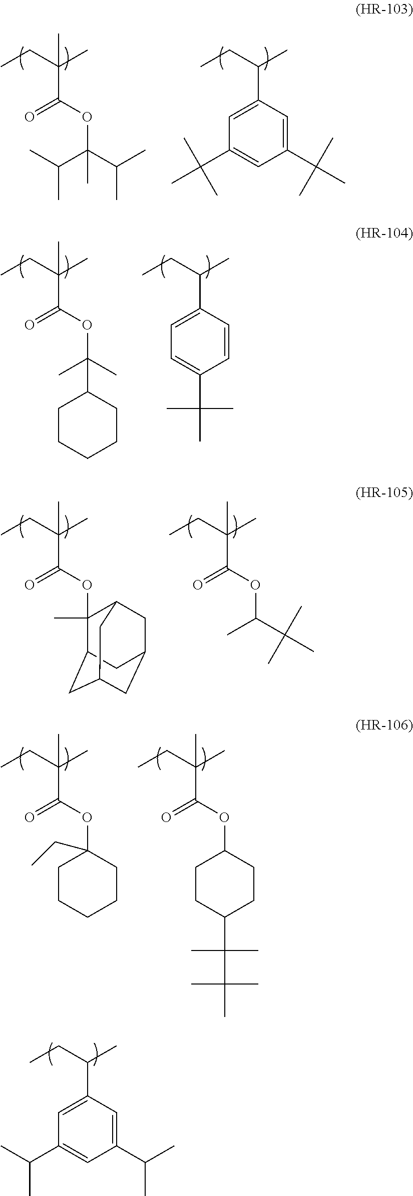

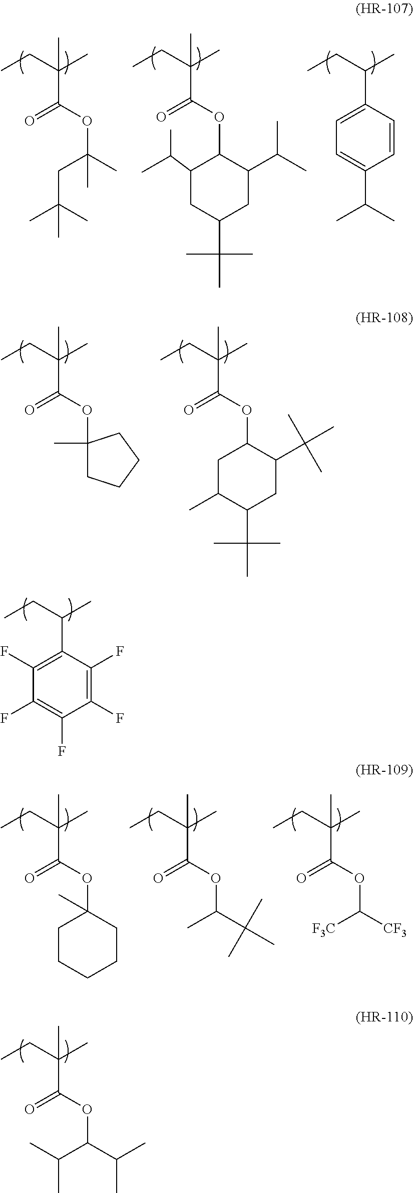

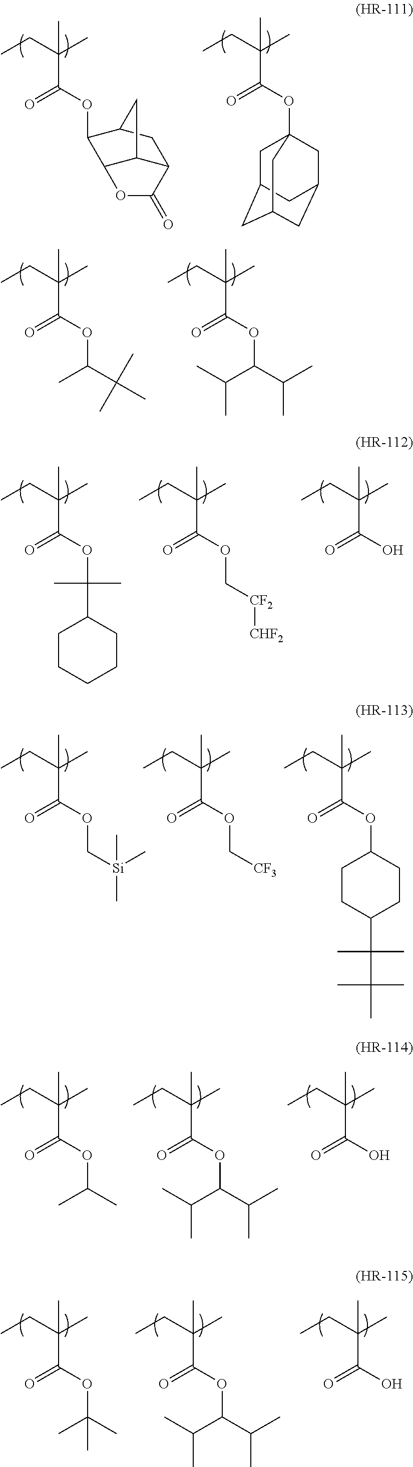

TABLE 1

| Resin | Comp. ratio | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |
| HR-66 | 50/50 | 9600 | 1.74 |
| HR-67 | 60/40 | 34500 | 1.43 |
| HR-68 | 30/70 | 19300 | 1.69 |
| HR-69 | 10/90 | 26400 | 1.41 |
| HR-70 | 100 | 27600 | 1.87 |
| HR-71 | 80/20 | 4400 | 1.96 |
| HR-72 | 100 | 16300 | 1.83 |
| HR-73 | 5/95 | 24500 | 1.79 |
| HR-74 | 20/80 | 15400 | 1.68 |
| HR-75 | 50/50 | 23800 | 1.46 |
| HR-76 | 100 | 22400 | 1.57 |
| HR-77 | 10/90 | 21600 | 1.52 |
| HR-78 | 100 | 28400 | 1.58 |
| HR-79 | 50/50 | 16700 | 1.82 |
| HR-80 | 100 | 23400 | 1.73 |
| HR-81 | 60/40 | 18600 | 1.44 |
| HR-82 | 80/20 | 12300 | 1.78 |
| HR-83 | 40/60 | 18400 | 1.58 |
| HR-84 | 70/30 | 12400 | 1.49 |
| HR-85 | 50/50 | 23500 | 1.94 |
| HR-86 | 10/90 | 7600 | 1.75 |
| HR-87 | 5/95 | 14100 | 1.39 |
| HR-88 | 50/50 | 17900 | 1.61 |
| HR-89 | 10/90 | 24600 | 1.72 |
| HR-90 | 50/40/10 | 23500 | 1.65 |
| HR-91 | 60/30/10 | 13100 | 1.51 |
| HR-92 | 50/50 | 21200 | 1.84 |
| HR-93 | 10/90 | 19500 | 1.66 |
| HR-94 | 50/50 | 16500 | 1.72 |
| HR-95 | 10/50/40 | 18000 | 1.77 |
| HR-96 | 5/50/45 | 27100 | 1.69 |
| HR-97 | 20/80 | 26500 | 1.79 |
| HR-98 | 10/90 | 24700 | 1.83 |
| HR-99 | 10/90 | 15700 | 1.99 |
| HR-100 | 5/90/5 | 21500 | 1.92 |
| HR-101 | 5/60/35 | 17700 | 2.1 |
| HR-102 | 35/35/30 | 25100 | 2.02 |
| HR-103 | 70/30 | 19700 | 1.85 |
| HR-104 | 75/25 | 23700 | 1.8 |
| HR-105 | 10/90 | 20100 | 2.02 |
| HR-106 | 5/35/60 | 30100 | 2.17 |
| HR-107 | 5/45/50 | 22900 | 2.02 |
| HR-108 | 15/75/10 | 28600 | 1.81 |
| HR-109 | 25/55/20 | 27400 | 1.87 |
| HR-110 | 100 | 25000 | 1.62 |
| HR-111 | 3/3/80/14 | 39600 | 1.83 |
| HR-112 | 15/80/5 | 5500 | 1.76 |
| HR-113 | 5/70/25 | 16000 | 1.66 |
| HR-114 | 30/65/5 | 25400 | 1.65 |
| HR-115 | 30/65/5 | 22000 | 1.71 |

[5] Basic Compound

[5-1] Basic Compound and Ammonium Salt Compound (N) that when exposed to actinic rays or radiation, exhibit lowered basicity

It is preferred for the actinic-ray- or radiation-sensitive resin composition of the present invention to contain a basic compound or ammonium salt compound (hereinafter also referred to as a “compound (N)”) that when exposed to actinic rays or radiation, exhibits a lowered basicity.

It is preferred for the compound (N) to be a compound (N-1) containing a basic functional group or ammonium group together with a group that when exposed to actinic rays or radiation, produces an acid functional group. Namely, it is preferred for the compound (N) to be a basic compound containing a basic functional group together with a group that when exposed to actinic rays or radiation, produces an acid functional group, or an ammonium salt compound containing an ammonium group together with a group that when exposed to actinic rays or radiation, produces an acid functional group.

As particular compounds (N), use can be made of any of the compounds set forth as component (C) in US Patent Application Publication No. 2012/0058427.

In the present invention, the lowering of basicity upon exposure to actinic rays or radiation means that the acceptor properties for the proton (acid produced by exposure to actinic rays or radiation) of the compound (N) are lowered by exposure to actinic rays or radiation. The lowering of acceptor properties means that when an equilibrium reaction in which a noncovalent-bond complex being a proton adduct is formed from a proton and a compound containing a basic functional group occurs, or when an equilibrium reaction in which the counter cation of a compound containing an ammonium group is replaced by a proton occurs, the equilibrium constant of the chemical equilibrium is lowered.

When the compound (N) whose basicity is lowered upon exposure to actinic rays or radiation is contained in the resist film, in nonexposed areas, the acceptor properties of the compound (N) are fully exhibited, so that any unintended reaction between the acid diffused from exposed areas, etc. and the resin (P) can be suppressed. In exposed areas, the acceptor properties of the compound (N) are lowered, so that the intended reaction between the acid and the resin (A) occurs with high certainty. It is presumed that, by virtue of the contribution of this activity mechanism, a pattern excelling in line width roughness (LWR), local uniformity of pattern dimension, focus latitude (depth of focus DOF) and pattern shape can be obtained.

The molecular weight of the compound (N) is preferably in the range of 500 to 1000.

It is optional for the actinic-ray- or radiation-sensitive resin composition of the present invention to contain the compound (N). When the compound (N) is contained, the content thereof based on the total solids of the actinic-ray- or radiation-sensitive resin composition is preferably in the range of 0.1 to 20 mass %, more preferably 0.1 to 10 mass %.

[5-2] Basic Compound (N′)

The actinic-ray- or radiation-sensitive resin composition of the present invention may contain a basic compound (N′) different from the above compounds (N) so as to minimize any performance change over time from exposure to bake.

As preferred basic compounds (N′), there can be mentioned the compounds having the structures of the following formulae (A) to (E).

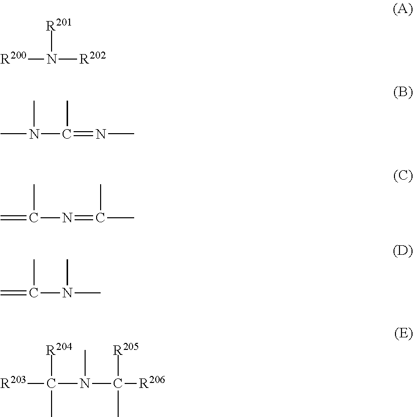

In general formulae (A) and (E),

R²⁰⁰, R²⁰¹ and R²⁰² may be identical to or different from each other and each represent a hydrogen atom, an alkyl group (preferably having 1 to 20 carbon atoms), a cycloalkyl group (preferably having 3 to 20 carbon atoms) or an aryl group (having 6 to 20 carbon atoms). R²⁰¹ and R²⁰² may be bonded to each other to thereby form a ring. R²⁰³, R²⁰⁴, R²⁰⁵ and R²⁰⁶ may be identical to or different from each other and each represent an alkyl group having 1 to 20 carbon atoms.

With respect to these alkyl groups, as a preferred substituted alkyl group, there can be mentioned an aminoalkyl group having 1 to 20 carbon atoms, a hydroxyalkyl group having 1 to 20 carbon atoms or a cyanoalkyl group having 1 to 20 carbon atoms.

More preferably, the alkyl groups in general formulae (A) and (E) are unsubstituted.

As preferred compounds, there can be mentioned guanidine, aminopyrrolidine, pyrazole, pyrazoline, piperazine, aminomorpholine, an aminoalkylmorpholine, piperidine and the like. As more preferred compounds, there can be mentioned compounds with an imidazole structure, a diazabicyclo structure, an onium hydroxide structure, an onium carboxylate structure, a trialkylamine structure, an aniline structure or a pyridine structure, alkylamine derivatives containing a hydroxyl group and/or an ether bond, aniline derivatives containing a hydroxyl group and/or an ether bond, and the like.

As the compounds with an imidazole structure, there can be mentioned imidazole, 2,4,5-triphenylimidazole, benzimidazole, 2-phenylbenzimidazole and the like. As the compounds with a diazabicyclo structure, there can be mentioned 1,4-diazabicyclo[2,2,2]octane, 1,5-diazabicyclo[4,3,0]non-5-ene, 1,8-diazabicyclo[5,4,0]undec-7-ene and the like. As the compounds with an onium hydroxide structure, there can be mentioned a triarylsulfonium hydroxide, phenacylsulfonium hydroxide, and sulfonium hydroxides containing a 2-oxoalkyl group such as triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide and the like. As the compounds with an onium carboxylate structure, there can be mentioned those having the anion moiety of the compounds with an onium hydroxide structure replaced by a carboxylate, for example, an acetate, an adamantane-1-carboxylate, a perfluoroalkyl carboxylate and the like. As the compounds with a trialkylamine structure, there can be mentioned tri(n-butyl)amine, tri(n-octyl)amine and the like. As the compounds with an aniline structure, there can be mentioned 2,6-diisopropylaniline, N,N-dimethylaniline, N,N-dibutylaniline, N,N-dihexylaniline and the like. As the alkylamine derivatives containing a hydroxyl group and/or an ether bond, there can be mentioned ethanolamine, diethanolamine, triethanolamine, tris(methoxyethoxyethyl)amine, tris(hydroxyethoxyethyl)amine and the like. As the aniline derivatives containing a hydroxyl group and/or an ether bond, there can be mentioned N,N-bis(hydroxyethyl)aniline and the like.

As preferred basic compounds (N′), there can be further mentioned an amine compound containing a phenoxy group, an ammonium salt compound containing a phenoxy group, an amine compound containing a sulfonic ester group and an ammonium salt compound containing a sulfonic ester group.

Each of the above amine compound containing a phenoxy group, ammonium salt compound containing a phenoxy group, amine compound containing a sulfonic ester group and ammonium salt compound containing a sulfonic ester group preferably contains at least one alkyl group bonded to the nitrogen atom thereof. Further preferably, the alkyl group in its chain contains an oxygen atom, thereby forming an oxyalkylene group. The number of oxyalkylene groups in each molecule is one or more, preferably 3 to 9 and more preferably 4 to 6. Among the oxyalkylene groups, the structures of —CH₂CH₂O—, —CH(CH₃)CH₂O— and —CH₂CH₂CH₂O— are preferred.

As specific examples of the above amine compound containing a phenoxy group, ammonium salt compound containing a phenoxy group, amine compound containing a sulfonic ester group and ammonium salt compound containing a sulfonic ester group, there can be mentioned the compounds (C1-1) to (C3-3) shown as examples in Section [0066] of U.S. Patent Application Publication No. 2007/0224539, which are however nonlimiting.

As one of the basic compounds (N′), a nitrogen-containing organic compound containing a group leaving under the action of an acid is more preferred. As an example of this compound, there can be mentioned any of compounds of general formula (F) below. The compounds of general formula (F) below manifests an effective basicity in the system through the cleavage of the group leaving under the action of an acid.

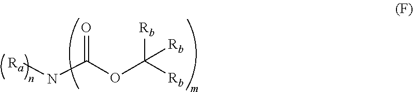

In general formula (F), Ra, or each of Ra's independently, represents a hydrogen atom, an alkyl group, a cycloalkyl group, an aryl group or an aralkyl group. When n=2, two Ra's may be identical to or different from each other, and two Ra's may be bonded to each other to thereby form a bivalent heterocyclic hydrocarbon group (preferably up to 20 carbon atoms) or a derivative thereof.

Each of Rb's independently represents a hydrogen atom, an alkyl group, a cycloalkyl group, an aryl group or an aralkyl group, provided that in the moiety —C(Rb)(Rb)(Rb), when one or more Rb's are hydrogen atoms, at least one of the remaining Rb's is a cyclopropyl group or a 1-alkoxyalkyl group.

At least two Rb's may be bonded to each other to thereby form an alicyclic hydrocarbon group, an aromatic hydrocarbon group, a heterocyclic hydrocarbon group or a derivative thereof.

In the formula, n is an integer of 0 to 2, and m is an integer of 1 to 3, provided that n+m=3.

In general formula (F) above, each of the alkyl groups, cycloalkyl groups, aryl groups and aralkyl groups represented by Ra and Rb may be substituted with a functional group, such as a hydroxyl group, a cyano group, an amino group, a pyrrolidino group, a piperidino group, a morpholino group or an oxo group, as well as an alkoxy group or a halogen atom. With respect to the alkoxyalkyl group represented by Rb, the same substitution can be performed.

As the alkyl group, cycloalkyl group, aryl group and aralkyl group represented by Ra and/or Rb (these alkyl group, cycloalkyl group, aryl group and aralkyl group may be substituted with the above functional group, alkoxy group or halogen atom), there can be mentioned, for example,

a group derived from a linear or branched alkane, such as methane, ethane, propane, butane, pentane, hexane, heptane, octane, nonane, decane, undecane or dodecane; a group as obtained by substituting the above alkane-derived group with at least one or at least one type of cycloalkyl group, such as a cyclobutyl group, a cyclopentyl group or a cyclohexyl group;

a group derived from a cycloalkane, such as cyclobutane, cyclopentane, cyclohexane, cycloheptane, cyclooctane, norbornane, adamantane or noradamantane; a group as obtained by substituting the above cycloalkane-derived group with at least one or at least one type of linear or branched alkyl group, such as a methyl group, an ethyl group, an n-propyl group, an i-propyl group, an n-butyl group, a 2-methylpropyl group, a 1-methylpropyl group or a t-butyl group;

a group derived from an aromatic compound, such as benzene, naphthalene or anthracene; a group as obtained by substituting the above aromatic-compound-derived group with at least one or at least one type of linear or branched alkyl group, such as a methyl group, an ethyl group, an n-propyl group, an i-propyl group, an n-butyl group, a 2-methylpropyl group, a 1-methylpropyl group or a t-butyl group;

a group derived from a heterocyclic compound, such as pyrrolidine, piperidine, morpholine, tetrahydrofuran, tetrahydropyran, indole, indoline, quinoline, perhydroquinoline, indazole or benzimidazole; a group as obtained by substituting the above heterocyclic-compound-derived group with at least one or at least one type of linear or branched alkyl group or aromatic-compound-derived group;

a group as obtained by substituting the above linear or branched-alkane-derived group or cycloalkane-derived group with at least one or at least one type of aromatic-compound-derived group, such as a phenyl group, a naphthyl group or an anthracenyl group; any of groups as obtained by substituting the above substituents with a functional group, such as a hydroxyl group, a cyano group, an amino group, a pyrrolidino group, a piperidino group, a morpholino group or an oxo group; and the like.

Particular examples of the basic compounds (N′) according to the present invention are shown below, which however in no way limit the scope of the present invention.

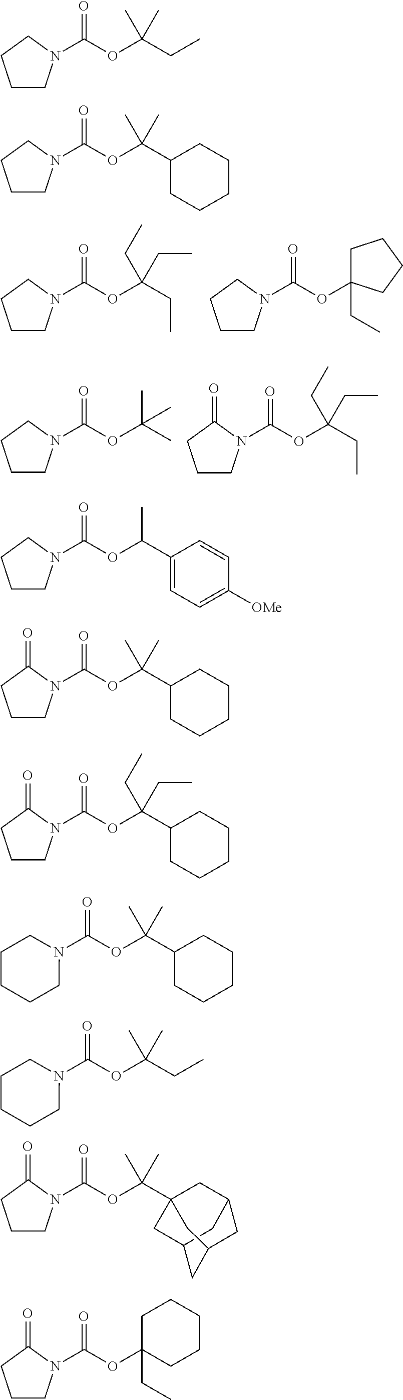

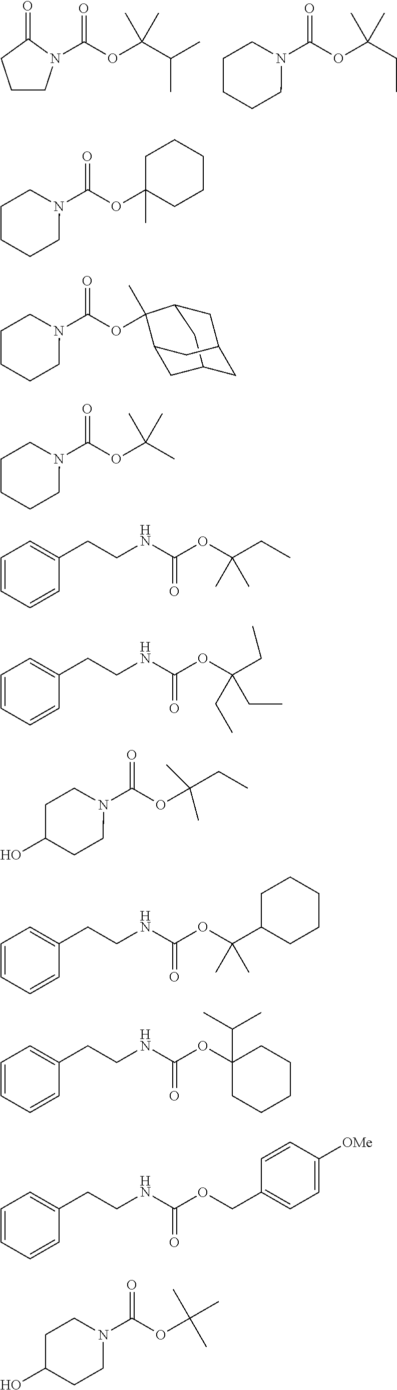

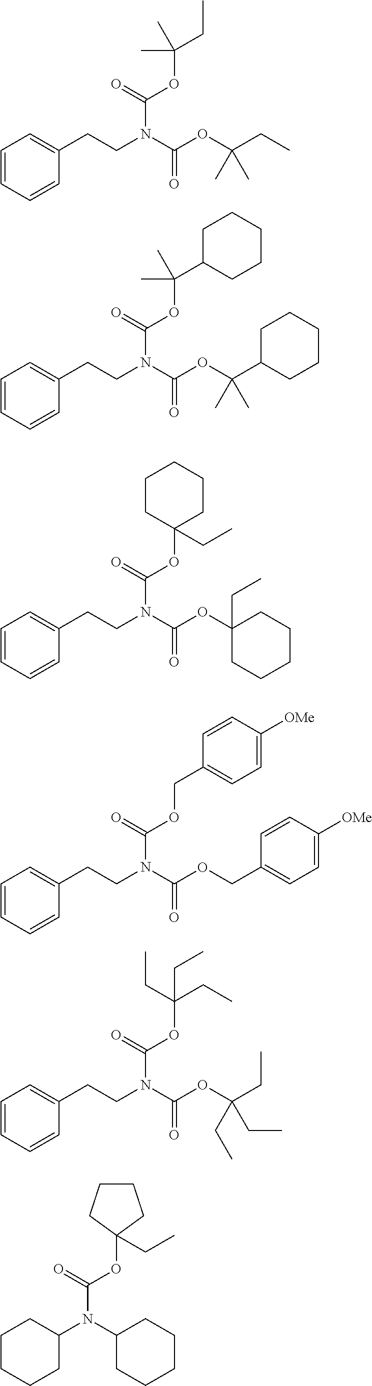

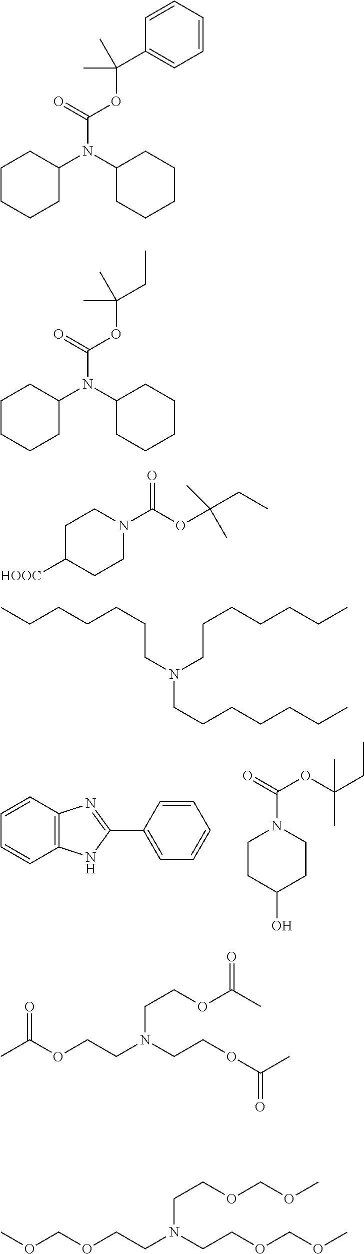

As the compounds of general formula (F) above, use can be made of commercially available products. They also may be synthesized from commercially available amines by the methods described in, for example, Protective Groups in Organic Synthesis, the fourth edition. The most common synthetic method can be found in, for example, JP-A-2009-199021.

Moreover, as the basic compounds (N′), use can be made of compounds each containing a fluorine atom or a silicon atom and exhibiting basicity or increasing its basicity under the action of an acid, as described in JP-A-2011-141494. As particular examples of these compounds, there can be mentioned, for example, the compounds (B-7) to (B-18) used in Examples of the publication.

The molecular weight of the basic compounds (N′) is preferably in the range of 250 to 2000, more preferably 400 to 1000. From the viewpoint of further lowering of LWR and local uniformity of pattern dimension, the molecular weight of the basic compounds is preferably 400 or greater, more preferably 500 or greater and further more preferably 600 or greater.

These basic compounds (N′) may be used in combination with the above compounds (N). Any one of the basic compounds (N′) may be used alone, or two or more thereof may be used in combination.

It is optional for the actinic-ray- or radiation-sensitive resin composition of the present invention to contain any of the basic compounds (N′). When any of the basic compounds (N′) is contained, the content thereof is generally in the range of 0.001 to 10 mass %, preferably 0.01 to 5 mass %, based on the total solids of the actinic-ray- or radiation-sensitive resin composition.

With respect to the ratio between acid generator and basic compound (comprising basic compound (N) and basic compound (N′)) used in the composition, the molar ratio of acid generator/basic compound is preferably in the range of 2.5 to 300. Namely, a molar ratio of 2.5 or higher is preferred from the viewpoint of the enhancement of sensitivity and resolution. A molar ratio of 300 or below is preferred from the viewpoint of the inhibition of any resolution deterioration due to resist pattern thickening over time until baking treatment after exposure. The molar ratio of acid generator/basic compound is more preferably in the range of 5.0 to 200, further more preferably 7.0 to 150.

[6] Surfactant

It is optional for the actinic-ray- or radiation-sensitive resin composition of the present invention to further contain a surfactant. When a surfactant is contained, it is preferred to contain any one, or two or more, of fluorinated and/or siliconized surfactants (fluorinated surfactant, siliconized surfactant and surfactant containing both fluorine and silicon atoms).

The actinic-ray- or radiation-sensitive resin composition of the present invention when containing the surfactant can, in the use of an exposure light source of 250 nm or below, especially 220 nm or below, produce a resist pattern of less adhesion and development defects with favorable sensitivity and resolution.

As the fluorinated and/or siliconized surfactants, there can be mentioned those described in section [0276] of US Patent Application Publication No. 2008/0248425. For example, there can be mentioned Eftop EF301 and EF303 (produced by Shin-Akita Kasei Co., Ltd.), Florad FC 430, 431 and 4430 (produced by Sumitomo 3M Ltd.), Megafac F171, F173, F176, F189, F113, F110, F177, F120 and R08 (produced by DIC Corporation), Surflon S-382, SC101, 102, 103, 104, 105, 106 and KH-20 (produced by Asahi Glass Co., Ltd.), Troy Sol S-366 (produced by Troy Chemical Co., Ltd.), GF-300 and GF-150 (produced by TOAGOSEI CO., LTD.), Sarfron S-393 (produced by SEIMI CHEMICAL CO., LTD.), Eftop EF121, EF122A, EF122B, RF122C, EF125M, EF135M, EF351, EF352, EF801, EF802 and EF601 (produced by JEMCO INC.), PF636, PF656, PF6320 and PF6520 (produced by OMNOVA SOLUTIONS, INC.), and FTX-204G, 208G, 218G, 230G, 204D, 208D, 212D, 218D and 222D (produced by NEOS). Further, polysiloxane polymer KP-341 (produced by Shin-Etsu Chemical Co., Ltd.) can be employed as a siliconized surfactant.

As the surfactant, besides the above publicly known surfactants, use can be made of a surfactant based on a polymer containing a fluoroaliphatic group derived from a fluoroaliphatic compound produced by a telomerization technique (also known as a telomer process) or an oligomerization technique (also known as an oligomer process). The fluoroaliphatic compound can be synthesized by the process described in JP-A-2002-90991.

As the relevant surfactants, there can be mentioned Megafac F178, F-470, F-473, F-475, F-476 or F-472 (produced by DIC Corporation), a copolymer from an acrylate (or methacrylate) containing a C₆F₁₃ group and a poly(oxyalkylene)acrylate (or methacrylate), a copolymer from an acrylate (or methacrylate) containing a C₃F₇ group, poly(oxyethylene)acrylate (or methacrylate) and poly(oxypropylene)acrylate (or methacrylate), and the like.

Moreover, in the present invention, use can be made of surfactants other than the fluorinated and/or siliconized surfactants, described in section [0280] of US Patent Application Publication No. 2008/0248425.

These surfactants may be used either individually or in combination.

When the actinic-ray- or radiation-sensitive resin composition contains a surfactant, the amount of surfactant used is preferably in the range of 0.0001 to 2 mass %, more preferably 0.0005 to 1 mass %, based on the total mass of the actinic-ray- or radiation-sensitive resin composition (excluding the solvent).

When the amount of surfactant added is controlled at 10 ppm or less based on the total mass of the actinic-ray- or radiation-sensitive resin composition (excluding the solvent), the localization of the resin (HR) according to the present invention in the surface layer is promoted to thereby cause the surface of the resist film to be highly hydrophobic, so that the water tracking property in the stage of liquid-immersion exposure can be enhanced.

[7] Other Additive

It is optional for the actinic-ray- or radiation-sensitive resin composition of the present invention to contain a carboxylic acid onium salt. As the carboxylic acid onium salt, there can be mentioned any of those described in sections [0605] to [0606] of US Patent Application Publication No. 2008/0187860.

These carboxylic acid onium salts can be synthesized by reacting a sulfonium hydroxide, an iodonium hydroxide or an ammonium hydroxide and a carboxylic acid with silver oxide in an appropriate solvent.

When the actinic-ray- or radiation-sensitive resin composition contains a carboxylic acid onium salt, the content thereof is generally in the range of 0.1 to 20 mass %, preferably 0.5 to 10 mass % and further more preferably 1 to 7 mass %, based on the total solids of the composition.

According to necessity, the actinic-ray- or radiation-sensitive resin composition of the present invention may further contain a dye, a plasticizer, a photosensitizer, a light absorber, an alkali-soluble resin, a dissolution inhibitor, a compound capable of accelerating the dissolution in a developer (for example, a phenolic compound of 1000 or less molecular weight, or a carboxylated alicyclic or aliphatic compound), etc.

The above phenolic compound of 1000 or less molecular weight can be easily synthesized by persons of ordinary skill in the art to which the present invention pertains while consulting the processes described in, for example, JP-A's H4-122938 and H2-28531, U.S. Pat. No. 4,916,210 and EP 219294.

As the carboxylated alicyclic or aliphatic compound, there can be mentioned, for example, a carboxylic acid derivative with a steroid structure such as cholic acid, deoxycholic acid or lithocholic acid, an adamantanecarboxylic acid derivative, adamantanedicarboxylic acid, cyclohexanecarboxylic acid, cyclohexanedicarboxylic acid or the like. These are however nonlimiting.

From the viewpoint of enhancing the resolving power, the actinic-ray- or radiation-sensitive resin composition of the present invention is preferably used in the form of a film whose thickness is in the range of 30 to 250 nm. More preferably, the film thickness is in the range of 30 to 200 nm. This film thickness can be attained by regulating the solid content of the composition within an appropriate range so as to cause the composition to have an appropriate viscosity, thereby improving the applicability and film forming property of the composition.

The solid concentration of the actinic-ray- or radiation-sensitive resin composition of the present invention is generally in the range of 1.0 to 10 mass %, preferably 2.0 to 5.7 mass % and more preferably 2.0 to 5.3 mass %. The resist solution can be uniformly applied onto substrates by regulating the solid concentration so as to fall within this range. Further, a resist pattern excelling in line width roughness can be formed by the regulation. Although the reason therefor is not necessarily apparent, it is presumed that very possibly, the aggregation of materials, especially photoacid generators, in the resist solution can be inhibited by regulating the solid concentration so as to be 10 mass % or below, preferably 5.7 mass % or below, so that a uniform resist film can be formed.

The solid concentration refers to the percentage of the weight of non-solvent resist components based on the total weight of the actinic-ray- or radiation-sensitive resin composition.

The actinic-ray- or radiation-sensitive resin composition of the present invention is used in such a manner that the above-mentioned components are dissolved in a given organic solvent, preferably the above-mentioned mixed solvent, and filtered and applied onto a given support (substrate). The filter medium for use in the filtration is preferably one made of a polytetrafluoroethylene, polyethylene or nylon that has a pore size of 0.1 μm or less, preferably 0.05 μm or less and more preferably 0.03 μm or less. In the filtration, as described in, for example, JP-A-2002-62667, a cyclic filtration may be carried out, or two or more types of filters may be connected in series or parallel. Moreover, the composition may be filtered two or more times. Further, the composition may be deaerated prior to and/or after the filtration.

<Method of Forming Pattern>

Now, the method of forming a pattern according to the present invention will be described.

The method of forming a pattern according to the present invention (namely, a negative pattern forming method) comprises at least the operations of:

(a) forming a film (namely, a resist film) comprising the actinic-ray- or radiation-sensitive resin composition of the present invention,

(b) exposing the film to actinic rays or radiation (namely, exposing operation), and

(c) developing the exposed film with a developer comprising an organic solvent.

In the operation (b) above, the exposure may be a liquid-immersion exposure.

In the pattern forming method of the present invention, the exposing operation (b) is preferably followed by a baking operation (d).

The pattern forming method of the present invention may further comprise an operation of development using an alkali developer (e).

In the pattern forming method of the present invention, the exposing operation (b) may be conducted two or more times.

In the pattern forming method of the present invention, the baking operation (d) may be conducted two or more times.

The resist film according to the present invention is one formed from the above actinic-ray- or radiation-sensitive resin composition of the present invention. In particular, the film is preferably one formed by coating a substrate with the actinic-ray- or radiation-sensitive resin composition. In the pattern forming method of the present invention, the operation of forming the film of the actinic-ray- or radiation-sensitive resin composition on a substrate, the operation of exposing the film to light, and the operation of developing the exposed film can be performed using generally known methods.

Preferably, the operation of prebake (PB) is performed after the film formation but prior to the exposing operation.

Also preferably, the operation of post-exposure bake (PEB) is performed after the exposing operation but prior to the developing operation.

In both the PB operation and the PEB operation, the baking is preferably performed at 70 to 130° C., more preferably 80 to 120° C.

The baking time is preferably in the range of 30 to 300 seconds, more preferably 30 to 180 seconds and further more preferably 30 to 90 seconds.

The baking can be performed by means provided in the common exposure/development equipment. The baking can also be performed using a hot plate or the like.

The baking accelerates the reaction in exposed areas, so that the sensitivity and pattern profile can be enhanced.

The wavelength of light source for use in the exposure apparatus in the present invention is not particularly limited. Use can be made of infrared rays, visible light, ultraviolet rays, far ultraviolet rays, extreme ultraviolet light, X-rays, electron beams, etc. Preferred use is made of far ultraviolet rays of wavelength preferably 250 nm or shorter, more preferably 220 nm or shorter and most preferably 1 to 200 nm, such as a KrF excimer laser (248 nm), an ArF excimer laser (193 nm) and an F₂ excimer laser (157 nm), X-rays, EUV (13 nm), electron beams, etc. A KrF excimer laser, an ArF excimer laser, EUV and electron beams are more preferred. An ArF excimer laser is most preferred.

A technique of liquid immersion exposure can be employed in the exposing operation according to the present invention.

The technique of liquid immersion exposure is a technology for realizing an enhancement of resolving power, which comprises exposing while filling the space between a projector lens and a sample with a liquid of high refractive index (hereinafter also referred to as “immersion liquid”).

The “effect of the liquid immersion” is as follows. Taking λ₀ as the wavelength of exposure light in air, n as the refractive index of the immersion liquid to air and 0 as the convergent half angle of the light beam, and providing that NA₀=sin θ, the resolving power and focus latitude (DOF) in the event of liquid immersion can be expressed by the following formulae. In the formulae, k₁ and k₂ are coefficients relating to process.

(Resolving power)=k₁·(λ₀/n)/NA₀

(DOF)=±k₂·(λ₀/n)/NA₀²

That is, the effect of the liquid immersion is equivalent to the use of an exposure wavelength of 1/n. In other words, in projection optic systems of identical NA, the liquid immersion enables the focal depth to be n-fold. This is effective in all pattern shapes. Further, this can be combined with a super-resolution technology, such as a phase shift method or a modified illumination method, now under study.

When the liquid immersion exposure is performed, the operation of washing the film surface with an aqueous chemical liquid may be carried out (1) after the film formation on the substrate but prior to the operation of exposure, and/or (2) after the operation of exposing the film to light via the immersion liquid but before the operation of baking the film.

The immersion liquid is preferably comprised of a liquid being transparent in exposure wavelength, whose temperature coefficient of refractive index is as low as possible so as to ensure minimization of any distortion of optical image projected on the film. Especially in the use of an ArF excimer laser (wavelength: 193 nm) as an exposure light source, it is preferred to use water from not only the above viewpoint but also the viewpoint of easy procurement and easy handling.

In the use of water as the immersion liquid, an additive (liquid) capable of not only decreasing the surface tension of water but also increasing an interface activating power may be added in a slight proportion. It is preferred for this additive to be one that does not dissolve the resist layer on the wafer and is negligible with respect to its influence on the optical coat applied to an under surface of lens element.

The additive is preferably, for example, an aliphatic alcohol exhibiting a refractive index approximately equal to that of water, such as methyl alcohol, ethyl alcohol, isopropyl alcohol or the like. The addition of an alcohol exhibiting a refractive index approximately equal to that of water is advantageous in that even when the alcohol component is evaporated from water to thereby cause a change of content concentration, any change of refractive index of the liquid as a whole can be minimized.

On the other hand, when a substance being opaque in 193 nm light or an impurity whose refractive index is greatly different from that of water is mingled in the immersion water, a distortion of optical image projected on the resist is invited. Accordingly, it is preferred to use distilled water as the immersion water. Furthermore, use may be made of pure water having been filtered through an ion exchange filter or the like.

Desirably, the electrical resistance of the water used as the immersion liquid is 18.3 MQcm or higher, and the TOC (organic matter concentration) thereof is 20 ppb or below. Prior deaeration of the water is desired.

The lithography performance can be enhanced by raising the refractive index of the immersion liquid. From this viewpoint, an additive suitable for refractive index increase may be added to the water, or heavy water (D₂O) may be used in place of the water.

The receding contact angle of the resist film formed from the actinic-ray- or radiation-sensitive resin composition of the present invention is 70° or greater at 23±3° C. in 45±5% humidity, which is appropriate in the exposure via the liquid immersion medium. The receding contact angle is preferably 75° or greater, more preferably 75 to 85°.

When the receding contact angle is extremely small, the resist film cannot be appropriate in the exposure via the liquid immersion medium, and the effect of suppressing any residual water (watermark) defect cannot be satisfactorily exerted.

When the above-mentioned hydrophobic resin (HR) contains substantially none of fluorine and silicon atoms, the receding contact angle of the surface of the resist film can be increased by incorporating the hydrophobic resin (HR) in the actinic-ray- or radiation-sensitive resin composition of the present invention.

From the viewpoint of increasing the receding contact angle, it is preferred for the hydrophobic resin (HR) to comprise at least either repeating unit of general formula (II) above or repeating unit of general formula (III) above. Further, from the viewpoint of increasing the receding contact angle, it is preferred for the ClogP value of the hydrophobic resin (HR) to be 1.5 or greater. Still further, from the viewpoint of increasing the receding contact angle, it is preferred for the mass content of CH₃ partial structure introduced in a side chain portion of the hydrophobic resin (HR) in the hydrophobic resin (HR) to be 12.0% or more.

In the operation of liquid immersion exposure, it is needed for the immersion liquid to move on the wafer while tracking the movement of an exposure head involving high-speed scanning on the wafer and thus forming an exposure pattern. Therefore, the contact angle of the immersion liquid with respect to the resist film in a dynamic condition is important, and it is required for the resist to be capable of tracking the high-speed scanning of the exposure head without leaving any droplets.

The substrate used for film formation in the present invention is not particularly limited. Use can be made of any of an inorganic substrate of silicon, SiN, SiO₂, TiN or the like, a coated inorganic substrate such as SOG and substrates commonly employed in a semiconductor production process for an IC or the like, a circuit board production process for a liquid crystal, a thermal head or the like and other photoapplication lithography processes. Further, according to necessity, an organic antireflection film may be provided between the resist film and the substrate.

When the pattern forming method of the present invention further comprises the operation of developing with an alkali developer, as the alkali developer, use can be made of, for example, any of alkaline aqueous solutions containing an inorganic alkali such as sodium hydroxide, potassium hydroxide, sodium carbonate, sodium silicate, sodium metasilicate or aqueous ammonia, a primary amine such as ethylamine or n-propylamine, a secondary amine such as diethylamine or di-n-butylamine, a tertiary amine such as triethylamine or methyldiethylamine, an alcoholamine such as dimethylethanolamine or triethanolamine, a quaternary ammonium salt such as tetramethylammonium hydroxide or tetraethylammonium hydroxide, a cycloamine such as pyrrole or piperidine, and the like.

Appropriate amounts of an alcohol and a surfactant may be added to the above alkaline aqueous solutions before the use thereof.

The alkali concentration of the alkali developer is generally in the range of 0.1 to 20 mass %.

The pH value of the alkali developer is generally in the range of 10.0 to 15.0. A 2.38 mass % aqueous tetramethylammonium hydroxide solution is particularly preferred.

Pure water is used as the rinse liquid for use in the rinse treatment performed after the alkali development. Before the use thereof, an appropriate amount of surfactant may be added thereto.

Further, the development operation or rinse operation may be followed by the operation of removing any portion of developer or rinse liquid adhering onto the pattern by use of a supercritical fluid.

As the developer (hereinafter also referred to as an organic developer) for use in the operation of developing with a developer comprising an organic solvent to be performed in the pattern forming method of the present invention, use can be made of a polar solvent, such as a ketone solvent, an ester solvent, an alcohol solvent, an amide solvent or an ether solvent, and a hydrocarbon solvent.

As the ketone solvent, there can be mentioned, for example, 1-octanone, 2-octanone, 1-nonanone, 2-nonanone, acetone, 2-heptanone(methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, propylene carbonate or the like.

As the ester solvent, there can be mentioned, for example, methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl 3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate or the like.

As the alcohol solvent, there can be mentioned, for example, an alcohol, such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol or n-decanol; a glycol solvent, such as ethylene glycol, diethylene glycol or triethylene glycol; a glycol ether solvent, such as ethylene glycol monomethyl ether, propylene glycol monomethyl ether, ethylene glycol monoethyl ether, propylene glycol monoethyl ether, diethylene glycol monomethyl ether, triethylene glycol monoethyl ether or methoxymethylbutanol; or the like.

As the ether solvent, there can be mentioned, for example, not only any of the above-mentioned glycol ether solvents but also dioxane, tetrahydrofuran or the like.

As the amide solvent, there can be mentioned, for example, N-methyl-2-pyrrolidone, N,N-dimethylacetamide, N,N-dimethylformamide, hexamethylphosphoric triamide, 1,3-dimethyl-2-imidazolidinone or the like.

As the hydrocarbon solvent, there can be mentioned, for example, an aromatic hydrocarbon solvent, such as toluene or xylene, or an aliphatic hydrocarbon solvent, such as pentane, hexane, octane or decane.

Two or more of these solvents may be mixed together before use. Alternatively, each of the solvents may be used in a mixture with a solvent other than those mentioned above or water. However, from the viewpoint of the fullest exertion of the effects of the present invention, it is preferred for the water content of the whole developer to be less than 10 mass %. More preferably, the developer contains substantially no water.

Namely, the amount of organic solvent used in the organic developer is preferably in the range of 90 to 100 mass %, more preferably 95 to 100 mass %, based on the whole amount of the developer.

It is especially preferred for the organic developer to be a developer comprising at least one organic solvent selected from the group consisting of a ketone solvent, an ester solvent, an alcohol solvent, an amide solvent and an ether solvent.

The vapor pressure of the organic developer at 20° C. is preferably 5 kPa or below, more preferably 3 kPa or below and most preferably 2 kPa or below. When the vapor pressure of the organic developer is 5 kPa or below, the evaporation of the developer on a substrate or in a development cup can be suppressed, so that the temperature uniformity within the plane of the wafer can be enhanced to thereby improve the dimensional uniformity within the plane of the wafer.

As particular examples of the organic developers exhibiting a vapor pressure of 5 kPa or below, there can be mentioned a ketone solvent, such as 1-octanone, 2-octanone, 1-nonanone, 2-nonanone, 2-heptanone(methyl amyl ketone), 4-heptanone, 2-hexanone, diisobutyl ketone, cyclohexanone, methylcyclohexanone, phenylacetone or methyl isobutyl ketone; an ester solvent, such as butyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl 3-ethoxypropionate, 3-methoxybutyl acetate, 3-methyl-3-methoxybutyl acetate, butyl formate, propyl formate, ethyl lactate, butyl lactate or propyl lactate; an alcohol solvent, such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol or n-decanol; a glycol solvent, such as ethylene glycol, diethylene glycol or triethylene glycol; a glycol ether solvent, such as ethylene glycol monomethyl ether, propylene glycol monomethyl ether, ethylene glycol monoethyl ether, propylene glycol monoethyl ether, diethylene glycol monomethyl ether, triethylene glycol monoethyl ether or methoxymethylbutanol; an ether solvent, such as tetrahydrofuran; an amide solvent, such as N-methyl-2-pyrrolidone, N,N-dimethylacetamide or N,N-dimethylformamide; an aromatic hydrocarbon solvent, such as toluene or xylene, and an aliphatic hydrocarbon solvent, such as octane or decane.

As particular examples of the organic developers exhibiting a vapor pressure of 2 kPa or below as an especially preferred range, there can be mentioned a ketone solvent, such as 1-octanone, 2-octanone, 1-nonanone, 2-nonanone, 4-heptanone, 2-hexanone, diisobutyl ketone, cyclohexanone, methylcyclohexanone or phenylacetone; an ester solvent, such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl 3-ethoxypropionate, 3-methoxybutyl acetate, 3-methyl-3-methoxybutyl acetate, ethyl lactate, butyl lactate or propyl lactate; an alcohol solvent, such as n-butyl alcohol, sec-butyl alcohol, tert-butyl alcohol, isobutyl alcohol, n-hexyl alcohol, n-heptyl alcohol, n-octyl alcohol or n-decanol; a glycol solvent, such as ethylene glycol, diethylene glycol or triethylene glycol; a glycol ether solvent, such as ethylene glycol monomethyl ether, propylene glycol monomethyl ether, ethylene glycol monoethyl ether, propylene glycol monoethyl ether, diethylene glycol monomethyl ether, triethylene glycol monoethyl ether or methoxymethylbutanol; an amide solvent, such as N-methyl-2-pyrrolidone, N,N-dimethylacetamide or N,N-dimethylformamide; an aromatic hydrocarbon solvent, such as xylene; and an aliphatic hydrocarbon solvent, such as octane or decane.

According to necessity, an appropriate amount of surfactant can be added to the organic developer.

The surfactant is not particularly limited. For example, use can be made of any of ionic and nonionic fluorinated and/or siliconized surfactants and the like. As such fluorinated and/or siliconized surfactants, there can be mentioned, for example, those described in JP-A's S62-36663, S61-226746, S61-226745, S62-170950, S63-34540, H7-230165, H8-62834, H9-54432 and H9-5988 and U.S. Pat. Nos. 5,405,720, 5,360,692, 5,529,881, 5,296,330, 5,436,098, 5,576,143, 5,294,511 and 5,824,451. Nonionic surfactants are preferred. Although nonionic surfactants are not particularly limited, using a fluorinated surfactant or siliconized surfactant is more preferred.

The amount of surfactant added is generally in the range of 0.001 to 5 mass %, preferably 0.005 to 2 mass % and more preferably 0.01 to 0.5 mass % based on the whole amount of the developer.

As the development method, use can be made of, for example, a method in which the substrate is dipped in a tank filled with a developer for a given period of time (dip method), a method in which a developer is puddled on the surface of the substrate by its surface tension and allowed to stand still for a given period of time to thereby effect development (puddle method), a method in which a developer is sprayed onto the surface of the substrate (spray method), or a method in which a developer is continuously discharged onto the substrate being rotated at a given speed while scanning a developer discharge nozzle at a given speed (dynamic dispense method).

With respect to the above various development methods, when the operation of discharging a developer toward a resist film through a development nozzle of a development apparatus is included, the discharge pressure of discharged developer (flow rate per area of discharged developer) is preferably 2 ml/sec/mm² or below, more preferably 1.5 ml/sec/mm² or below and further more preferably 1 ml/sec/mm² or below. There is no particular lower limit of the flow rate. However, from the viewpoint of through-put, it is preferred for the flow rate to be 0.2 ml/sec/mm² or higher.

Pattern defects attributed to any resist residue after development can be markedly reduced by regulating the discharge pressure of discharged developer so as to fall within the above range.

The detail of the mechanism thereof has not been elucidated. However, it is presumed that regulating the discharge pressure so as to fall within the above range decreases the pressure of the developer on the resist film, thereby inhibiting any inadvertent shaving or crumbling of the resist film/resist pattern.

The discharge pressure of developer (ml/sec/mm²) refers to a value exhibited at the outlet of the development nozzle of the development apparatus.

For the regulation of the discharge pressure of developer, there can be employed, for example, a method in which the discharge pressure is regulated by means of a pump or the like, or a method in which the discharge pressure is changed through pressure regulation by supply from a pressure tank.

The operation of developing with a developer comprising an organic solvent may be followed by the operation of discontinuing the development by replacement with another solvent.

The operation of developing with a developer comprising an organic solvent is preferably followed by the operation of rinsing the developed film with a rinse liquid.

The rinse liquid for use in the rinse operation after the operation of development with a developer comprising an organic solvent is not particularly limited as long as it does not dissolve the resist pattern, and solutions comprising common organic solvents can be used as the same. It is preferred for the rinse liquid to be one comprising at least one organic solvent selected from the group consisting of a hydrocarbon solvent, a ketone solvent, an ester solvent, an alcohol solvent, an amide solvent and an ether solvent.

Particular examples of the hydrocarbon solvent, ketone solvent, ester solvent, alcohol solvent, amide solvent and ether solvent are the same as set forth above in connection with the developer comprising an organic solvent.

The operation of developing with the developer comprising an organic solvent is preferably followed by the operation of rinsing with a rinse liquid comprising at least one organic solvent selected from the group consisting of a ketone solvent, an ester solvent, an alcohol solvent and an amide solvent; more preferably followed by the operation of rinsing with a rinse liquid comprising an alcohol solvent or an ester solvent; further more preferably followed by the operation of rinsing with a rinse liquid comprising a monohydric alcohol; and most preferably followed by the operation of rinsing with a rinse liquid comprising a monohydric alcohol having 5 or more carbon atoms.

As the monohydric alcohol for use in the rinse operation, there can be mentioned a linear, branched or cyclic monohydric alcohol. In particular, use can be made of 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol or the like. As the most preferred monohydric alcohol having 5 or more carbon atoms, use can be made of 1-hexanol, 2-hexanol, 4-methyl-2-pentanol, 1-pentanol, 3-methyl-1-butanol or the like.

Two or more of these components may be mixed together before use. Also, they may be mixed with other organic solvents before use.

The water content of the rinse liquid is preferably 10 mass % or below, more preferably 5 mass % or below and most preferably 3 mass % or below. Favorable development performance can be attained by controlling the water content of the rinse liquid at 10 mass % or below.

With respect to the rinse liquid for use after the operation of developing with a developer comprising an organic solvent, the vapor pressure thereof at 20° C. is preferably in the range of 0.05 to 5 kPa, more preferably 0.1 to 5 kPa and most preferably 0.12 to 3 kPa. When the vapor pressure of the rinse liquid is in the range of 0.05 to 5 kPa, not only can the temperature uniformity within the plane of the wafer be enhanced but also the swell attributed to the penetration of the rinse liquid can be suppressed to thereby improve the dimensional uniformity within the plane of the wafer.

An appropriate amount of surfactant may be added to the rinse liquid before use.

In the rinse operation, the wafer having undergone the development with a developer comprising an organic solvent is rinsed with the above rinse liquid comprising an organic solvent. The method of rinse treatment is not particularly limited. For example, use can be made of any of a method in which the rinse liquid is continuously applied onto the substrate being rotated at a given speed (spin application method), a method in which the substrate is dipped in a tank filled with the rinse liquid for a given period of time (dip method) and a method in which the rinse liquid is sprayed onto the surface of the substrate (spray method). Preferably, the rinse treatment is carried out according to the spin application method, and thereafter the substrate is rotated at a rotating speed of 2000 to 4000 rpm to thereby remove the rinse liquid from the top of the substrate. Also, preferably, a baking operation (post-bake) is carried out subsequent to the rinse operation. Any inter-pattern and intra-pattern remaining developer and rinse liquid are removed by carrying out the bake. The bake operation subsequent to the rinse operation is generally performed at 40 to 160° C., preferably 70 to 95° C., for a period of 10 seconds to 3 minutes, preferably 30 to 90 seconds.

Furthermore, the present invention relates to a process for manufacturing an electronic device in which the above-described negative pattern forming method of the present invention is included, and relates to an electronic device manufactured by the process.

The electronic device of the present invention can be appropriately mounted in electrical and electronic equipments (household electronic appliance, OA/media-related equipment, optical apparatus, telecommunication equipment and the like).

### EXAMPLES

The present invention will be described in greater detail below by way of its examples. However, the gist of the present invention is in no way limited to these examples.

### Acid-Decomposable Resin (P)

### Synthetic Example 1

### Synthesis of Resin a-1

In a nitrogen gas stream, 86.9 g of cyclohexanone was placed in a three-necked flask and heated at 80° C. A solution obtained by dissolving the compounds (monomers) indicated in Table 2 below (amounting in order from the left side to 18.89 g, 3.72 g, 18.89 g and 3.36 g) and further polymerization initiator V601 (produced by Wako Pure Chemical Industries, Ltd., 2.855 g) in 161.4 g of cyclohexanone was dropped thereinto over a period of 6 hours. After the completion of the dropping, reaction was continued at 80° C. for 2 hours. The thus obtained reaction liquid was allowed to stand still to cool, and was dropped into a mixed liquid comprised of 1600 g of n-heptane and 400 g of ethyl acetate over a period of 20 minutes. The thus precipitated powder was collected by filtration and dried, thereby obtaining 35.0 g of resin A-1. The polymer component ratio thereof determined by NMR was 40/10/40/10. With respect to the obtained resin A-1, the standard-polystyrene-equivalent weight average molecular weight (Mw) determined by GPC analysis was 8000, and the polydispersity index (Mw/Mn) was 1.4. Resins A-2 to A-15 were synthesized in the same manner as in Synthetic Example 1. Table 2 below lists the structures of synthesized polymers together with the component ratios, weight average molecular weights (Mw) and polydispersity indices (Mw/Mn) thereof. In Table 2, the positional relationship of individual repeating units of each of the resins corresponds to the positional relationship of component ratio numeric values.

TABLE 2

| Resin | Structural formula | |
|---|---|---|
| (P) | (Comp. ratio/mol %) | |
| A-1 | 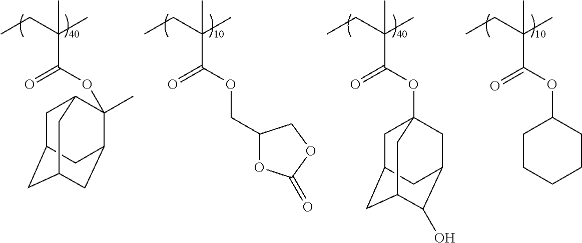 | Mw: 8000 Mw/Mn: 1.4 |
| A-2 | 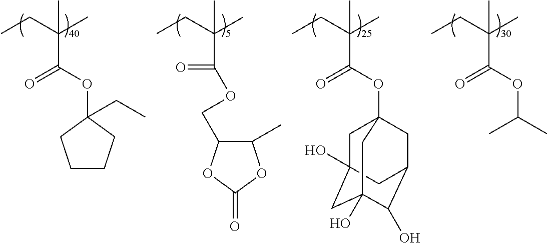 | Mw: 9000 Mw/Mn: 1.6 |
| A-3 | 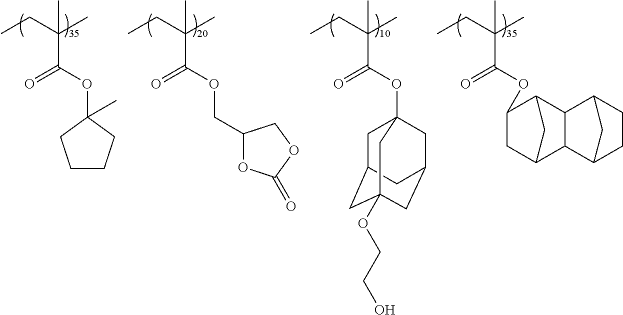 | Mw: 11000 Mw/Mn: 1.3 |
| A-4 | 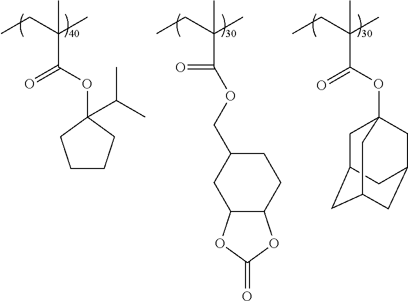 | Mw: 17000 Mw/Mn: 1.5 |
| A-5 | 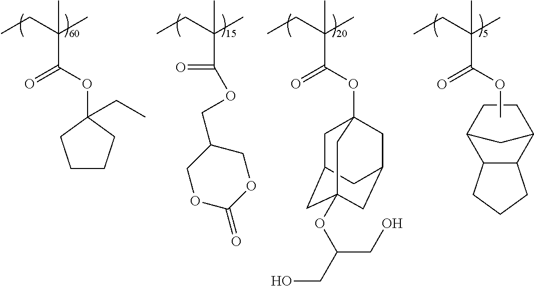 | Mw: 13000 Mw/Mn: 1.6 |
| A-6 | 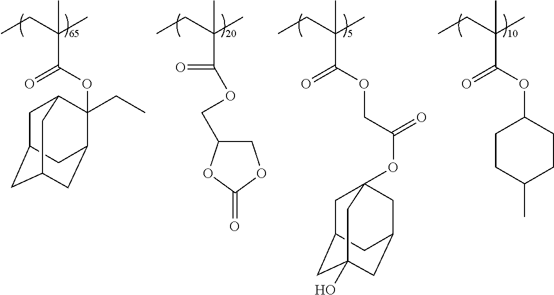 | Mw: 18000 Mw/Mn: 1.8 |
| A-7 | 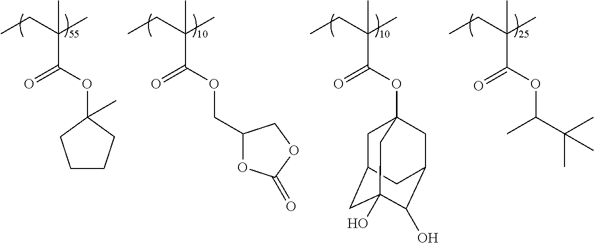 | Mw: 15000 Mw/Mn: 1.9 |
| A-8 | 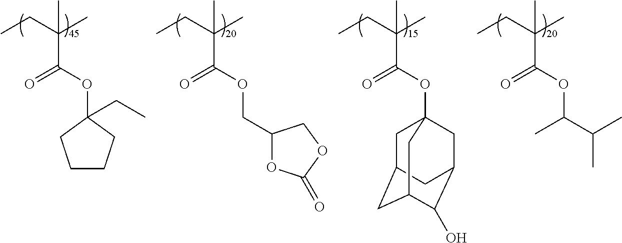 | Mw: 8000 Mw/Mn: 1.4 |
| A-9 | 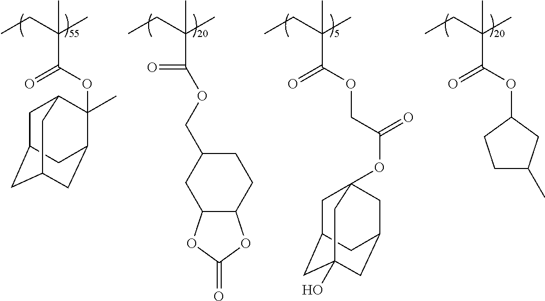 | Mw: 17000 Mw/Mn: 1.5 |
| A-10 | 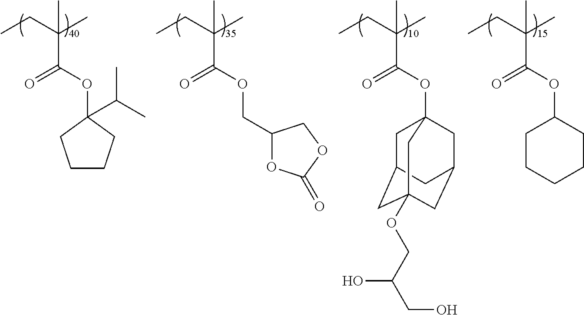 | Mw: 10000 Mw/Mn: 1.4 |
| A-11 | 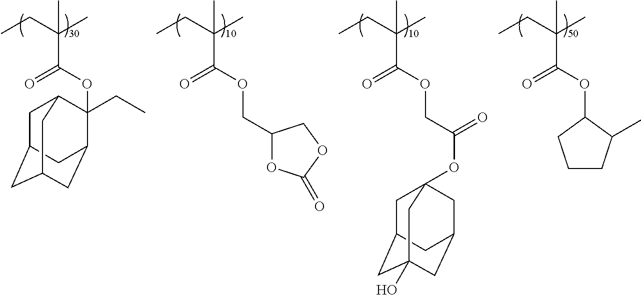 | Mw: 20000 Mw/Mn: 1.8 |
| A-12 | 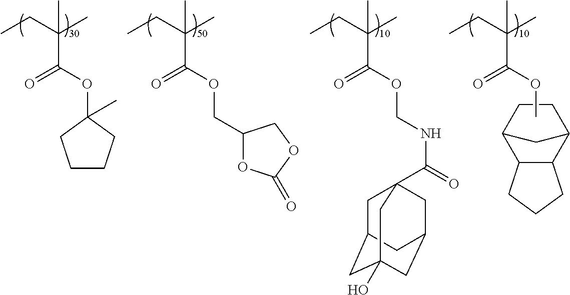 | Mw: 25000 Mw/Mn: 1.9 |
| A-13 | 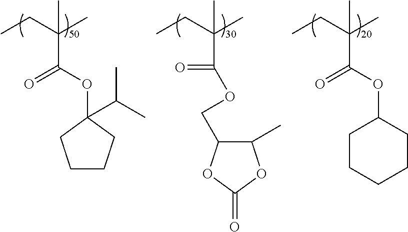 | Mw: 15000 Mw/Mn: 1.6 |
| A-14 | 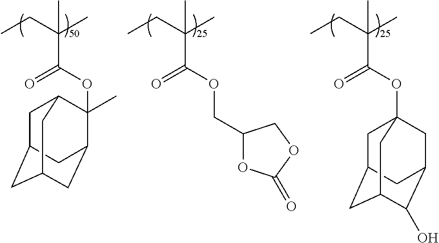 | Mw: 17000 Mw/Mn: 1.7 |
| A-15 | 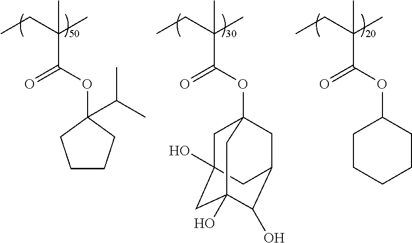 | Mw: 21000 Mw/Mn: 1.8 |

<Hydrophobic Resin (HR)>

Hydrophobic resins F-1 to F-5 were synthesized in the same manner as in the synthesis of resins (P). Table 3 below lists the structures of synthesized polymers together with the component ratios, weight average molecular weights (Mw) and polydispersity indices (Mw/Mn) thereof. In Table 3, the positional relationship of individual repeating units of each of the resins corresponds to the positional relationship of component ratio numeric values.

TABLE 3

| | Structural formula | |
|---|---|---|
| Resin | (Comp. ratio/mol %) | |
| F-1 | 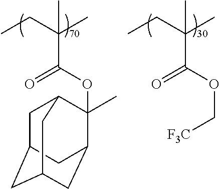 | Mw: 6000 Mw/Mn: 1.4 |
| F-2 | 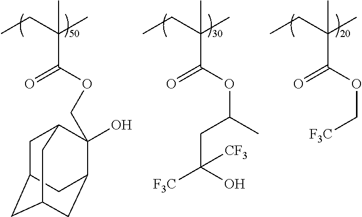 | Mw: 5000 Mw/Mn: 1.6 |
| F-3 | 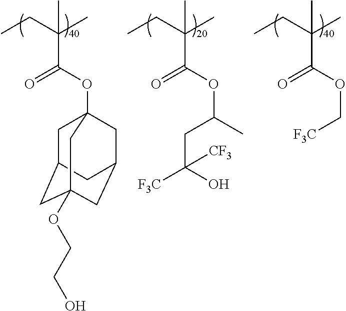 | Mw: 10000 Mw/Mn: 1.5 |
| F-4 | 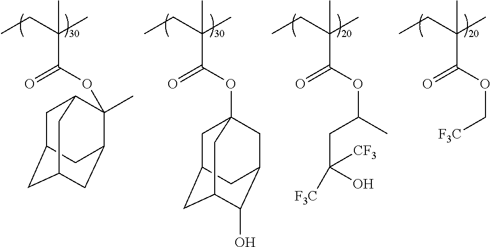 | Mw: 8000 Mw/Mn: 1.3 |
| F-5 | 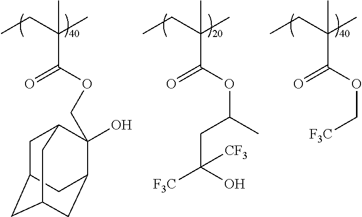 | Mw: 9000 Mw/Mn: 1.4 |

### Acid Generator

### Synthetic Example 2

### Synthesis of Acid Generator

Acid generators B-1 to B-15 and PAG-1 and PAG-2 with the below shown structures were synthesized in accordance with the method as described in, for example, WO 2011/093139 A1.

PAG-1 and PAG-2 with the below shown structures were synthesized as acid generators different from those of general formula (B-1) above.

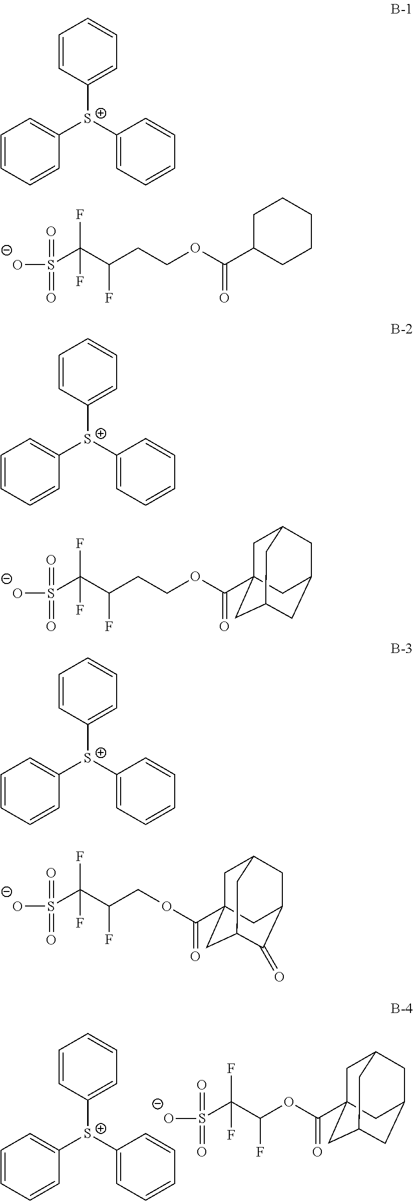

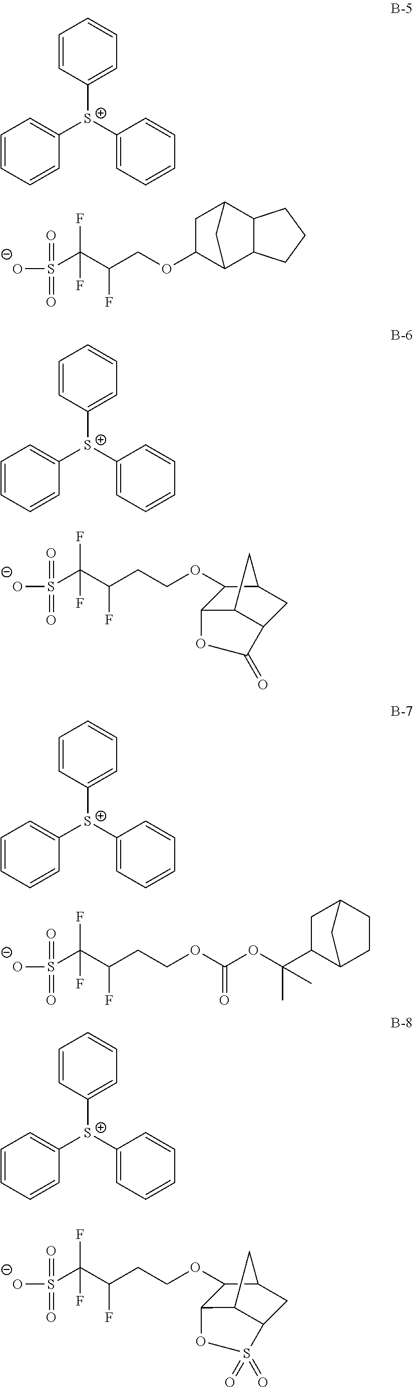

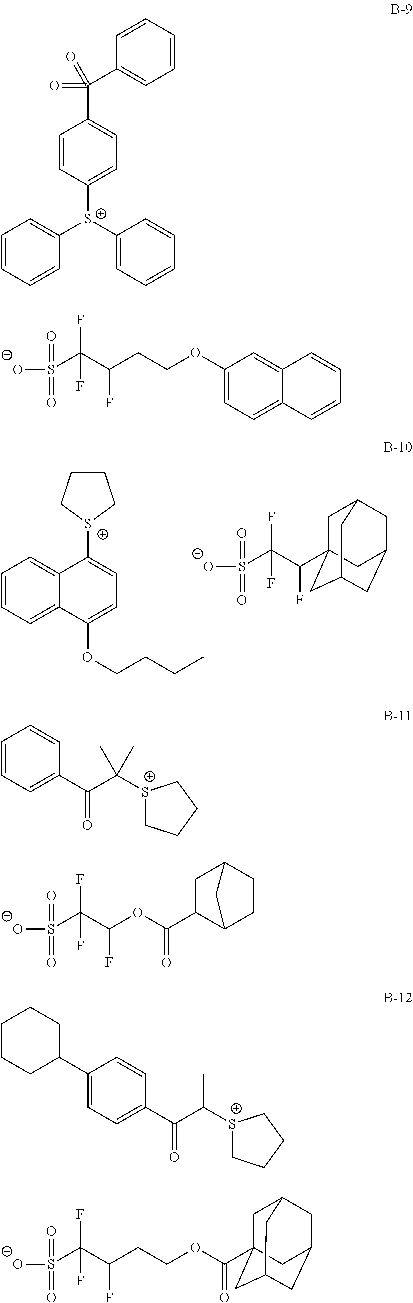

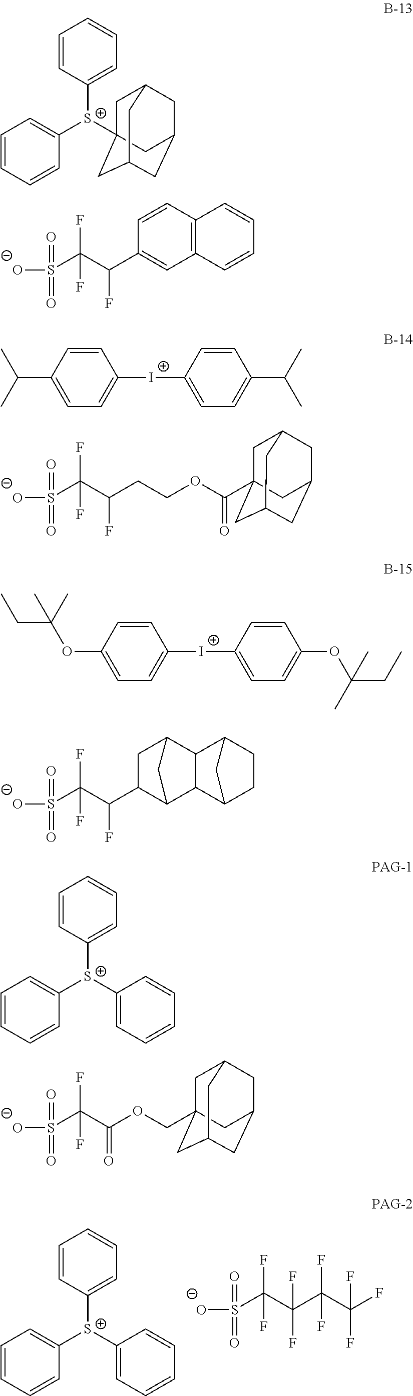

<Basic Compound>

The following compounds were used as basic compounds.

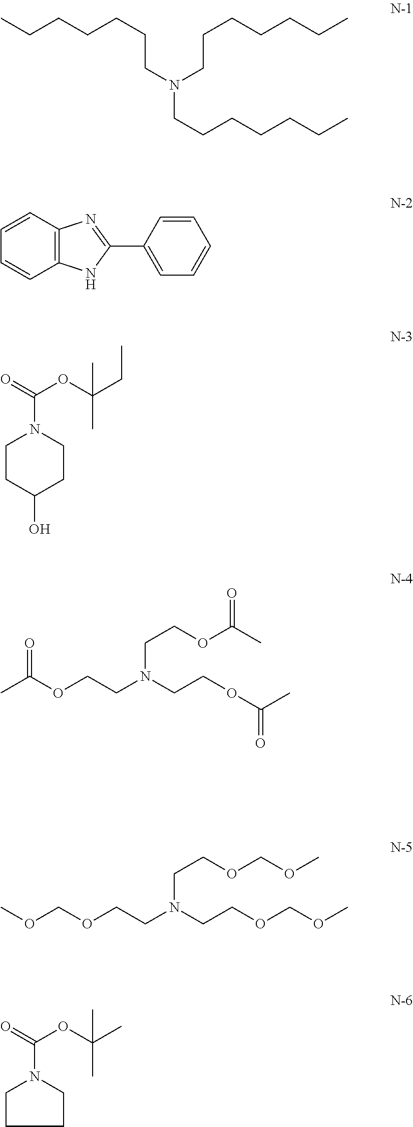

<Surfactant>

The following surfactants were used.

W-1: Megafac F176 (produced by DIC Corporation, fluorinated),

W-2: Megafac R08 (produced by DIC Corporation, fluorinated and siliconized),

W-3: polysiloxane polymer KP-341 (produced by Shin-Etsu Chemical Co., Ltd., siliconized),

W-4: Troy Sol S-366 (produced by Troy Chemical Co., Ltd.),

W-5: KH-20 (produced by Asahi Kasei Corporation), and

W-6: PolyFox PF-6320 (produced by OMNOVA SOLUTIONS, INC.).

<Solvent>

The following solvents were provided.

SL-1: propylene glycol monomethyl ether acetate (PGMEA),

SL-2: propylene glycol monomethyl ether propionate,

SL-3: 2-heptanone,

SL-4: ethyl lactate,

SL-5: propylene glycol monomethyl ether (PGME),

SL-6: cyclohexanone,

SL-7: γ-butyrolactone, and

SL-8: propylene carbonate.

<Developer>

Butyl acetate was used as the developer.

<Rinse Liquid>

The following rinse liquid was used.

SR-1: 4-methyl-2-pentanol.

[Evaluation Method]

<ArF Liquid-Immersion Exposure 1>

(Preparation of Resist and Formation of Pattern)

Dissolution of individual components in solvents as indicated in Table 4 below was carried out, thereby obtaining solutions each of 3.8 mass % solid content. The solutions were each passed through a polyethylene filter of 0.03 μm pore size, thereby obtaining actinic-ray- or radiation-sensitive resin compositions (resist compositions). An organic antireflection film ARC29SR (produced by Nissan Chemical Industries, Ltd.) was applied onto a silicon wafer and baked at 205° C. for 60 seconds, thereby forming a 95 nm-thick antireflection film. Each of the above resist compositions was applied thereonto and baked (prebaked: PB) at 100° C. for 60 seconds, thereby forming a 100 nm-thick resist film.

The resultant wafer was patternwise exposed through a 1:1 line and space half-tone mask of 86 nm pitch to light by means of an ArF excimer laser liquid immersion scanner (manufactured by ASML, XT1700i, NA1.20, C-Quad, outer sigma 0.900, inner sigma 0.812, XY deflection). Ultrapure water was used as the immersion liquid. Thereafter, the exposed wafer was baked (post-exposure baked: PEB) at 100° C. for 60 seconds. The wafer after PEB was developed by puddling with butyl acetate for 30 seconds. When a rinse liquid was used, the rinse was performed by puddling with a rinse liquid (4-methyl-2-pentanol) for 30 seconds. Thereafter, the wafer was rotated at a rotating speed of 4000 rpm for 30 seconds, thereby obtaining a 43 nm line width 1:1 line and space pattern.

(Line Width Roughness (LWR, m))

Each of the 43 nm (1:1) line-and-space resist patterns resolved with the optimum exposure amount in the evaluation of exposure latitude was observed from above the pattern by means of a critical dimension scanning electron microscope (SEM model S-9380II, manufactured by Hitachi, Ltd.). The line widths of the pattern was measured at arbitrary points, and the standard deviation thereof was determined, from which 3σ was computed. The smaller the value thereof, the more favorable the performance exhibited.

(Pattern Collapse (Collapse, m))

The optimum exposure amount was defined as the exposure amount capable of reproduction of a 43 nm line-and-space mask pattern. The exposure amount was decreased from the optimum exposure amount to make the line width of the formed line pattern smaller. The pattern collapse (collapse, m) was defined as the line width (nm) allowing pattern resolution without collapse. The larger the value thereof, the finer the pattern resolved without collapse, namely, the less the occurrence of pattern collapse.

<ArF Liquid-Immersion Exposure 2>

(Preparation of Resist)

Dissolution of individual components in solvents as indicated in Table 4 below was carried out, thereby obtaining solutions each of 3.8 mass % solid content. The solutions were each passed through a polyethylene filter of 0.03 μm pore size, thereby obtaining actinic-ray- or radiation-sensitive resin compositions (resist compositions). An organic antireflection film ARC29SR (produced by Nissan Chemical Industries, Ltd.) was applied onto a silicon wafer and baked at 205° C. for 60 seconds, thereby forming a 95 nm-thick antireflection film. Each of the above resist compositions was applied thereonto and baked (prebaked: PB) at 100° C. for 60 seconds, thereby forming a 100 nm-thick resist film.

The resultant wafer was patternwise exposed through a half-tone mask of square array of 60 nm hole size and 90 nm inter-hole pitch (herein, due to a negative image formation, light transmission through portions corresponding to holes blocked) to light by means of an ArF excimer laser liquid immersion scanner (manufactured by ASML, XT1700i, NA1.20, C-Quad, outer sigma 0.900, inner sigma 0.812, XY deflection). Ultrapure water was used as the immersion liquid. Thereafter, the exposed wafer was baked (post-exposure baked: PEB) at 105° C. for 60 seconds. The wafer after PEB was developed by puddling with butyl acetate for 30 seconds. When a rinse liquid was used, the rinse was performed by puddling with a rinse liquid (4-methyl-2-pentanol) for 30 seconds. Thereafter, the wafer was rotated at a rotating speed of 4000 rpm for 30 seconds, thereby obtaining a contact hole pattern of 45 nm hole diameter.

(Local Pattern Dimension Uniformity (CDU, m))

Within one shot of exposure with the optimum exposure amount determined in the evaluation of exposure latitude, the sizes of arbitrary 25 holes in each of twenty 1 μm interspaced localities (namely, a total of 500 holes) were measured. The standard deviation of measurements was determined, and 30 was computed therefrom. The smaller the value thereof, the smaller the dimension variation, namely, the more favorable the performance exhibited.

Evaluation results are listed in Table 4 below.

TABLE 4

| | Acid- | | Hydro- | | | | | |
|---|---|---|---|---|---|---|---|---|
| | decomposable | Parts by | phobic | Parts by | Acid | Parts by | Basic | Parts by |
| Ex. No. | resin (P) | mass | resin (HR) | mass | generator | mass | compd. | mass |
| Ex. 1 | A-1 | 79.7 | F-1 | 0.9 | B-1 | 8.0 | N-3/N-2 | 0.80/0.20 |
| Ex. 2 | A-2 | 74.8 | F-1 | 4.2 | B-2 | 10.0 | N-2/N-3 | 0.50/0.10 |
| Ex. 3 | A-3 | 74.7 | F-3 | 1.7 | B-3/B-10 | 8.0/4.0 | N-1 | 0.70 |
| Ex. 4 | A-4/A-1 | 60.6/10.0 | F-2 | 2.5 | B-4/B-2 | 10.0/6.0 | N-4 | 0.50 |
| Ex. 5 | A-5 | 72.1 | F-4 | 2.5 | B-5 | 15.0 | N-3/N-5 | 0.30/0.20 |
| Ex. 6 | A-6 | 68.1 | F-3 | 4.5 | B-6/B-12 | 8.0/8.0 | N-1 | 0.40 |
| Ex. 7 | A-7 | 67.8 | F-4 | 3.2 | B-7/B-14 | 14.0/4.0 | N-6/N-3 | 0.50/0.10 |
| Ex. 8 | A-8 | 78 | F-5 | 2.4 | B-8 | 8.0 | N-1 | 0.70 |
| Ex. 9 | A-9 | 69.1 | F-2/F-2 | 0.3/2.7 | B-9/B-2 | 9.0/8.0 | N-4 | 0.50 |
| Ex. 10 | A-10/A-3 | 57.5/15.0 | F-4 | 5.1 | B-10 | 12.0 | N-3/N-5 | 0.30/0.20 |
| Ex. 11 | A-11 | 73.5 | F-2 | 1.2 | B-11/B-6 | 6.0/8.0 | N-1 | 0.40 |
| Ex. 12 | A-12 | 72 | F-3/F-1 | 2.1/0.4 | B-12/B-4 | 6.0/8.0 | N-3/N-6 | 0.40/0.20 |
| Ex. 13 | A-13/A-5 | 57.5/15.0 | F-5 | 3.1 | B-13 | 14.0 | N-6/N-5 | 0.30/0.20 |
| Ex. 14 | A-1 | 79.7 | F-1 | 0.9 | PAG-1 | 8.0 | N-3/N-2 | 0.80/0.20 |
| Ex. 15 | A-1 | 79.7 | F-1 | 0.9 | PAG-2 | 8.0 | N-3/N-2 | 0.80/0.20 |
| Comp. Ex. 1 | A-14 | 76.4 | F-5 | 2.5 | B-1 | 10.0 | N-2 | 0.70 |
| Comp. Ex. 2 | A-15 | 76.4 | F-1 | 2.5 | B-1 | 10.0 | N-2 | 0.70 |

| | | | Solvent | | | | | | | | | |
|---|---|---|---|---|---|---|---|---|---|---|---|---|
| | | Parts | | Parts | | Parts | | Parts | Rinse | | Pattern | |
| Ex. No. | Surfactant | by mass | Solvent 1 | by mass | Solvent 2 | by mass | Solvent 3 | by mass | liq. | LWR | collapse | CDU |
| Ex. 1 | W-2 | 0.5 | SL-1 | 1451 | SL-4 | 800 | SL-7 | 30 | SR-1 | 4.3 | 52 | 6 |
| Ex. 2 | W-6 | 0.5 | SL-1 | 2111 | SL-5 | 100 | SL-7 | 70 | None | 4.6 | 53 | 6.1 |
| Ex. 3 | W-6 | 1 | SL-1 | 981 | SL-5 | 1000 | SL-6 | 300 | SR-1 | 5 | 50 | 7.8 |
| Ex. 4 | W-4 | 0.5 | SL-1 | 1681 | SL-4 | 500 | SL-7 | 100 | None | 4.4 | 54 | 6.4 |
| Ex. 5 | None | | SL-1 | 1281 | SL-5 | 800 | SL-3 | 200 | SR-1 | 4.6 | 55 | 6.8 |
| Ex. 6 | W-5 | 1 | SL-6 | 1631 | SL-5 | 650 | | | None | 4.8 | 52 | 6.1 |
| Ex. 7 | W-3 | 0.5 | SL-1 | 1411 | SL-5 | 800 | SL-2 | 70 | SR-1 | 4.2 | 53 | 5.9 |
| Ex. 8 | W-6 | 1 | SL-1 | 731 | SL-6 | 1500 | SL-7 | 50 | None | 4.3 | 52 | 5.8 |
| Ex. 9 | W-4 | 0.5 | SL-1 | 1581 | SL-4 | 600 | SL-7 | 100 | SR-1 | 4.5 | 53 | 6.4 |
| Ex. 10 | None | | SL-1 | 1661 | SL-4 | 600 | SL-8 | 20 | None | 5 | 50 | 7.2 |
| Ex. 11 | W-5 | 1 | SL-6 | 1611 | SL-1 | 650 | SL-7 | 20 | SR-1 | 5.3 | 50 | 7.9 |
| Ex. 12 | W-5 | 1 | SL-6 | 1611 | SL-1 | 650 | SL-7 | 20 | None | 5.2 | 50 | 7.2 |
| Ex. 13 | None | | SL-1 | 1661 | SL-4 | 600 | SL-8 | 20 | SR-1 | 4.2 | 54 | 6 |
| Ex. 14 | W-2 | 0.5 | SL-1 | 1451 | SL-4 | 800 | SL-7 | 30 | None | 5.6 | 51 | 7.3 |
| Ex. 15 | W-2 | 0.5 | SL-1 | 1451 | SL-4 | 800 | SL-7 | 30 | SR-1 | 5.4 | 51 | 7.6 |
| Comp. Ex. 1 | W-1 | 0.5 | SL-1 | 1681 | SL-6 | 600 | | | None | 6 | 47 | 10.5 |
| Comp. Ex. 2 | W-1 | 0.5 | SL-1 | 1481 | SL-6 | 800 | | | None | 6.2 | 47 | 10 |

It is apparent from the above results that the pattern formed in accordance with the negative pattern forming method of the present invention excels in pattern dimension uniformity and line width roughness. It is also apparent that with respect to pattern collapse as well, favorable results can be obtained by the method. Further, compositions corresponding to those of Table 4 above devoid of hydrophobic resins were prepared, and similar evaluations were performed. With these compositions as well, excellent results were obtained in pattern dimension uniformity, line width roughness and pattern collapse.

What is claimed is:

1. A method of forming a pattern, comprising:
(a) forming a film comprising an actinic-ray- or radiation-sensitive resin composition comprising:
a resin (P) containing a repeating unit (P1) with a cyclic carbonic acid ester structure and any of repeating units (P2) of general formula (P2-1) below, and
a compound (B) that when exposed to actinic rays or radiation, generates an acid;
(b) exposing the film to actinic rays or radiation; and
(c) developing the exposed film with a developer comprising an organic solvent to thereby obtain a negative pattern, 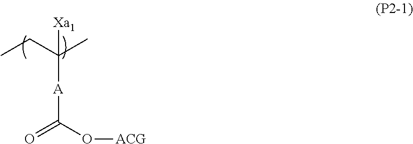
in which
Xa₁ represents a hydrogen atom, an alkyl group, a cyano group or a halogen atom;
A represents a single bond or a bivalent connecting group; and
ACG represents a non-acid-leaving hydrocarbon group consisting only of a carbon atom and a hydrogen atom.

2. The method according to claim 1, wherein the resin (P) contains any of repeating units of general formula (A-1) below as the repeating unit (P1) with a cyclic carbonic acid ester structure, 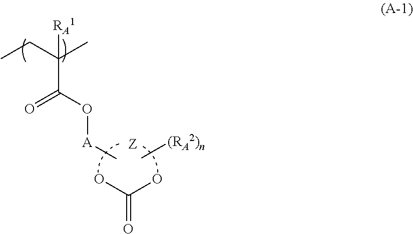
in which
R_{A}¹ represents a hydrogen atom or an alkyl group;
R_{A}², each independently when n is 2 or greater, represents a substituent;
A represents a single bond or a bivalent connecting group;
Z represents an atomic group forming a mono- or polycyclic structure with a group expressed by —O—C(═O)—O— in the formula; and
n is an integer of 0 or greater.

3. The method according to claim 1, wherein the resin (P) contains the repeating unit (P1) with a cyclic carbonic acid ester structure in an amount of 5 to 50 mol % based on all the repeating units of the resin (P).

4. The method according to claim 1, wherein the non-acid-leaving hydrocarbon group represented by ACG contains a mono- or polyalicyclic hydrocarbon structure.

5. The method according to claim 1, wherein the resin (P) contains the any of repeating units (P2) of general formula (P2-1) in an amount of 5 to 50 mol % based on all the repeating units of the resin (P).

6. The method according to claim 1, wherein the actinic-ray- or radiation-sensitive resin composition further comprises a hydrophobic resin containing at least either a fluorine atom or a silicon atom.

7. The method according to claim 1, wherein the developer comprises at least one organic solvent selected from the group consisting of a ketone solvent, an ester solvent, an alcohol solvent, an amide solvent and an ether solvent.

8. The method according to claim 1, further comprising (d) rinsing with a rinse liquid comprising an organic solvent.

9. A process for manufacturing an electronic device, comprising the pattern forming method according to claim 1.

10. An electronic device manufactured by the process of claim 9.

11. An actinic-ray- or radiation-sensitive resin composition comprising:
a resin (P) containing a repeating unit (P1) with a cyclic carbonic acid ester structure and any of repeating units (P2) of general formula (P2-1) below, and
a compound (B) that when exposed to actinic rays or radiation, generates an acid, 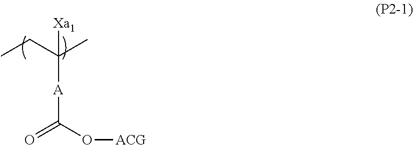
in which
Xa₁ represents a hydrogen atom, an alkyl group, a cyano group or a halogen atom;
A represents a single bond or a bivalent connecting group; and
ACG represents a non-acid-leaving hydrocarbon group consisting only of a carbon atom and a hydrogen atom.

12. An actinic-ray- or radiation-sensitive film comprising the actinic-ray- or radiation-sensitive resin composition of claim 11.
